(19) United States
(12) Patent Application Publication
(10) Pub. No.: US 2012/0104373 A1
(43) Pub. Date: May 3, 2012

(54) Organometallic Complex, and Light-Emitting Element and Display Device Using the Organometallic Complex

(75) Inventors: Hideko Inoue, Atsugi (JP); Satoko Shitagaki, Isehara (JP); Satoshi Seo, Sagamihara (JP)

(73) Assignee: Semiconductor Energy Laboratory Co., Ltd.

(21) Appl. No.: 13/283,936

(22) Filed: Oct. 28, 2011

(30) Foreign Application Priority Data
Oct. 29, 2010 (JP) 2010-244599

(51) Int. Cl. H01L 51/54; C07F 15/00

(52) U.S. Cl. 257/40; 544/225; 257/E51.024

(57) ABSTRACT

An object is to provide a novel organometallic complex capable of phosphorescence and having high heat resistance. Alternatively, an object is to provide a light-emitting device with high added value. The objects are achieved by providing an organometallic complex which has a structure represented by a general formula (G1) or (G2) below and is formed in such a way that a corresponding one of pyrazine derivatives represented by general formulae (G0) and (G0′) below is ortho-metalated by a Group 9 or Group 10 metal ion, or by providing a light-emitting element and a light-emitting device including the organometallic complex.

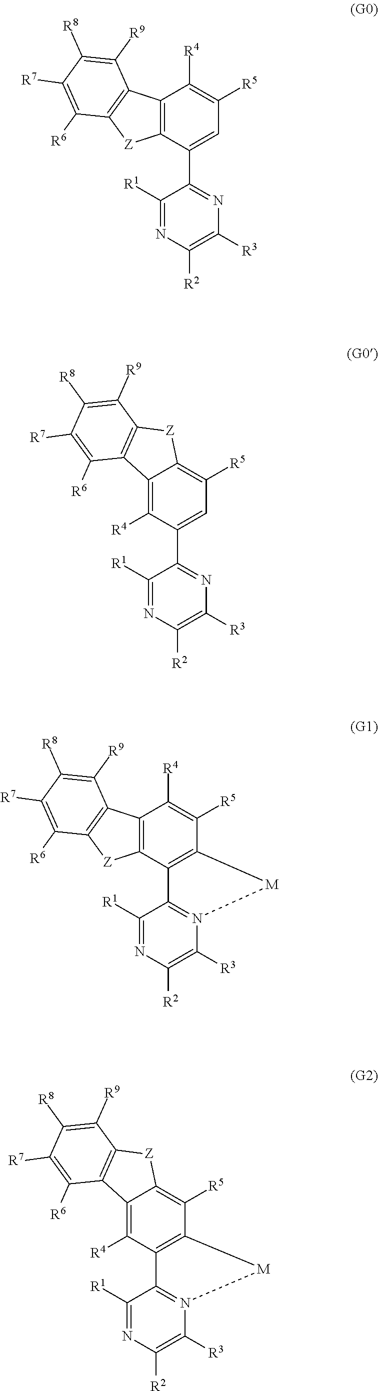

### BACKGROUND OF THE INVENTION

1. Field of the Invention

The present invention disclosed in this specification relates to an organometallic complex. In particular, the invention relates to an organometallic complex that can provide light emission from a triplet excited state. In addition, the invention relates to a light-emitting element and a light-emitting device each using the substance.

2. Description of the Related Art

In recent years, there have been the active research and product development of light-emitting elements in each of which an organic or inorganic compound having a light-emitting property is used as a light-emitting material. In particular, light-emitting elements called EL (electroluminescence) elements have characteristics such as feasibility of being thinner and more lightweight and responsive to input signals, because the basic structure of such elements is a simple structure in which a layer containing a light-emitting material (light-emitting layer) is just provided between a pair of electrodes (an anode and a cathode).

The light emission mechanism of organic EL elements is as follows: voltage application between a pair of electrodes causes electrons injected from the cathode and holes injected from the anode which serve as carriers to recombine in the light emission center of a light-emitting layer, a light-emitting substance is brought into an excited state, and the return of the molecular excitons to the ground state is accompanied by release of heat energy and light energy. The percentage of the light energy in this released energy (i.e., the percentage of generated photons to the injected carriers) is expressed as “internal quantum efficiency”.

A singlet excited state (S*) and a triplet excited state (T*) are known as types of the above excited state, and light emission can be obtained through either of the excited states. Note that, in a light-emitting element, the statistical generation ratio of the singlet excited state (S*) to the triplet excited state (T*) is considered to be 1:3.

It can be estimated in terms of the above generation ratio that, when the number of the injected carriers is 100%, about 25% of the light (photons) emitted by a light-emitting element is light emitted from the singlet excited state (S*) and about 75% is light emitted from the triplet excited state (T*).

Note that in this specification, light emitted from the singlet excited state (S*) is referred to as “fluorescence” and a compound that emits fluorescence is referred to as a “fluorescent compound”. Further, in this specification, light emitted from the triplet excited state (T*) is referred to as “phosphorescence” and a compound that emits phosphorescence is referred to as a “phosphorescent compound”.

Thus, the use of a phosphorescent compound in addition to a fluorescent compound can increase the upper limit of the internal quantum efficiency even to 100% and can realize much higher emission efficiency than the use of only a fluorescent compound.

For such a reason, light-emitting devices including light-emitting elements containing phosphorescent compounds in light-emitting layers have been under active development in recent years in order that highly-efficient light-emitting elements can be realized (e.g., see Non-Patent Document 1). As phosphorescent compounds, organometallic complexes that have iridium or the like as a central metal have particularly attracted attention because of their high phosphorescence quantum yield at room temperature, and organometallic complexes capable of emitting phosphorescence have been actively researched (e.g., see Non-Patent Document 2).

### REFERENCES

### Non-Patent Documents

Non-Patent Document 1: Zhang, Guo-Lin and five others, Gaodeng Xuexiao Huaxue Xuebao, 2004, vol. 25, No. 3, pp. 397-400
Non-Patent Document 2: Tetsuo Tsutsui and eight others, Japanese Journal of Applied Physics, Vol. 38, L1502-L1504, 1999

### SUMMARY OF THE INVENTION

Although phosphorescent compounds have found application in various fields owing to the high emission efficiency as described above, the number of phosphorescent compounds has been less than that of fluorescent materials at present.

Further, since the decomposition temperature of organometallic complexes is generally low, the problem of heat resistance might arise: for example, in fabrication of a light-emitting element containing an organometallic complex, treatment involving high temperature application to the organometallic complex (e.g., treatment in which the organometallic complex is heated in vacuum to form a thin film on a substrate (so-called vacuum evaporation treatment)) causes the material to be decomposed, failing to give desired performance.

Moreover, organometallic complexes preferably have high heat resistance. This is because the original performance of an organometallic complex is difficult to extract when the organometallic complex is heated in vacuum to form a thin film on a substrate and pyrolyzed during the heating, for example.

The present invention is made in view of the foregoing technical background. Therefore, an object of one embodiment of the present invention is to provide a novel organometallic complex that is capable of emitting phosphorescence and has high heat resistance.

Another object of one embodiment of the present invention is to provide an organometallic complex for which the time and cost for the synthesis are saved.

Another object of one embodiment of the present invention is to provide an organometallic complex having high emission quantum yield.

Another object of one embodiment of the present invention is to provide a light-emitting element having high emission efficiency.

Another object of one embodiment of the present invention is to provide a light-emitting element capable of low voltage driving.

Another object of one embodiment of the present invention is to provide a light-emitting element with a small emission intensity reduction relative to the driving time.

Another object of one embodiment of the present invention is to provide a light-emitting device with low power consumption.

Another object of one embodiment of the present invention is to provide a light-emitting device with high reliability.

The present invention aims to achieve at least one of the above-described objects.

As a result of intensive research, the present inventors have found that an organometallic complex having a structure formed in such a way that a pyrazine derivative including a dibenzofuran skeleton or a pyrazine derivative including a dibenzothiophene skeleton is ortho-metalated by an ion of a Group 9 metal or of a Group 10 metal is capable of emitting phosphorescence. Furthermore, the inventors have also newly found good heat resistance, high emission quantum yield, and the effect of saving synthesis time and cost by adjusting the structure of the organometallic complex or a ligand.

Specifically, one embodiment of the present invention is an organometallic complex having a structure represented by a general formula (G1).

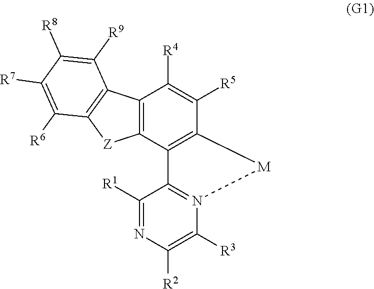

In the above general formula (G1), R¹ represents an alkyl group having 1 to 4 carbon atoms or an alkoxy group having 1 to 4 carbon atoms. Further, R² and R³ separately represent hydrogen or an alkyl group having 1 to 4 carbon atoms. Furthermore, R⁴, R⁵, R⁶, R⁷, R⁸, and R⁹ separately represent hydrogen or an alkyl group having 1 to 4 carbon atoms. Note that a phenyl group may be bonded to the alkyl group. In addition, Z represents oxygen or sulfur. Further, M is a central metal and represents either a Group 9 element or a Group 10 element.

Here, specific examples of the alkyl group having 1 to 4 carbon atoms for any of R¹ to R⁹ include a methyl group, an ethyl group, a propyl group, an isopropyl group, an n-butyl group, a sec-butyl group, an isobutyl group, and a tert-butyl group. Further, specific examples of the alkoxy group having 1 to 4 carbon atoms for R¹ include a methoxy group, an ethoxy group, a propoxy group, an isopropoxy group, an n-butoxy group, a sec-butoxy group, an isobutoxy group, and a tert-butoxy group.

The organometallic complex having the structure represented by the above general formula (G1) is formed in such a way that the pyrazine derivative is ortho-metalated by the central metal M, and accordingly, the heavy atom effect of the central metal M enables emission of phosphorescence. Further, the organometallic complex has a rigid structure including a dibenzofuran skeleton or a dibenzothiophene skeleton which is a ring structure, and accordingly has high heat resistance. Thus, the organometallic complex having the structure represented by the above general formula (G1) is an organometallic complex that is capable of emitting phosphorescence and has high heat resistance. Consequently, the organometallic complex can be used in a variety of fields, for example, fabrication of light-emitting elements which requires high heat resistance.

Further, one embodiment of the present invention is an organometallic complex having a structure represented by the following general formula (G2).

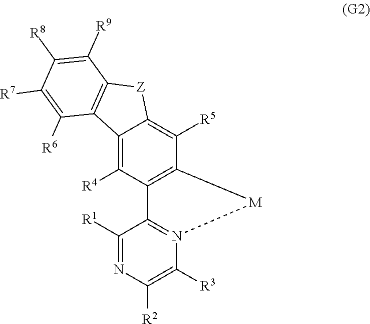

In the above general formula (G2), R¹ represents an alkyl group having 1 to 4 carbon atoms or an alkoxy group having 1 to 4 carbon atoms. Further, R² and R³ separately represent hydrogen or an allyl group having 1 to 4 carbon atoms. Furthermore, R⁴, R⁵, R⁶, R⁷, R⁸, and R⁹ separately represent hydrogen or an alkyl group having 1 to 4 carbon atoms. Note that a phenyl group may be bonded to the alkyl group. In addition, Z represents oxygen or sulfur. Further, M is a central metal and represents either a Group 9 element or a Group 10 element.

Here, specific examples of the alkyl group having 1 to 4 carbon atoms for any of R¹ to R⁹ include a methyl group, an ethyl group, a propyl group, an isopropyl group, an n-butyl group, a sec-butyl group, an isobutyl group, and a tert-butyl group. Further, specific examples of the alkoxy group having 1 to 4 carbon atoms for R¹ include a methoxy group, an ethoxy group, a propoxy group, an isopropoxy group, an n-butoxy group, a sec-butoxy group, an isobutoxy group, and a tert-butoxy group.

The organometallic complex having a structure represented by the above general formula (G2) is formed in such a way that the pyrazine derivative is ortho-metalated by the central metal M, and accordingly, the heavy atom effect of the central metal M enables emission of phosphorescence. Further, the organometallic complex has a rigid structure including a dibenzofuran skeleton or a dibenzothiophene skeleton which is a ring structure, and accordingly has high heat resistance. Thus, the organometallic complex having a structure represented by the above general formula (G2) is an organometallic complex that is capable of emitting phosphorescence and has high heat resistance. Consequently, the organometallic complex can be used in a variety of fields, for example, fabrication of light-emitting elements which requires high heat resistance.

Further, one embodiment of the present invention is an organometallic complex represented by a general formula (G3) below. The general formula (G3) below represents one mode of the organometallic complex having the structure represented by the above general formula (G1) and is a structure that is preferred because of the ease of synthesis.

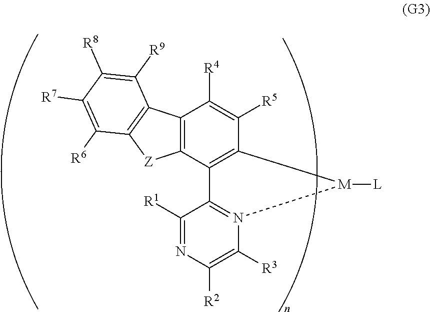

In the above general formula (G3), R¹ represents an alkyl group having 1 to 4 carbon atoms or an alkoxy group having 1 to 4 carbon atoms. Further, R² and R³ separately represent hydrogen or an alkyl group having 1 to 4 carbon atoms. Furthermore, R⁴, R⁵, R⁶, R⁷, R⁸, and R⁹ separately represent hydrogen or an alkyl group having 1 to 4 carbon atoms. Note that a phenyl group may be bonded to the alkyl group. In addition, M is a central metal and represents either a Group 9 element or a Group 10 element. Further, L represents a monoanionic ligand. In addition, Z represents oxygen or sulfur. Further, n is 2 when the central metal M is a Group 9 element, or n is 1 when the central metal M is a Group 10 element.

Here, specific examples of the alkyl group having 1 to 4 carbon atoms for any of R¹ to R⁹ include a methyl group, an ethyl group, a propyl group, an isopropyl group, an n-butyl group, a sec-butyl group, an isobutyl group, and a tert-butyl group. Further, specific examples of the alkoxy group having 1 to 4 carbon atoms for R¹ include a methoxy group, an ethoxy group, a propoxy group, an isopropoxy group, an n-butoxy group, a sec-butoxy group, an isobutoxy group, and a tert-butoxy group.

The organometallic complex represented by the above general formula (G3) has a structure, where the general formula (G1) which is a rigid structure including a dibenzofuran skeleton or a dibenzothiophene skeleton which is a ring structure is coordinated, and accordingly has high heat resistance. Consequently, the organometallic complex can be used in a variety of fields, for example, fabrication of light-emitting elements which requires high heat resistance.

Further, one embodiment of the present invention is an organometallic complex represented by the following general formula (G4).

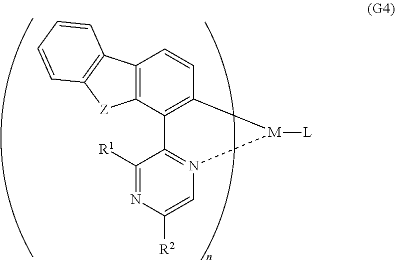

In the above general formula (G4), R¹ represents an alkyl group having 1 to 4 carbon atoms or an alkoxy group having 1 to 4 carbon atoms. Further, R² represents either hydrogen or an alkyl group having 1 to 4 carbon atoms. Note that a phenyl group may be bonded to the alkyl group. In addition, M is a central metal and represents either a Group 9 element or a Group 10 element. Further, L represents a monoanionic ligand. In addition, Z represents oxygen or sulfur. Further, n is 2 when the central metal M is a Group 9 element, or n is 1 when the central metal M is a Group 10 element.

Here, specific examples of the alkyl group having 1 to 4 carbon atoms for R¹ and R² include a methyl group, an ethyl group, a propyl group, an isopropyl group, an n-butyl group, a sec-butyl group, an isobutyl group, and a tert-butyl group. Further, specific examples of the alkoxy group having 1 to 4 carbon atoms for R¹ include a methoxy group, an ethoxy group, a propoxy group, an isopropoxy group, an n-butoxy group, a sec-butoxy group, an isobutoxy group, and a tert-butoxy group.

In the organometallic complex represented by the general formula (G4), the substituents R³, R⁴, R⁵, R⁶, R⁷, R⁸, and R⁹ in the general formula (G3) are hydrogen. Accordingly, steric hindrance of the pyrazine derivative can be reduced so that it can be easily ortho-metalated by the metal ion, which leads to an increase in the synthesis yield of the organometallic complex. Thus, the time and cost for the synthesis can be saved.

Further, one embodiment of the present invention is an organometallic complex represented by a general formula (G5) below. The general formula (G5) below represents one mode of the organometallic complex having a structure represented by the above general formula (G2) and is a structure that is preferred because of the ease of synthesis.

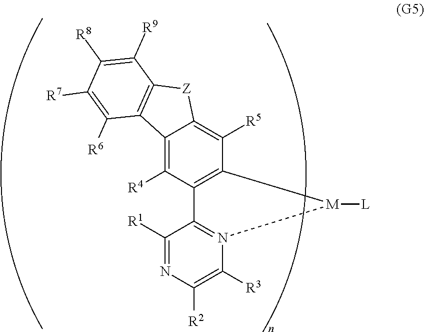

In the above general formula (G5), R¹ represents an alkyl group having 1 to 4 carbon atoms or an alkoxy group having 1 to 4 carbon atoms. Further, R² and R³ separately represent hydrogen or an alkyl group having 1 to 4 carbon atoms. Furthermore, R⁴, R⁵, R⁶, R⁷, R⁸, and R⁹ separately represent hydrogen or an alkyl group having 1 to 4 carbon atoms. Note that a phenyl group may be bonded to the alkyl group. In addition, M is a central metal and represents either a Group 9 element or a Group 10 element. Further, L represents a monoanionic ligand. In addition, Z represents oxygen or sulfur. Further, n is 2 when the central metal M is a Group 9 element, or n is 1 when the central metal M is a Group 10 element.

Here, specific examples of the alkyl group having 1 to 4 carbon atoms for any of R¹ to R⁹ include a methyl group, an ethyl group, a propyl group, an isopropyl group, an n-butyl group, a sec-butyl group, an isobutyl group, and a tert-butyl group. Further, specific examples of the alkoxy group having 1 to 4 carbon atoms for R¹ include a methoxy group, an ethoxy group, a propoxy group, an isopropoxy group, an n-butoxy group, a sec-butoxy group, an isobutoxy group, and a tert-butoxy group.

The organometallic complex represented by the above general formula (G5) has a structure, where the general formula (G2) which is a rigid structure including a dibenzofuran skeleton or a dibenzothiophene skeleton which is a ring structure is coordinated, and accordingly has high heat resistance. Consequently, the organometallic complex can be used in a variety of fields, for example, fabrication of light-emitting elements which requires high heat resistance.

Further, one embodiment of the present invention is an organometallic complex represented by the following general formula (G6).

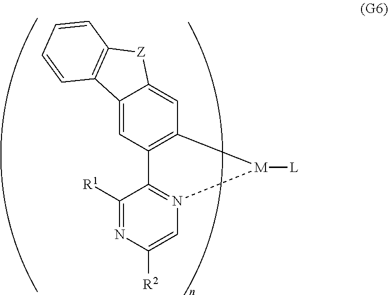

In the above general formula (G6), R¹ represents an alkyl group having 1 to 4 carbon atoms or an alkoxy group having 1 to 4 carbon atoms. Further, R² represents either hydrogen or an alkyl group having 1 to 4 carbon atoms. Note that a phenyl group may be bonded to the alkyl group. In addition, M is a central metal and represents either a Group 9 element or a Group 10 element. Further, L represents a monoanionic ligand. In addition, Z represents oxygen or sulfur. Further, n is 2 when the central metal M is a Group 9 element, or n is 1 when the central metal M is a Group 10 element.

Here, specific examples of the alkyl group having 1 to 4 carbon atoms for R¹ and R² include a methyl group, an ethyl group, a propyl group, an isopropyl group, an n-butyl group, a sec-butyl group, an isobutyl group, and a tert-butyl group. Further, specific examples of the alkoxy group having 1 to 4 carbon atoms for R¹ include a methoxy group, an ethoxy group, a propoxy group, an isopropoxy group, an n-butoxy group, a sec-butoxy group, an isobutoxy group, and a tert-butoxy group.

In the organometallic complex represented by the general formula (G6), the substituents R³, R⁴, R⁵, R⁶, R⁷, R⁸, and R⁹ in the general formula (G5) are hydrogen. Accordingly, steric hindrance of the pyrazine derivative can be reduced so that it can be easily ortho-metalated by the metal ion, which leads to an increase in the synthesis yield of the organometallic complex. Thus, the time and cost for the synthesis can be saved.

One embodiment of the present invention is an organometallic complex represented by any of the general formulae (G3) to (G6) and in which the monoanionic ligand (L) is any of a monoanionic bidentate chelate ligand having a β-diketone structure, a monoanionic bidentate chelate ligand having a carboxyl group, a monoanionic bidentate chelate ligand having a phenolic hydroxyl group, and a monoanionic bidentate chelate ligand in which two ligand elements are both nitrogen. More preferably, the monoanionic ligand (L) is a monoanionic ligand represented by any of the following structural formulae (L1) to (L6).

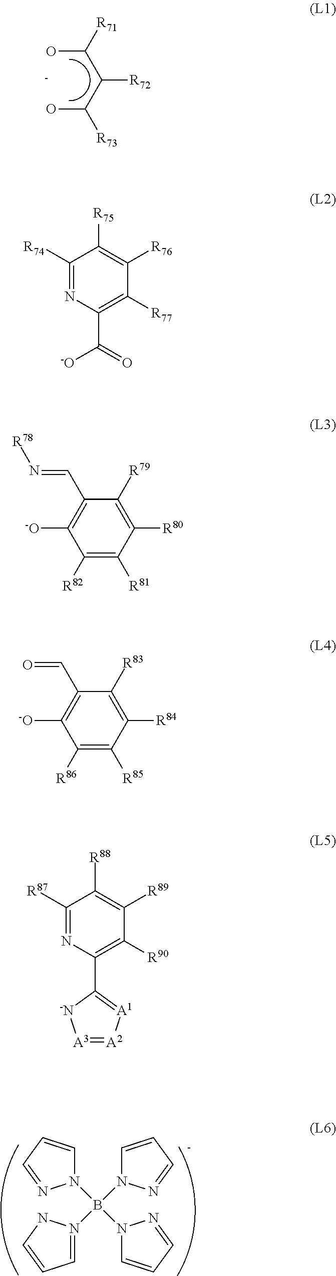

In the above structural formulae (L1) to (L6), R⁷¹ to R⁹⁰ separately represent any of hydrogen, an alkyl group having 1 to 4 carbon atoms, a halogen group, a haloalkyl group, an alkoxy group having 1 to 4 carbon atoms, and an allylthio group having 1 to 4 carbon atoms. In addition, A¹, A², and A³ separately represent nitrogen N or carbon C—R, and R represents hydrogen, an alkyl group having 1 to 4 carbon atoms, a halogen group, a haloalkyl group having 1 to 4 carbon atoms, or a phenyl group.

The monoanionic ligands represented by the above structural formulae (L1) to (L6) have high coordination ability and are inexpensively available. Accordingly, the time and cost for the synthesis can be saved.

Further, one embodiment of the present invention is an organometallic complex represented by a general formula (G7) below. The general foiinula (G7) below represents one mode of the organometallic complex having the structure represented by the above general formula (G1) and is a structure that is preferred because of the ease of synthesis.

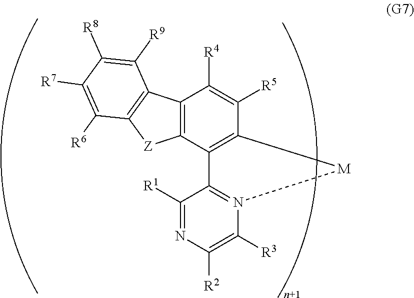

In the above general formula (G7), R¹ represents an alkyl group having 1 to 4 carbon atoms or an alkoxy group having 1 to 4 carbon atoms. Further, R² and R³ separately represent hydrogen or an alkyl group having 1 to 4 carbon atoms. Furthermore, R⁴, R⁵, R⁶, R⁷, R⁸, and R⁹ separately represent hydrogen or an alkyl group having 1 to 4 carbon atoms. Note that a phenyl group may be bonded to the alkyl group. In addition, M is a central metal and represents either a Group 9 element or a Group 10 element. In addition, Z represents oxygen or sulfur. Further, n is 2 when the central metal M is a Group 9 element, or n is 1 when the central metal M is a Group 10 element.

Here, specific examples of the alkyl group having 1 to 4 carbon atoms for any of R¹ to R⁹ include a methyl group, an ethyl group, a propyl group, an isopropyl group, an n-butyl group, a sec-butyl group, an isobutyl group, and a tert-butyl group. Further, specific examples of the alkoxy group having 1 to 4 carbon atoms for R¹ include a methoxy group, an ethoxy group, a propoxy group, an isopropoxy group, an n-butoxy group, a sec-butoxy group, an isobutoxy group, and a tert-butoxy group.

The organometallic complex represented by the above general formula (G7) has a structure, where the general formula (G1) which is a rigid structure including a dibenzofuran skeleton or a dibenzothiophene skeleton which is a ring structure is coordinated, and accordingly has very high heat resistance. Consequently, the organometallic complex can be used in a variety of fields.

Further, one embodiment of the present invention is an organometallic complex represented by the following general formula (G8).

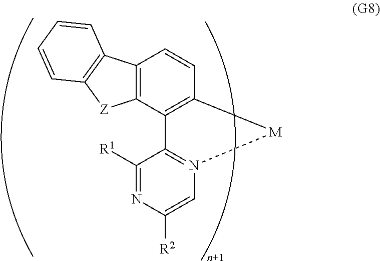

In the above general formula (G8), R¹ represents an alkyl group having 1 to 4 carbon atoms or an alkoxy group having 1 to 4 carbon atoms. Further, R² represents either hydrogen or an alkyl group having 1 to 4 carbon atoms. Note that a phenyl group may be bonded to the alkyl group. In addition, M is a central metal and represents either a Group 9 element or a Group 10 element. In addition, Z represents oxygen or sulfur. Further, n is 2 when the central metal M is a Group 9 element, or n is 1 when the central metal M is a Group 10 element.

Here, specific examples of the alkyl group having 1 to 4 carbon atoms for R¹ and R² include a methyl group, an ethyl group, a propyl group, an isopropyl group, an n-butyl group, a sec-butyl group, an isobutyl group, and a tert-butyl group. Further, specific examples of the alkoxy group having 1 to 4 carbon atoms for R¹ include a methoxy group, an ethoxy group, a propoxy group, an isopropoxy group, an n-butoxy group, a sec-butoxy group, an isobutoxy group, and a tert-butoxy group.

In the organometallic complex represented by the general formula (G8), the substituents R³, R⁴, R⁵, R⁶, R⁷, R⁸, and R⁹ in the general formula (G7) are hydrogen. Accordingly, steric hindrance of the pyrazine derivative can be reduced so that it can be easily ortho-metalated by the metal ion, which leads to an increase in the synthesis yield of the organometallic complex. Thus, the time and cost for the synthesis can be saved.

Further, one embodiment of the present invention is an organometallic complex represented by a general formula (G9) below. The general formula (G9) below represents one mode of the organometallic complex having a structure represented by the above general formula (G2) and is a structure that is preferred because of the ease of synthesis.

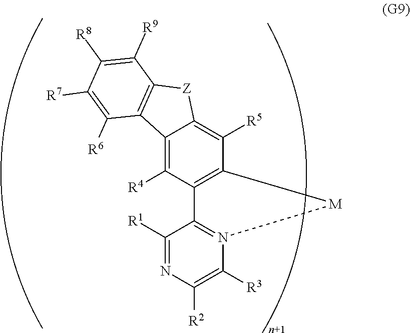

In the above general formula (G9), R¹ represents an alkyl group having 1 to 4 carbon atoms or an alkoxy group having 1 to 4 carbon atoms. Further, R² and R³ separately represent hydrogen or an alkyl group having 1 to 4 carbon atoms. Furthermore, R⁴, R⁵, R⁶, R⁷, R⁸, and R⁹ separately represent hydrogen or an alkyl group having 1 to 4 carbon atoms. Note that a phenyl group may be bonded to the alkyl group. In addition, Z represents oxygen or sulfur. Further, M is a central metal and represents either a Group 9 element or a Group 10 element. In addition, n is 2 when the central metal M is a Group 9 element, or n is 1 when the central metal M is a Group 10 element.

Here, specific examples of the alkyl group having 1 to 4 carbon atoms for any of R¹ to R⁹ include a methyl group, an ethyl group, a propyl group, an isopropyl group, an n-butyl group, a sec-butyl group, an isobutyl group, and a tert-butyl group. Further, specific examples of the alkoxy group having 1 to 4 carbon atoms for R¹ include a methoxy group, an ethoxy group, a propoxy group, an isopropoxy group, an n-butoxy group, a sec-butoxy group, an isobutoxy group, and a tert-butoxy group.

The organometallic complex represented by the above general formula (G9) has a structure, where the general formula (G2) which is a rigid structure including a dibenzofuran skeleton or a dibenzothiophene skeleton which is a ring structure is coordinated, and accordingly has very high heat resistance. Consequently, the organometallic complex can be used in a variety of fields.

Further, one embodiment of the present invention is an organometallic complex represented by the following general formula (G10).

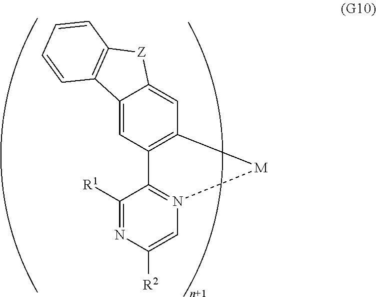

In the above general formula (G10), R¹ represents an alkyl group having 1 to 4 carbon atoms or an alkoxy group having 1 to 4 carbon atoms. Further, R² represents either hydrogen or an alkyl group having 1 to 4 carbon atoms. Note that a phenyl group may be bonded to the alkyl group. In addition, Z represents oxygen or sulfur. Further, M is a central metal and represents either a Group 9 element or a Group 10 element. In addition, n is 2 when the central metal M is a Group 9 element, or n is 1 when the central metal M is a Group 10 element.

Here, specific examples of the alkyl group having 1 to 4 carbon atoms for R¹ and R² include a methyl group, an ethyl group, a propyl group, an isopropyl group, an n-butyl group, a sec-butyl group, an isobutyl group, and a tert-butyl group. Further, specific examples of the alkoxy group having 1 to 4 carbon atoms for R¹ include a methoxy group, an ethoxy group, a propoxy group, an isopropoxy group, an n-butoxy group, a sec-butoxy group, an isobutoxy group, and a tert-butoxy group.

In the organometallic complex represented by the general formula (G10), the substituents R³, R⁴, R⁵, R⁶, R⁷, R⁸, and R⁹ in the general formula (G9) are hydrogen. Accordingly, steric hindrance of the pyrazine derivative can be reduced so that it can be easily ortho-metalated by the metal ion, which leads to an increase in the synthesis yield of the organometallic complex. Thus, the time and cost for the synthesis can be saved.

One embodiment of the present invention is one of the above organometallic complexes, which includes the central metal M as iridium or platinum.

By use of iridium or platinum, which is a heavy element, as the central metal M, a spin flip due to the heavy atom effect easily occurs, and this increases the probability that an electron at the excited singlet level will be transferred by intersystem crossing to the excited triplet level. Accordingly, the emission quantum yield can be enhanced as compared with an organometallic complex containing an element that is lighter than iridium and platinum as the central metal.

One embodiment of the present invention is a light-emitting element including any of the above organometallic complexes as a light-emitting substance.

A feature of the above organometallic complexes is high emission quantum yield. Therefore, the emission efficiency of the light-emitting element including any of the above organometallic complexes can be increased, and the driving voltage thereof can also be reduced due to the higher emission efficiency. Furthermore, owing to the good heat resistance, the organometallic complexes have high electrical and chemical stability. Accordingly, an emission intensity reduction of the light-emitting element including any of the above organometallic complexes can be suppressed to a small value even after long-time driving.

One embodiment of the present invention is a light-emitting device including the above light-emitting element.

Other features of the light-emitting element are high emission efficiency and low driving voltage. Consequently, a light-emitting device with low power consumption can be provided by using the light-emitting element. Another feature is that a reduction in emission intensity is small relative to the driving time. Consequently, a light-emitting device with high reliability can be provided by using the light-emitting element.

Note that the term “light-emitting device” in this specification encompasses an electronic device including a light-emitting element and a lighting device including a light-emitting element, and therefore refers to an image display device, a light-emitting device, or a light source (including a lighting device). In addition, the light-emitting device includes all the following modules: a module in which a connector, such as a flexible printed circuit (FPC), a tape automated bonding (TAB) tape, or a tape carrier package (TCP), is attached to a light-emitting device, a module in which a printed wiring board is provided at the end of a TAB tape or a TCP, and a module in which an integrated circuit (IC) is directly mounted on a light-emitting device by a chip-on-glass (COG) method.

In this specification, an EL layer refers to a layer provided between a pair of electrodes in a light-emitting element. Thus, a light-emitting layer containing an organic compound that is a light-emitting substance which is interposed between electrodes is one mode of the EL layer.

In this specification, when Substance A is dispersed in a matrix formed of Substance B, Substance B forming the matrix is called a host material and Substance A dispersed in the matrix is called a guest material. Note that Substance A and Substance B may be separately a single substance or a mixture of two or more kinds of substances.

Further, the expression “A and B are connected to each other” in this specification refers to the case where A and B are electrically connected to each other (i.e., A and B are connected to each other with another element or another circuit interposed therebetween), where A and B are functionally connected to each other (i.e., A and B are functionally connected to each other with another circuit interposed therebetween), or where A and B are directly connected to each other (i.e., A and B are connected to each other without any other element or circuit interposed therebetween).

By use of one embodiment of the present invention, an organometallic complex that is capable of emitting phosphorescence and has high heat resistance can be provided.

Alternatively, by use of one embodiment of the present invention, an organometallic complex, for which the time and cost for the synthesis are saved, can be provided.

Alternatively, by use of one embodiment of the present invention, an organometallic complex with high emission quantum yield can be provided.

Alternatively, by use of one embodiment of the present invention, a light-emitting element having high emission efficiency can be provided.

Alternatively, by use of one embodiment of the present invention, a light-emitting element capable of low voltage driving can be provided.

Alternatively, by use of one embodiment of the present invention, a light-emitting element with a small emission intensity reduction relative to the driving time, can be provided.

Alternatively, by use of one embodiment of the present invention, a light-emitting device with low power consumption can be provided.

Alternatively, by use of one embodiment of the present invention, a light-emitting device with high reliability can be provided.

### BRIEF DESCRIPTION OF THE DRAWINGS

FIG. 1 illustrates a light-emitting element which is one embodiment of the present invention.

FIG. 2 illustrates a light-emitting element which is one embodiment of the present invention.

FIG. 3 illustrates a light-emitting element which is one embodiment of the present invention.

FIGS. 4A to 4D illustrate a passive matrix light-emitting device.

FIG. 5 illustrates a passive matrix light-emitting device.

FIGS. 6A and 6B illustrate an active matrix light-emitting device.

FIGS. 7A to 7E illustrate electronic devices.

FIG. 8 illustrates lighting devices.

FIGS. 9A and 9B illustrate an electronic apparatus.

FIG. 10 shows a ¹H-NMR chart of an organometallic complex represented by a structural formula (100).

FIG. 11 shows an ultraviolet-visible absorption and emission spectra of the organometallic complex represented by the structural formula (100).

FIG. 12 shows a ¹H-NMR chart of an organometallic complex represented by a structural formula (124).

FIG. 13 shows an ultraviolet-visible absorption and emission spectra of the organometallic complex represented by the structural formula (124).

FIG. 14 shows a ¹H-NMR chart of an organometallic complex represented by a structural formula (135).

FIG. 15 shows an ultraviolet-visible absorption and emission spectra of the organometallic complex represented by the structural formula (135).

FIG. 16 illustrates a light-emitting element which is one embodiment of the present invention.

FIG. 17 shows luminance versus current density characteristics of light-emitting elements which are embodiments of the present invention.

FIG. 18 shows luminance versus voltage characteristics of the light-emitting elements which are embodiments of the present invention.

FIG. 19 shows normalized luminance versus driving time characteristics of the light-emitting elements which are embodiments of the present invention.

FIG. 20 shows emission spectra of the light-emitting elements which are embodiments of the present invention.

### DETAILED DESCRIPTION OF THE INVENTION

Embodiments will be described in detail with reference to the drawings. Note that the invention is not limited to the description given below, and it will be easily understood by those skilled in the art that various changes and modifications can be made without departing from the spirit and scope of the invention. Therefore, the invention should not be construed as being limited to the description in the following embodiments. Note that in the structures of the invention described below, the same portions or portions having similar functions are denoted by the same reference numerals in different drawings, and description of such portions is not repeated.

### Embodiment 1

In Embodiment 1, organometallic complexes which are embodiments of the present invention will be described.

### [Synthesis Method of Structure Represented by General Formula (G1)]

A pyrazine derivative represented by the general formula (G0) below can be synthesized by a simple synthesis scheme as follows. For example, as illustrated in a scheme (a) below, boronic acid including a dibenzofuran skeleton or a dibenzothiophene skeleton (A1) is coupled with a halogenated pyrazine compound (A2), so that the pyrazine derivative can be obtained. Alternatively, as illustrated in a scheme (a′) below, diketone of boronic acid including a dibenzofuran skeleton or a dibenzothiophene skeleton (A1′) is reacted with diamine (A2′), so that the pyrazine derivative can be obtained. Note that in the general formula (G0) below, R¹ represents an alkyl group having 1 to 4 carbon atoms or an alkoxy group having 1 to 4 carbon atoms. Further, R² and R³ separately represent hydrogen or an alkyl group having 1 to 4 carbon atoms. Furthermore, R⁴, R⁵, R⁶, R⁷, R⁸, and R⁹ separately represent hydrogen or an alkyl group having 1 to 4 carbon atoms. Note that a phenyl group may be bonded to the alkyl group. In addition, Z represents oxygen or sulfur. Further, X represents a halogen element.

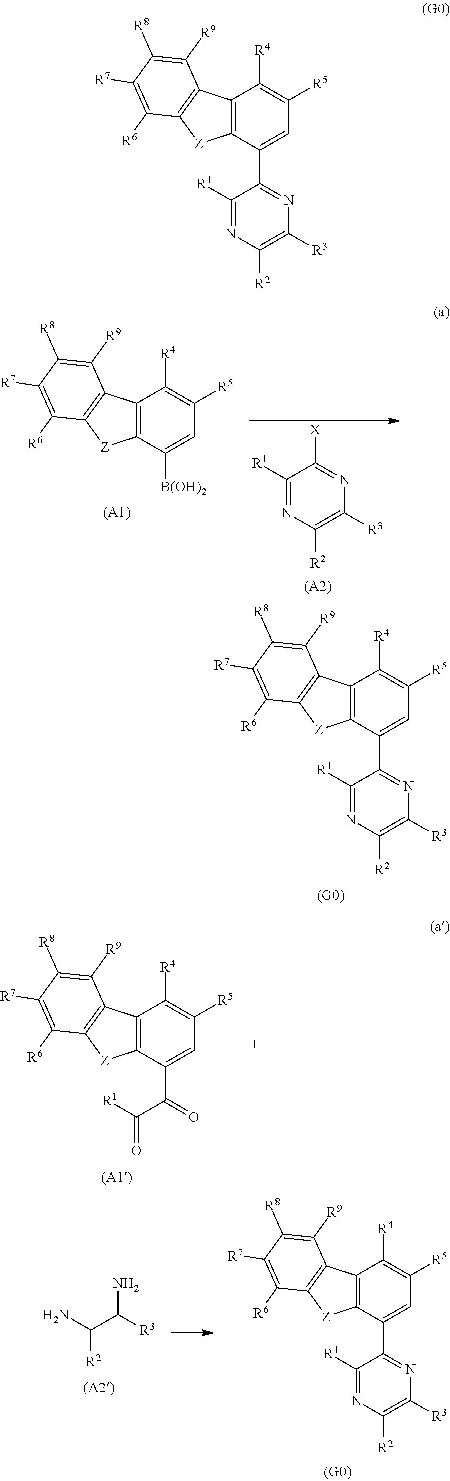

One embodiment of the present invention is an organometallic complex that has the structure represented by the general formula (G1) below and is formed in such a way that the pyrazine derivative prepared by the above synthesis method is ortho-metalated by an ion of a Group 9 metal or of a Group 10 metal.

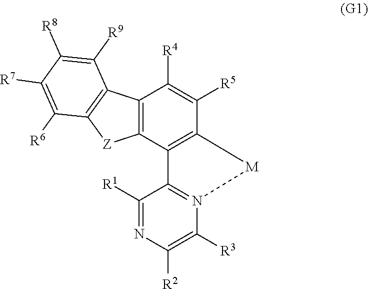

In the above general formula (G1), R¹ represents an alkyl group having 1 to 4 carbon atoms or an alkoxy group having 1 to 4 carbon atoms. Further, R² and R³ separately represent hydrogen or an alkyl group having 1 to 4 carbon atoms. Furthermore, R⁴, R⁵, R⁶, R⁷, R⁸, and R⁹ separately represent hydrogen or an alkyl group having 1 to 4 carbon atoms. Note that a phenyl group may be bonded to the alkyl group. In addition, Z represents oxygen or sulfur. Further, M is a central metal and represents either a Group 9 element or a Group 10 element.

Here, specific examples of the alkyl group having 1 to 4 carbon atoms for any of R¹ to R⁹ include a methyl group, an ethyl group, a propyl group, an isopropyl group, an n-butyl group, a sec-butyl group, an isobutyl group, and a tert-butyl group. Further, specific examples of the alkoxy group having 1 to 4 carbon atoms for R¹ include a methoxy group, an ethoxy group, a propoxy group, an isopropoxy group, an n-butoxy group, a sec-butoxy group, an isobutoxy group, and a tert-butoxy group.

The organometallic complex having the structure represented by the above general formula (G1) is formed in such a way that the pyrazine derivative is ortho-metalated by the central metal M, and accordingly, the heavy atom effect of the central metal M enables emission of phosphorescence. Further, the organometallic complex has a rigid structure including a dibenzofuran skeleton or a dibenzothiophene skeleton which is a ring structure, and accordingly has high heat resistance. Thus, the organometallic complex having the structure represented by the above general formula (G1) is an organometallic complex that is capable of emitting phosphorescence and has high heat resistance. Consequently, the organometallic complex can be used in a variety of fields, for example, fabrication of light-emitting elements which requires high heat resistance.

Since a wide variety of substances as the compounds (A1), (A2), (A1′), and (A2′) in the scheme (a) and the scheme (a′) are commercially available or can be synthesized, a great variety of substances as the phenylpyrazine derivative represented by the general formula (G0) can be synthesized. Consequently, the organometallic complex, which has the structure represented by the general formula (G1) and is formed in such a way that the general formula (G0) is ortho-metalated by an ion of a Group 9 metal or of a Group 10 metal, also shows variations with a wide variety of ligands.

### [Synthesis Method of Structure Represented by General Formula (G2)]

A pyrazine derivative represented by the general formula (G0′) below can be synthesized by a simple synthesis scheme as follows. For example, as illustrated in a scheme (b) below, boronic acid including a dibenzofuran skeleton or a dibenzothiophene skeleton (B1) is coupled with a halogenated pyrazine compound (A2), so that the pyrazine derivative can be obtained. Alternatively, as illustrated in a scheme (b′) below, diketone of boronic acid including a dibenzofuran skeleton or a dibenzothiophene skeleton (B1′) is reacted with diamine (A2′), so that the pyrazine derivative can be obtained. Note that in the general formula (G0′) below, R¹ represents an alkyl group having 1 to 4 carbon atoms or an alkoxy group having 1 to 4 carbon atoms. Further, R² and R³ separately represent hydrogen or an alkyl group having 1 to 4 carbon atoms. Furthermore, R⁴, R⁵, R⁶, R⁷, R⁸, and R⁹ separately represent hydrogen or an alkyl group having 1 to 4 carbon atoms. Note that a phenyl group may be bonded to the alkyl group. In addition, Z represents oxygen or sulfur. Further, X represents a halogen element.

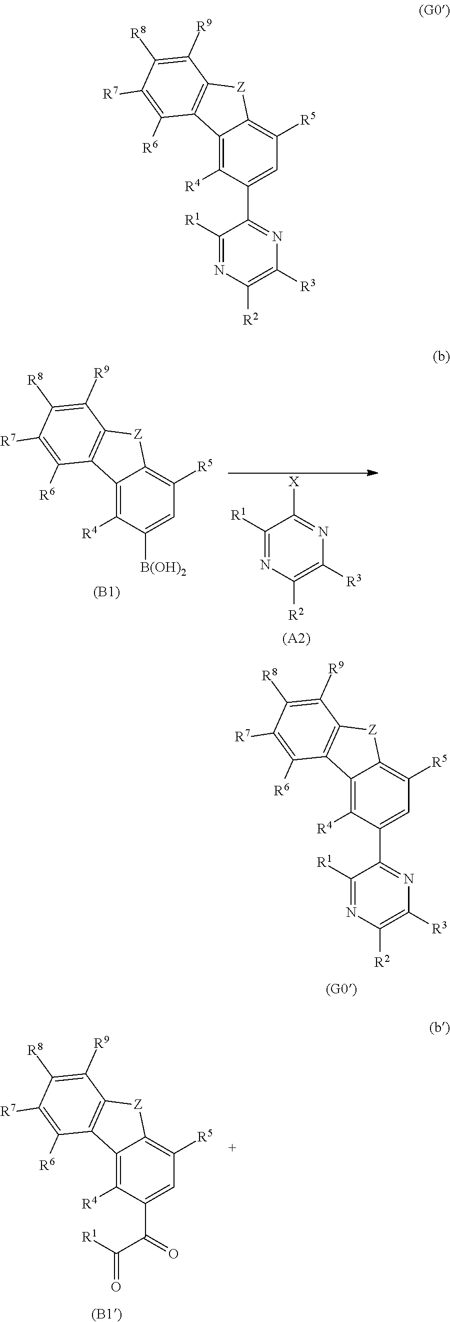

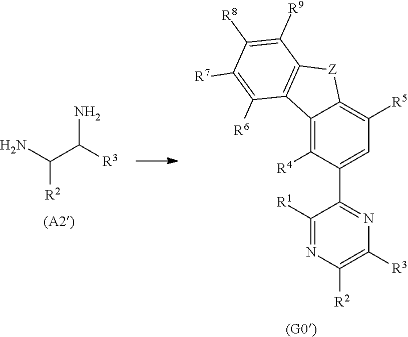

One embodiment of the present invention is an organometallic complex that has the structure represented by the general formula (G2) below and is formed in such a way that the pyrazine derivative, which is prepared by the above synthesis method and represented by the general formula (G0′), is ortho-metalated by an ion of a Group 9 metal or of a Group 10 metal.

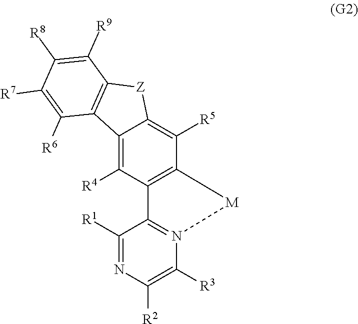

In the above general formula (G2), R¹ represents an alkyl group having 1 to 4 carbon atoms or an alkoxy group having 1 to 4 carbon atoms. Further, R² and R³ separately represent hydrogen or an alkyl group having 1 to 4 carbon atoms. Furthermore, R⁴, R⁵, R⁶, R⁷, R⁸, and R⁹ separately represent hydrogen or an alkyl group having 1 to 4 carbon atoms. Note that a phenyl group may be bonded to the alkyl group. In addition, Z represents oxygen or sulfur. Further, M is a central metal and represents either a Group 9 element or a Group 10 element.

Here, specific examples of the alkyl group having 1 to 4 carbon atoms for any of R¹ to R⁹ include a methyl group, an ethyl group, a propyl group, an isopropyl group, an n-butyl group, a sec-butyl group, an isobutyl group, and a tert-butyl group. Further, specific examples of the alkoxy group having 1 to 4 carbon atoms for R¹ include a methoxy group, an ethoxy group, a propoxy group, an isopropoxy group, an n-butoxy group, a sec-butoxy group, an isobutoxy group, and a tert-butoxy group.

The organometallic complex having a structure represented by the above general formula (G2) is formed in such a way that the pyrazine derivative is ortho-metalated by the central metal M, and accordingly, the heavy atom effect of the central metal M enables emission of phosphorescence. Further, the organometallic complex has a rigid structure including a dibenzofuran skeleton or a dibenzothiophene skeleton which is a ring structure, and accordingly has high heat resistance. Thus, the organometallic complex having a structure represented by the above general formula (G2) is an organometallic complex that is capable of emitting phosphorescence and has high heat resistance. Consequently, the organometallic complex can be used in a variety of fields, for example, fabrication of light-emitting elements which requires high heat resistance.

Since a wide variety of substances as the compounds (B1), (A2), (B1′), and (A2′) in the scheme (b) and the scheme (b′) are commercially available or can be synthesized, a great variety of substances as the phenylpyrazine derivative represented by the general formula (G0′) can be synthesized. Consequently, the organometallic complex, which has the structure represented by the general formula (G2) and is formed in such a way that the general formula (G0′) is ortho-metalated by an ion of a Group 9 metal or of a Group 10 metal, also shows variations with a wide variety of ligands.

### [Synthesis Method and Preferred Modes of Organometallic Complex Represented by General Formula (G3)]

Next, a method of synthesizing the organometallic complex represented by the general formula (G3) below, which is a specific preferred example of the organometallic complex having the structure represented by the general formula (G1), will be described.

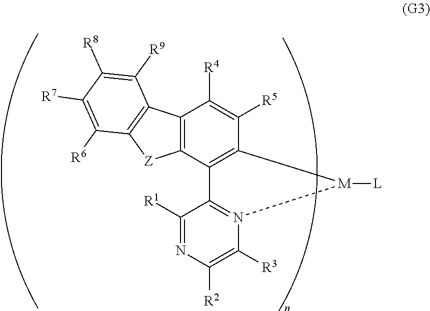

First, as illustrated in a synthesis scheme (c) below, the pyrazine derivative represented by the general formula (G0) and a compound of a Group 9 metal or of a Group 10 metal which contains a halogen (e.g., a metal halide or a metal complex) are heated with an alcohol-based solvent (e.g., glycerol, ethylene glycol, 2-methoxyethanol, or 2-ethoxyethanol) alone or a mixed solvent of water and one or more kinds of such alcohol-based solvents, so that a binuclear complex (B) can be obtained, which is a kind of organometallic complex including the structure represented by the general formula (G1). There is no particular limitation on a heating means, and an oil bath, a sand bath, or an aluminum block may be used. Further, heating with microwaves can be used.

Examples of the compounds of a Group 9 or Group 10 metal which contain halogen include, but not limited to, rhodium chloride hydrate, palladium chloride, iridium chloride hydrate, iridium chloride hydrochloride hydrate, potassium tetrachloroplatinate(II), and the like. Note that in the synthesis scheme (c) below, M is a central metal and represents either a Group 9 element or a Group 10 element, and X represents a halogen element. In addition, n is 2 when the central metal M is a Group 9 element, or n is 1 when the central metal M is a Group 10 element. In addition, Z represents oxygen or sulfur. Further, X represents a halogen element.

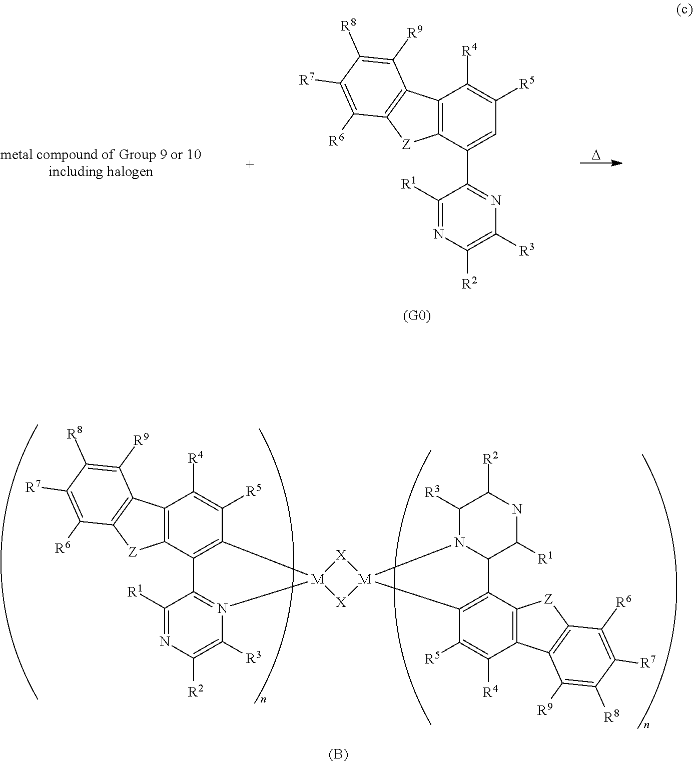

Furthermore, as illustrated in a synthesis scheme (d) below, the binuclear complex (B) obtained by the above synthesis scheme (c) is reacted with HL which is a material of a monoanionic ligand, so that a proton of HL is eliminated and the monoanionic ligand L is coordinated with the central metal M; thus, the organometallic complex represented by the general formula (G3) which is one embodiment of the present invention can be obtained. There is no particular limitation on a heating means, and an oil bath, a sand bath, or an aluminum block may be used. Further, heating with microwaves can be used. Note that in the synthesis scheme (d), the central metal M represents either a Group 9 element or a Group 10 element, and X represents a halogen element. In addition, n is 2 when the central metal M is a Group 9 element, or n is 1 when the central metal M is a Group 10 element. In addition, Z represents oxygen or sulfur. Further, X represents a halogen element.

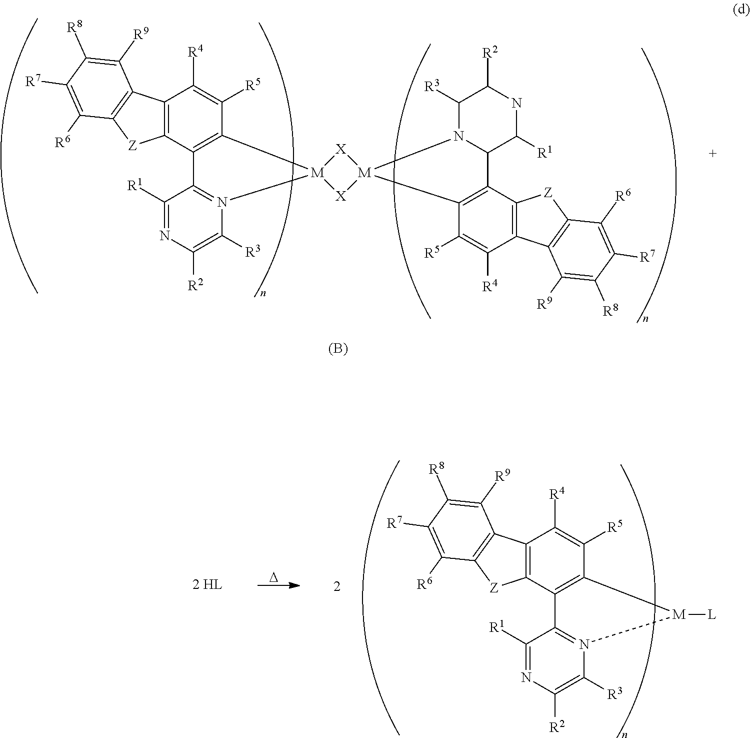

The organometallic complex represented by the general formula (G3) below, which can be synthesized according to the schemes (c) and (d) as described above, is one embodiment of the present invention. The general formula (G3) below is one mode of the organometallic complex having the structure of the general formula (G1), and is easy to synthesize and therefore preferable.

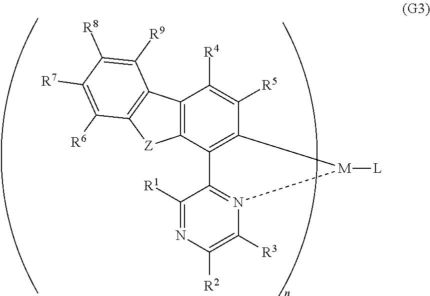

In the above general formula (G3), R¹ represents an alkyl group having 1 to 4 carbon atoms or an alkoxy group having 1 to 4 carbon atoms. Further, R² and R³ separately represent hydrogen or an alkyl group having 1 to 4 carbon atoms. Furthermore, R⁴, R⁵, R⁶, R⁷, R⁸, and R⁹ separately represent hydrogen or an alkyl group having 1 to 4 carbon atoms. Note that a phenyl group may be bonded to the alkyl group. In addition, M is a central metal and represents either a Group 9 element or a Group 10 element. In addition, Z represents oxygen or sulfur. Further, L represents a monoanionic ligand. In addition, n is 2 when the central metal M is a Group 9 element, or n is 1 when the central metal M is a Group 10 element.

Here, specific examples of the alkyl group having 1 to 4 carbon atoms for any of R¹ to R⁹ include a methyl group, an ethyl group, a propyl group, an isopropyl group, an n-butyl group, a sec-butyl group, an isobutyl group, and a tert-butyl group. Further, specific examples of the alkoxy group having 1 to 4 carbon atoms for R¹ include a methoxy group, an ethoxy group, a propoxy group, an isopropoxy group, an n-butoxy group, a sec-butoxy group, an isobutoxy group, and a tert-butoxy group.

The organometallic complex represented by the above general formula (G3) has a structure, where the general formula (G1) which is a rigid structure including a dibenzofuran skeleton or a dibenzothiophene skeleton which is a ring structure is coordinated, and accordingly has high heat resistance. Consequently, the organometallic complex can be used in a variety of fields, for example, fabrication of light-emitting elements which requires high heat resistance.

Note that the general formula (G3) also shows variations with a wide variety of ligands, since the organometallic complex, which has the structure represented by the general formula (G1) and is formed in such a way that the general formula (G0) is ortho-metalated by an ion of a Group 9 metal or of a Group 10 metal, shows variations with a wider variety of ligands due to the variations of the compounds (A1), (A2), (A1′), and (A2′) used in the scheme (a) and the scheme (a′), as described above.

One embodiment of the present invention is an organometallic complex represented by the general formula (G4) below, which is among the variations with a wide variety of ligands.

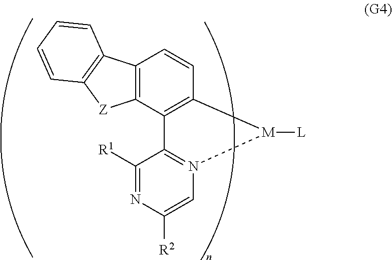

In the above general formula (G4), R¹ represents an alkyl group having 1 to 4 carbon atoms or an alkoxy group having 1 to 4 carbon atoms. Further, R² represents either hydrogen or an alkyl group having 1 to 4 carbon atoms. Note that a phenyl group may be bonded to the alkyl group. In addition, Z represents oxygen or sulfur. Further, M is a central metal and represents either a Group 9 element or a Group 10 element. Further, L represents a monoanionic ligand. In addition, n is 2 when the central metal M is a Group 9 element, or n is 1 when the central metal M is a Group 10 element.

Here, specific examples of the alkyl group having 1 to 4 carbon atoms for R¹ and R² include a methyl group, an ethyl group, a propyl group, an isopropyl group, an n-butyl group, a sec-butyl group, an isobutyl group, and a tert-butyl group. Further, specific examples of the alkoxy group having 1 to 4 carbon atoms for R¹ include a methoxy group, an ethoxy group, a propoxy group, an isopropoxy group, an n-butoxy group, a sec-butoxy group, an isobutoxy group, and a tert-butoxy group.

In the organometallic complex represented by the general formula (G4), the substituents R³, R⁴, R⁵, R⁶, R⁷, R⁸, and R⁹ in the general formula (G3) are hydrogen. Accordingly, steric hindrance of the pyrazine derivative can be reduced so that it can be easily ortho-metalated by the metal ion, which leads to an increase in the synthesis yield of the organometallic complex. Thus, the time and cost for the synthesis can be saved.

### [Synthesis Method and Preferred Modes of Organometallic Complex Represented by General Formula (G5)]

Next, a method of synthesizing the organometallic complex represented by the general formula (G5) below, which is a specific preferred example of the organometallic complex having the structure represented by the general formula (G2), will be described.

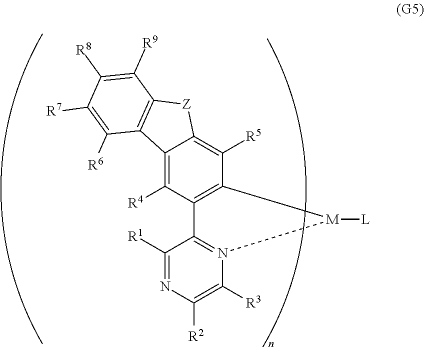

First, as illustrated in a synthesis scheme (e) below, the pyrazine derivative represented by General Formula (G0′) and a compound of a Group 9 metal or of a Group 10 metal which contains a halogen (e.g., a metal halide or a metal complex) are heated with an alcohol-based solvent (e.g., glycerol, ethylene glycol, 2-methoxyethanol, or 2-ethoxyethanol) alone or a mixed solvent of water and one or more kinds of such alcohol-based solvents, so that a binuclear complex (C) can be obtained, which is a kind of organometallic complex including the structure represented, by the general formula (G2). There is no particular limitation on a heating means, and an oil bath, a sand bath, or an aluminum block may be used. Further, heating with microwaves can be used.

Examples of the compounds of a Group 9 or Group 10 metal which contain halogen include, but not limited to, rhodium chloride hydrate, palladium chloride, iridium chloride hydrate, iridium chloride hydrochloride hydrate, potassium tetrachloroplatinate(II), and the like. Note that in the synthesis scheme (e) below, M is a central metal and represents either a Group 9 element or a Group 10 element, and X represents a halogen element. In addition, n is 2 when the central metal M is a Group 9 element, or n is 1 when the central metal M is a Group 10 element. In addition, Z represents oxygen or sulfur. Further, X represents a halogen element.

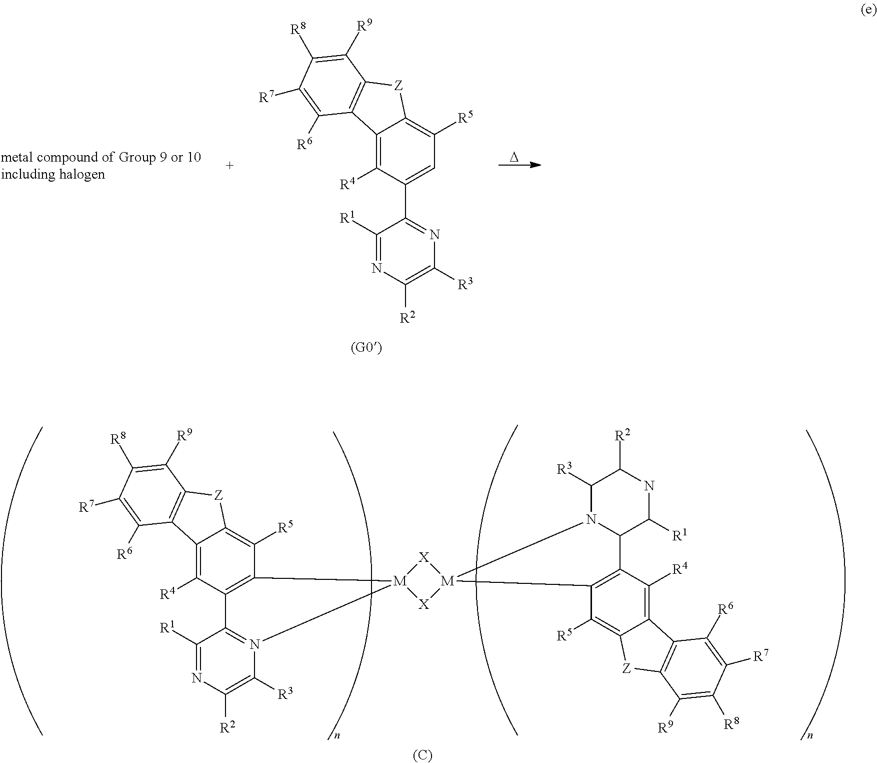

Furthermore, as illustrated in a synthesis scheme (f) below, the binuclear complex (C) obtained by the above synthesis scheme (e) is reacted with HL which is a material of a monoanionic ligand, so that a proton of HL is eliminated and the monoanionic ligand L is coordinated with the central metal M; thus, the organometallic complex represented by the general formula (G5) which is one embodiment of the present invention can be obtained. There is no particular limitation on a heating means, and an oil bath, a sand bath, or an aluminum block may be used. Further, heating with microwaves can be used. Note that in the synthesis scheme (f), the central metal M represents either a Group 9 element or a Group 10 element, and X represents a halogen element. In addition, n is 2 when the central metal M is a Group 9 element, or n is 1 when the central metal M is a Group 10 element. In addition, Z represents oxygen or sulfur. Further, X represents a halogen element.

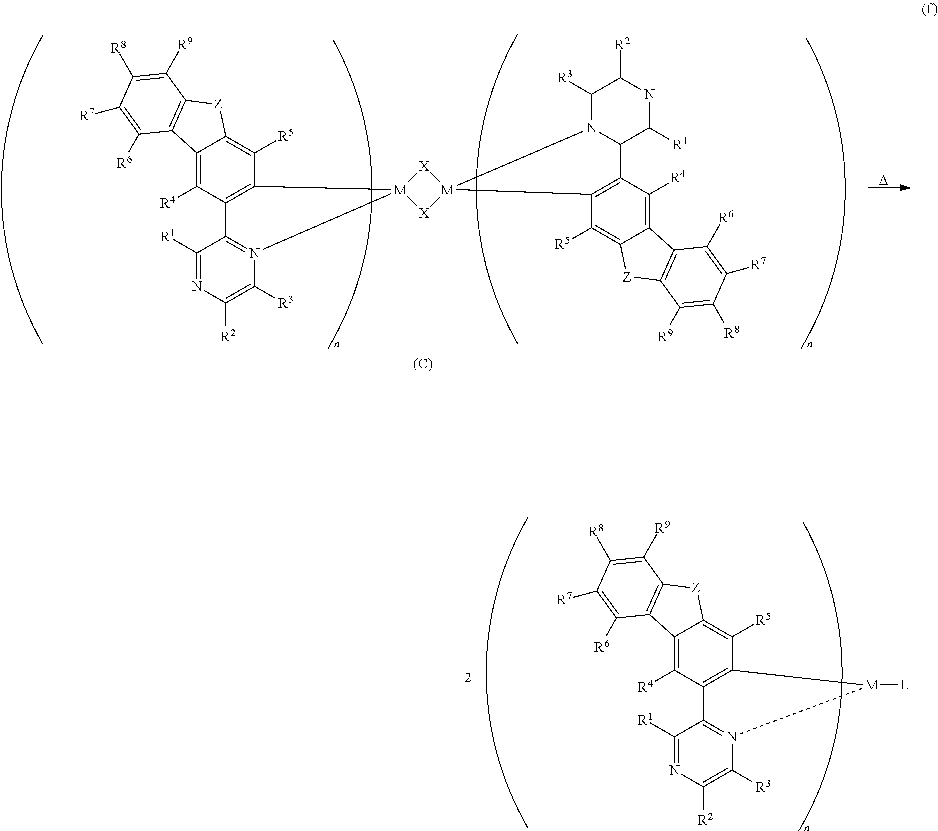

The organometallic complex represented by the general formula (G5) below, which can be synthesized according to the schemes (e) and (f) as described above, is one embodiment of the present invention. The general formula (G5) below is one mode of the organometallic complex having the structure of the general formula (G2), and is easy to synthesize and therefore preferable.

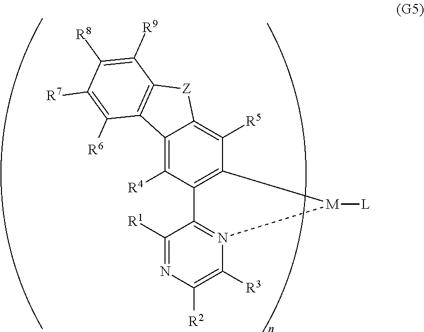

In the above general formula (G5), R¹ represents an alkyl group having 1 to 4 carbon atoms or an alkoxy group having 1 to 4 carbon atoms. Further, R² and R³ separately represent hydrogen or an alkyl group having 1 to 4 carbon atoms. Furthermore, R⁴, R⁵, R⁶, R⁷, R⁸, and R⁹ separately represent hydrogen or an alkyl group having 1 to 4 carbon atoms. Note that a phenyl group may be bonded to the alkyl group. In addition, M is a central metal and represents either a Group 9 element or a Group 10 element. Further, L represents a monoanionic ligand. In addition, n is 2 when the central metal M is a Group 9 element, or n is 1 when the central metal M is a Group 10 element.

Here, specific examples of the alkyl group having 1 to 4 carbon atoms for any of R¹ to R⁹ include a methyl group, an ethyl group, a propyl group, an isopropyl group, an n-butyl group, a sec-butyl group, an isobutyl group, and a tert-butyl group. Further, specific examples of the alkoxy group having 1 to 4 carbon atoms for R¹ include a methoxy group, an ethoxy group, a propoxy group, an isopropoxy group, an n-butoxy group, a sec-butoxy group, an isobutoxy group, and a tert-butoxy group.

The organometallic complex represented by the above general formula (G5) has a structure, where the general formula (G2) which is a rigid structure including a dibenzofuran skeleton or a dibenzothiophene skeleton which is a ring structure is coordinated, and accordingly has high heat resistance. Consequently, the organometallic complex can be used in a variety of fields, for example, fabrication of light-emitting elements which requires high heat resistance.

Note that the general formula (G5) also shows variations with a wide variety of ligands, since the organometallic complex, which is represented by the general formula (G2) and Ruined in such a way that the general formula (G0′) is ortho-metalated by an ion of a Group 9 metal or of a Group 10 metal, shows variations with a wider variety of ligands due to the variations of the compounds (B1), (A2), (B1′), and (A2′) used in the scheme (b) and the scheme (b′), as described above.

One embodiment of the present invention is an organometallic complex represented by the general formula (G6) below, which is among the variations with a wide variety of ligands.

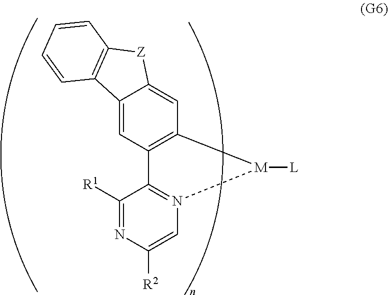

In the above general formula (G6), R¹ represents an alkyl group having 1 to 4 carbon atoms or an alkoxy group having 1 to 4 carbon atoms. Further, R² represents either hydrogen or an alkyl group having 1 to 4 carbon atoms. Note that a phenyl group may be bonded to the alkyl group. In addition, Z represents oxygen or sulfur. Further, M is a central metal and represents either a Group 9 element or a Group 10 element. Further, L represents a monoanionic ligand. In addition, n is 2 when the central metal M is a Group 9 element, or n is 1 when the central metal M is a Group 10 element.

Here, specific examples of the alkyl group having 1 to 4 carbon atoms for R¹ and R² include a methyl group, an ethyl group, a propyl group, an isopropyl group, an n-butyl group, a sec-butyl group, an isobutyl group, and a tert-butyl group. Further, specific examples of the alkoxy group having 1 to 4 carbon atoms for R¹ include a methoxy group, an ethoxy group, a propoxy group, an isopropoxy group, an n-butoxy group, a sec-butoxy group, an isobutoxy group, and a tert-butoxy group.

In the organometallic complex represented by the general formula (G6), the substituents R³, R⁴, R⁵, R⁶, R⁷, R⁸, and R⁹ in the general formula (G5) are hydrogen. Accordingly, steric hindrance of the pyrazine derivative can be reduced so that it can be easily ortho-metalated by the metal ion, which leads to an increase in the synthesis yield of the organometallic complex. Thus, the time and cost for the synthesis can be saved.

### [Specific Examples of Ligand (L)]

Each monoanionic ligand (L) in the above general formulae (G3) to (G6) is preferably any of a monoanionic bidentate chelate ligand having a β-diketone structure, a monoanionic bidentate chelate ligand having a carboxyl group, a monoanionic bidentate chelate ligand having a phenolic hydroxyl group, and a monoanionic bidentate chelate ligand in which two ligand elements are both nitrogen. More preferably, the monoanionic ligand L is a monoanionic ligand represented by any of the structural formulae (L1) to (L6) below. These ligands have high coordination ability and are inexpensively available, and the time and cost for the synthesis can be saved accordingly.

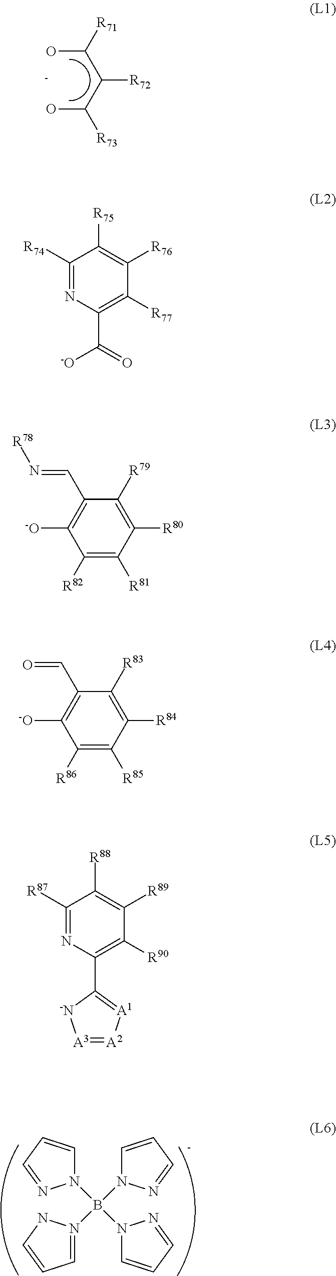

In the above structural formulae (L1) to (L6), R⁷¹ to R⁹⁰ separately represent any of hydrogen, an alkyl group having 1 to 4 carbon atoms, a halogen group, a haloalkyl group, an alkoxy group having 1 to 4 carbon atoms, and an allylthio group having 1 to 4 carbon atoms. In addition, A¹, A², and A³ separately represent nitrogen N or carbon C—R, and R represents hydrogen, an alkyl group having 1 to 4 carbon atoms, a halogen group, a haloalkyl group having 1 to 4 carbon atoms, or a phenyl group.

### [Synthesis Method and Preferred Modes of Organometallic Complex Having Structure Represented by General Formula (G7)]

Next, a method of synthesizing the organometallic complex represented by the general formula (G7) below, which is a specific preferred example of the organometallic complex having the structure represented by the general formula (G1), will be described.

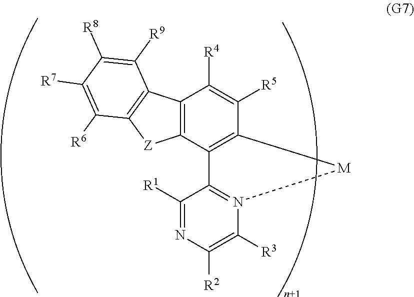

As shown in the synthesis scheme (g) below, the pyrazine derivative represented by the general formula (G0) is mixed with a compound of a Group 9 metal or a Group 10 metal which contains a halogen (e.g., rhodium chloride hydrate, palladium chloride, iridium chloride hydrate, ammonium hexachloroiridate, or potassium tetrachloroplatinate) or with an organometallic complex compound of a Group 9 metal or a Group 10 metal (e.g., an acetylacetonate complex or a diethylsulfide complex) and the mixture is then heated, so that the organometallic complex represented by the above general formula (G7) which is one embodiment of the present invention can be obtained. Further, this heating process may be performed after the pyrazine derivative represented by the general formula (G0) and the compound of a Group 9 metal or a Group 10 metal which contains a halogen or the organometallic complex compound of a Group 9 metal or a Group 10 metal are dissolved in an alcohol-based solvent (e.g., glycerol, ethylene glycol, 2-metoxyethanol, or 2-ethoxyethanol). Note that in the scheme (g), M represents a central metal and represents either a Group 9 element or a Group 10 element. In addition, n is 2 when the central metal M is a Group 9 element, or n is 1 when the central metal M is a Group 10 element. In addition, Z represents oxygen or sulfur. Further, X represents a halogen element.

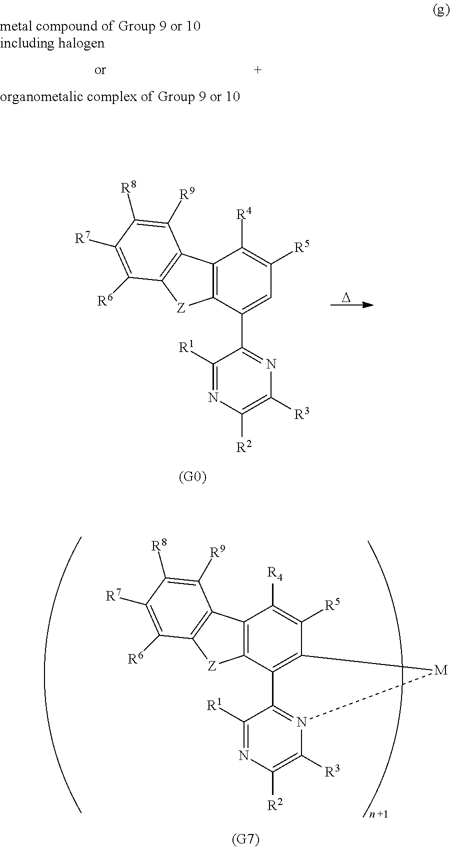

The organometallic complex represented by the general formula (G7) below, which can be synthesized according to the scheme (g) as described above, is one embodiment of the present invention. The general formula (G7) below is one mode of the organometallic complex having the structure of the general formula (G1), and is easy to synthesize and therefore preferable.

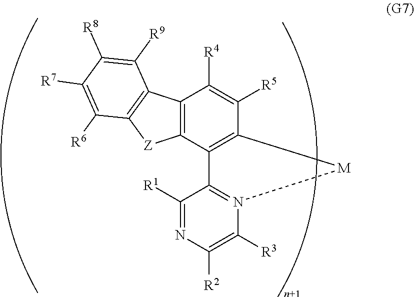

In the above general formula (G7), R¹ represents an alkyl group having 1 to 4 carbon atoms or an alkoxy group having 1 to 4 carbon atoms. Further, R² and R³ separately represent hydrogen or an alkyl group having 1 to 4 carbon atoms. Furthermore, R⁴, R⁵, R⁶, R⁷, R⁸, and R⁹ separately represent hydrogen or an alkyl group having 1 to 4 carbon atoms. Note that a phenyl group may be bonded to the alkyl group. In addition, Z represents oxygen or sulfur. Further, M is a central metal and represents either a Group 9 element or a Group 10 element. In addition, n is 2 when the central metal M is a Group 9 element, or n is 1 when the central metal M is a Group 10 element.

Here, specific examples of the alkyl group having 1 to 4 carbon atoms for any of R¹ to R⁹ include a methyl group, an ethyl group, a propyl group, an isopropyl group, an n-butyl group, a sec-butyl group, an isobutyl group, and a tert-butyl group. Further, specific examples of the alkoxy group having 1 to 4 carbon atoms for R¹ include a methoxy group, an ethoxy group, a propoxy group, an isopropoxy group, an n-butoxy group, a sec-butoxy group, an isobutoxy group, and a tert-butoxy group.

The organometallic complex represented by the above general formula (G7) has a structure, where the general formula (G1) which is a rigid structure including a dibenzofuran skeleton or a dibenzothiophene skeleton which is a ring structure is coordinated, and accordingly has very high heat resistance. Consequently, the organometallic complex can be used in a variety of fields.

Note that the general formula (G7) synthesized with use of the general formula (G0) also shows variations with a wide variety of ligands, since the organometallic complex, which has the structure represented by the general formula (G1) and is fanned in such a way that the general formula (G0) is ortho-metalated by an ion of a Group 9 metal or of a Group 10 metal, shows variations with a wider variety of ligands due to the variations of the compounds (A1), (A2), (A1′), and (A2′) used in the scheme (a) and the scheme (a′), as described above.

One embodiment of the present invention is an organometallic complex represented by the general formula (G8) below, which is among the variations with a wide variety of ligands. The general formula (G8) below is one mode of the organometallic complex represented by the general formula (G7), and is easy to synthesize and therefore preferable.

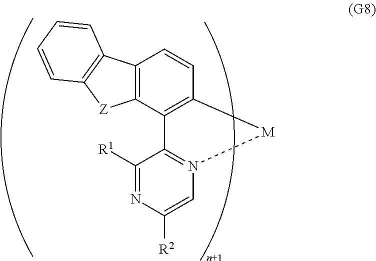

In the above general formula (G8), R¹ represents an alkyl group having 1 to 4 carbon atoms or an alkoxy group having 1 to 4 carbon atoms. Further, R² represents either hydrogen or an alkyl group having 1 to 4 carbon atoms. Note that a phenyl group may be bonded to the alkyl group. In addition, M is a central metal and represents either a Group 9 element or a Group 10 element. In addition, Z represents oxygen or sulfur. Further, n is 2 when the central metal M is a Group 9 element, or n is 1 when the central metal M is a Group 10 element.

Here, specific examples of the alkyl group having 1 to 4 carbon atoms for R¹ and R² include a methyl group, an ethyl group, a propyl group, an isopropyl group, an n-butyl group, a sec-butyl group, an isobutyl group, and a tert-butyl group. Further, specific examples of the alkoxy group having 1 to 4 carbon atoms for R¹ include a methoxy group, an ethoxy group, a propoxy group, an isopropoxy group, an n-butoxy group, a sec-butoxy group, an isobutoxy group, and a tert-butoxy group.

In the organometallic complex represented by the general formula (G8), the substituents R³, R⁴, R⁵, R⁶, R⁷, R⁸, and R⁹ in the general formula (G7) are hydrogen. Accordingly, steric hindrance of the pyrazine derivative can be reduced so that it can be easily ortho-metalated by the metal ion, which leads to an increase in the synthesis yield of the organometallic complex. Thus, the time and cost for the synthesis can be saved.

### [Synthesis Method and Preferred Modes of Organometallic Complex Represented by General Formula (G9)]

Next, a method of synthesizing the organometallic complex represented by the general formula (G9) below, which is a specific preferred example of the organometallic complex having the structure represented by the general formula (G2), will be described.

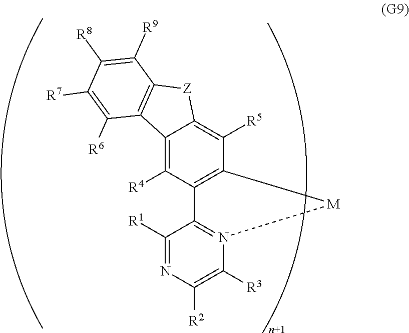

As shown in the synthesis scheme (h) below, the pyrazine derivative represented by the general formula (G0′) is mixed with a compound of a Group 9 metal or a Group 10 metal which contains a halogen (e.g., rhodium chloride hydrate, palladium chloride, iridium chloride hydrate, ammonium hexachloroiridate, or potassium tetrachloroplatinate) or with an organometallic complex compound of a Group 9 metal or a Group 10 metal (e.g., an acetylacetonate complex or a diethylsulfide complex) and the mixture is then heated, so that the organometallic complex represented by the above general formula (G9) which is one embodiment of the present invention can be obtained. Further, this heating process may be performed after the pyrazine derivative represented by the general formula (G0′) and the compound of a Group 9 metal or a Group 10 metal which contains a halogen or the organometallic complex compound of a Group 9 metal or a Group 10 metal are dissolved in an alcohol-based solvent (e.g., glycerol, ethylene glycol, 2-metoxyethanol, or 2-ethoxyethanol). Note that in the scheme (h), M represents a central metal and represents either a Group 9 element or a Group 10 element. In addition, n is 2 when the central metal M is a Group 9 element, or n is 1 when the central metal M is a Group 10 element. In addition, Z represents oxygen or sulfur. Further, X represents a halogen element.

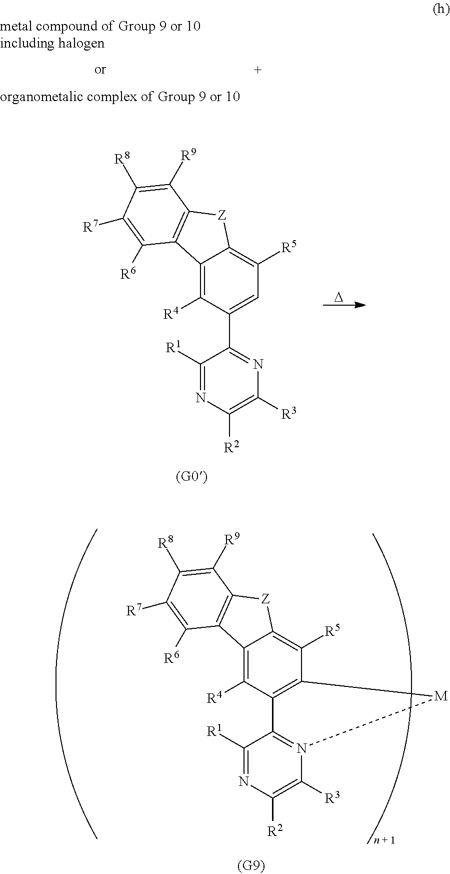

The organometallic complex represented by the general formula (G9) below, which can be synthesized according to the scheme (h) as described above, is one embodiment of the present invention. The general formula (G9) below is one mode of the organometallic complex having the structure of the general formula (G2), and is easy to synthesize and therefore preferable.

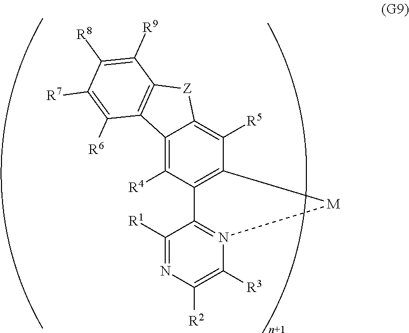

In the above general formula (G9), R¹ represents an alkyl group having 1 to 4 carbon atoms or an alkoxy group having 1 to 4 carbon atoms. Further, R² and R³ separately represent hydrogen or an alkyl group having 1 to 4 carbon atoms. Furthermore, R⁴, R⁵, R⁶, R⁷, R⁸, and R⁹ separately represent hydrogen or an alkyl group having 1 to 4 carbon atoms. Note that a phenyl group may be bonded to the allyl group. In addition, M is a central metal and represents either a Group 9 element or a Group 10 element. In addition, Z represents oxygen or sulfur. Further, n is 2 when the central metal M is a Group 9 element, or n is 1 when the central metal M is a Group 10 element.

Here, specific examples of the alkyl group having 1 to 4 carbon atoms for any of R¹ to R⁹ include a methyl group, an ethyl group, a propyl group, an isopropyl group, an n-butyl group, a sec-butyl group, an isobutyl group, and a tert-butyl group. Further, specific examples of the alkoxy group having 1 to 4 carbon atoms for R¹ include a methoxy group, an ethoxy group, a propoxy group, an isopropoxy group, an n-butoxy group, a sec-butoxy group, an isobutoxy group, and a tert-butoxy group.

The organometallic complex represented by the above general formula (G9) has a structure, where the general formula (G2) which is a rigid structure including a dibenzofuran skeleton or a dibenzothiophene skeleton which is a ring structure is coordinated, and accordingly has very high heat resistance. Consequently, the organometallic complex can be used in a variety of fields.

Note that the general formula (G9) synthesized with use of the general formula (G0′) also shows variations with a wide variety of ligands, since the organometallic complex, which is represented by the general formula (G2) and formed in such a way that the general formula (G0′) is ortho-metalated by an ion of a Group 9 metal or of a Group 10 metal, shows variations with a wider variety of ligands due to the variations of the compounds (B1), (A2), (B1′), and (A2′) used in the scheme (b) and the scheme (b′), as described above.

One embodiment of the present invention is an organometallic complex represented by the general formula (G10) below, which is among the variations with a wide variety of ligands. The general formula (G10) below is one mode of the organometallic complex represented by the general formula (G9), and is easy to synthesize and therefore preferable.

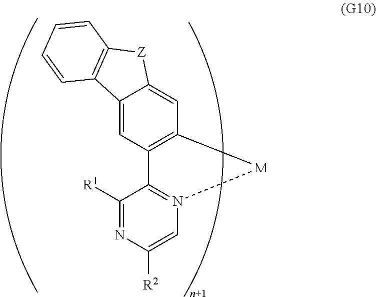

In the above general formula (G10), R¹ represents an alkyl group having 1 to 4 carbon atoms or an alkoxy group having 1 to 4 carbon atoms. Further, R² represents either hydrogen or an alkyl group having 1 to 4 carbon atoms. Note that a phenyl group may be bonded to the alkyl group. In addition, Z represents oxygen or sulfur. Further, M is a central metal and represents either a Group 9 element or a Group 10 element.

Here, specific examples of the alkyl group having 1 to 4 carbon atoms for R¹ and R² include a methyl group, an ethyl group, a propyl group, an isopropyl group, an n-butyl group, a sec-butyl group, an isobutyl group, and a tert-butyl group. Further, specific examples of the alkoxy group having 1 to 4 carbon atoms for R¹ include a methoxy group, an ethoxy group, a propoxy group, an isopropoxy group, an n-butoxy group, a sec-butoxy group, an isobutoxy group, and a tert-butoxy group.

In the organometallic complex represented by the general formula (G10), the substituents R³, R⁴, R⁵, R⁶, R⁷, R⁸, and R⁹ in the general formula (G9) are hydrogen. Accordingly, steric hindrance of the pyrazine derivative can be reduced so that it can be easily ortho-metalated by the metal ion, which leads to an increase in the synthesis yield of the organometallic complex. Thus, the time and cost for the synthesis can be saved.

Although examples of the synthesis methods and modes of the organometallic complexes are described above, organometallic complexes which are disclosed embodiments of the present invention may be synthesized by another synthesis method.

Note that, for more efficient emission of phosphorescence, a metal that provides a heavy atom effect is particularly preferable among Group 9 and Group 10 elements used as the central metal M. Therefore, a feature of one embodiment of the present invention is that the central metal M in the above organometallic complexes which are embodiments of the present invention is iridium or platinum.

Owing to the presence of iridium or platinum, which is a heavy atom, in the organometallic complex, a spin flip due to the heavy atom effect easily occurs. This increases the probability that an electron at the excited singlet level will be transferred by intersystem crossing to the excited triplet level, so that the above organometallic complex can emit phosphorescence efficiently and is a structure that is preferred.

Note that, although there is a heavier element than iridium and platinum among the Group 9 and Group 10 elements that can be used as the central metal M, use of iridium or platinum is preferred in terms of chemical stability, hazard, and the like.

The organometallic complexes which are embodiments of the present invention are each formed by combining the central metal M and the monoanionic ligand L described above, as appropriate. Specific structural formulae of the organometallic complexes which are embodiments of the present invention are given in structural formulae (100) to (151) below. Note that the present invention is not limited to these examples.

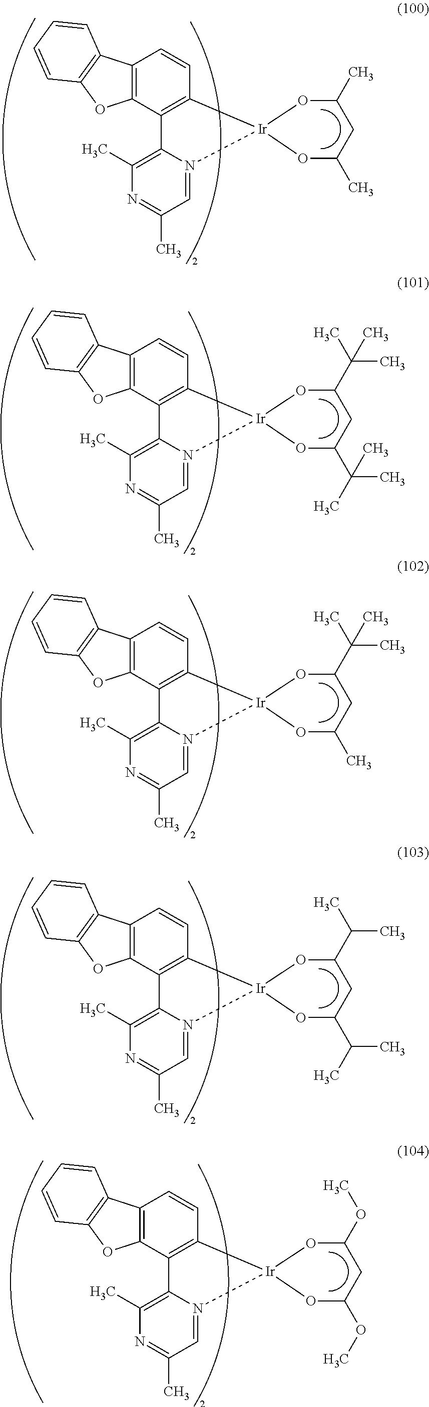

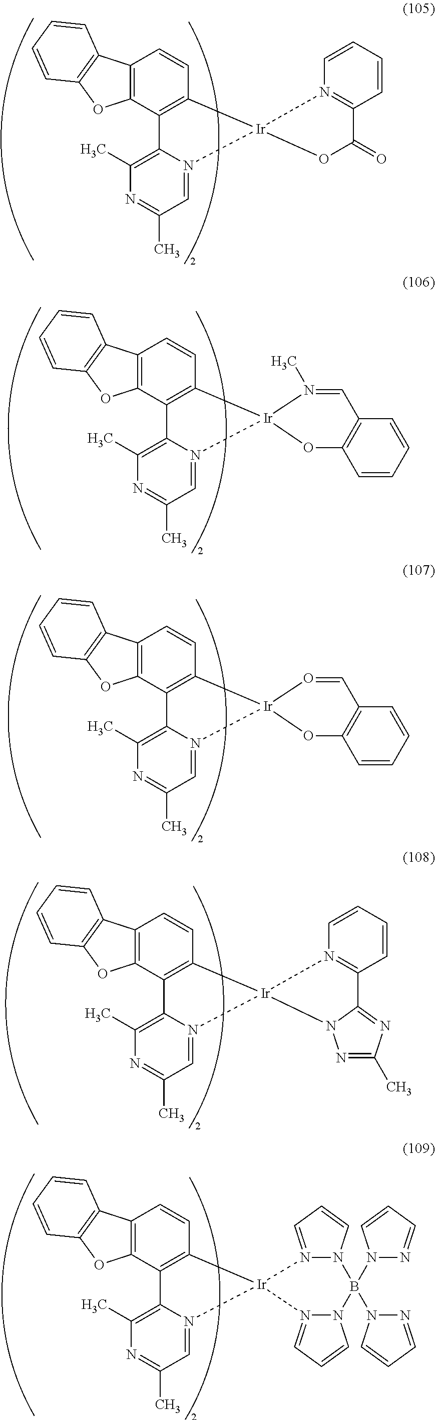

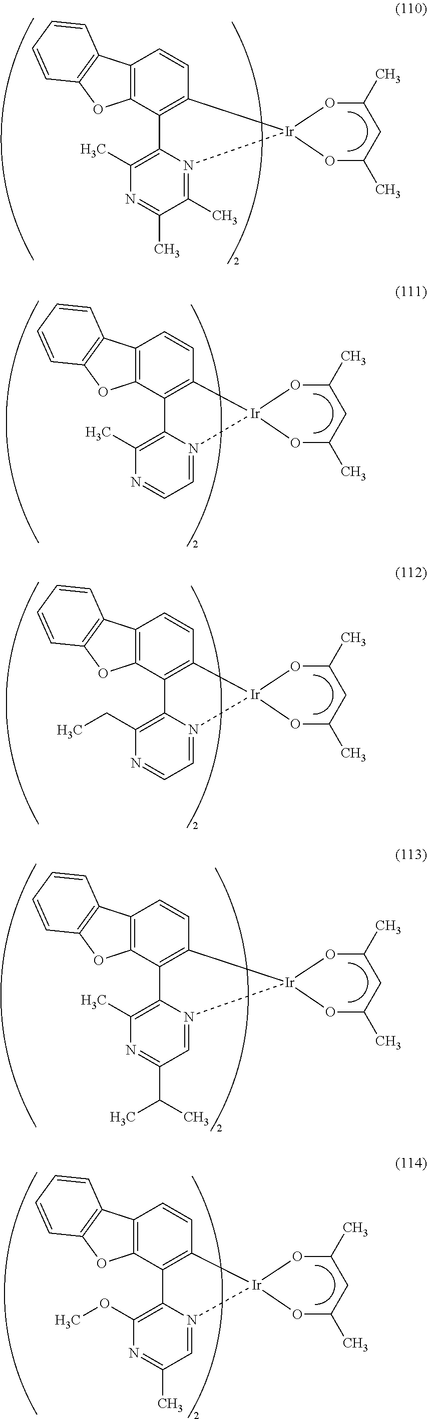

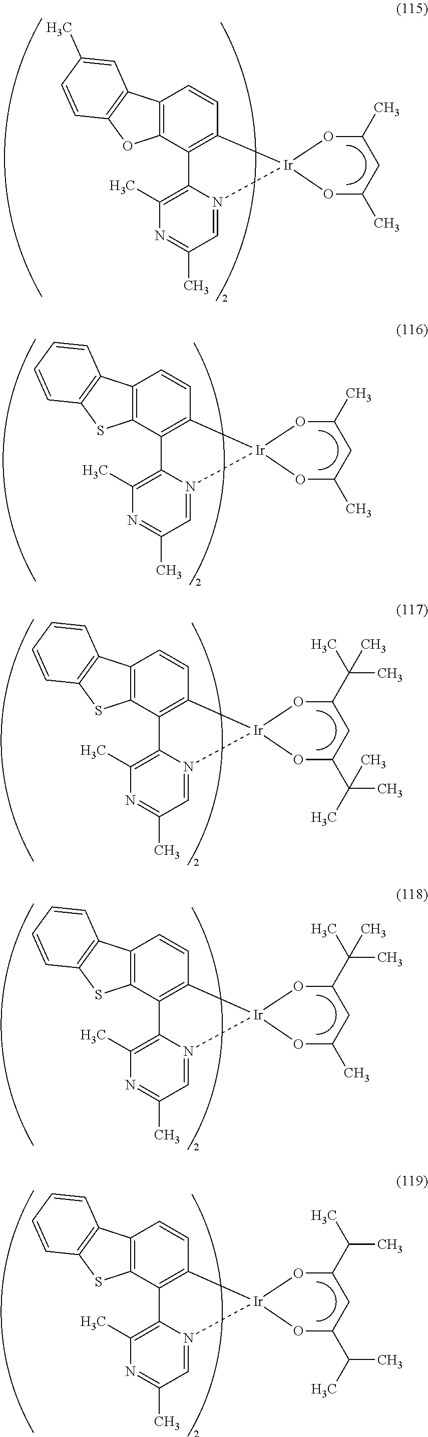

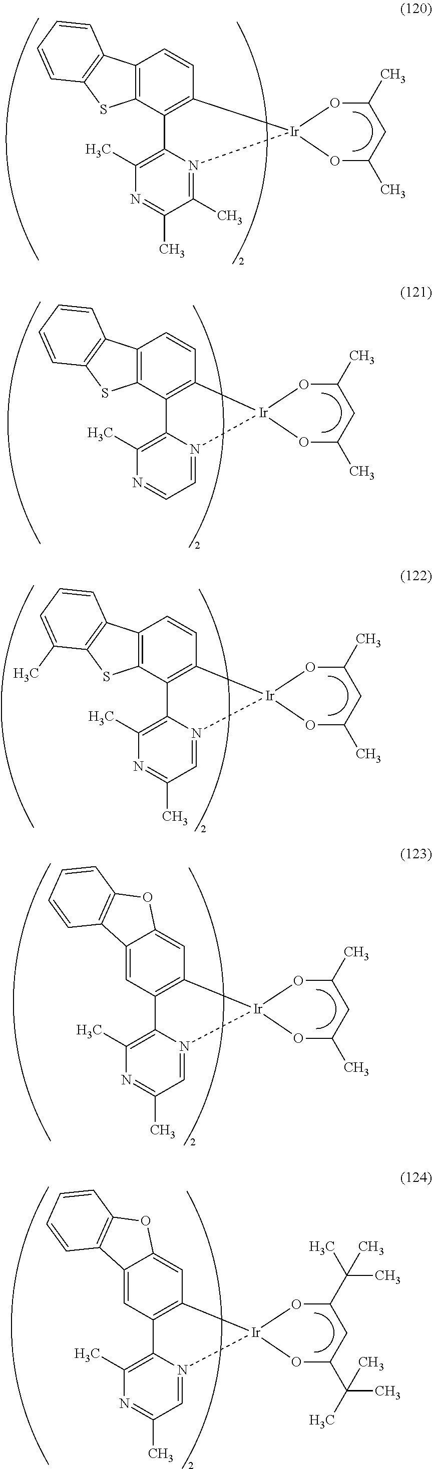

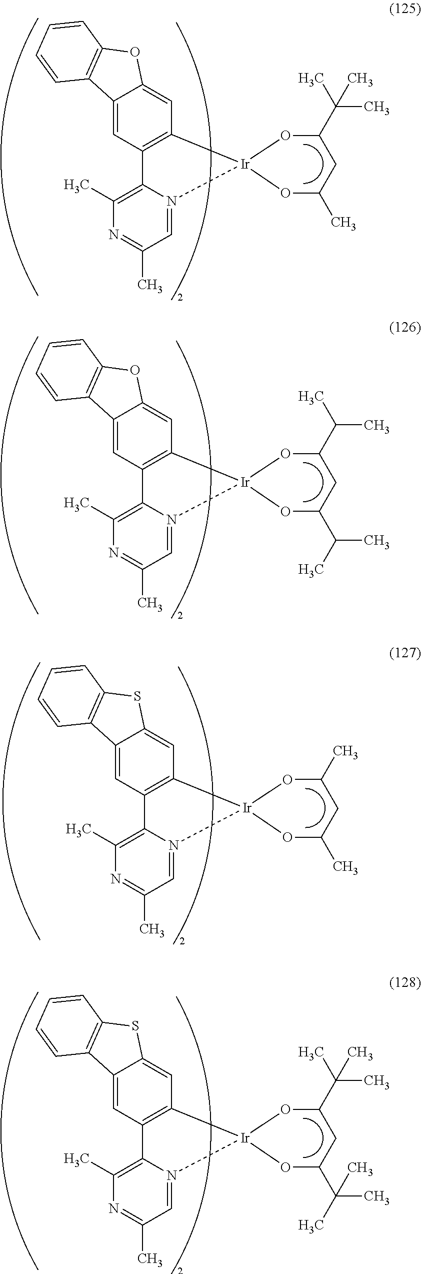

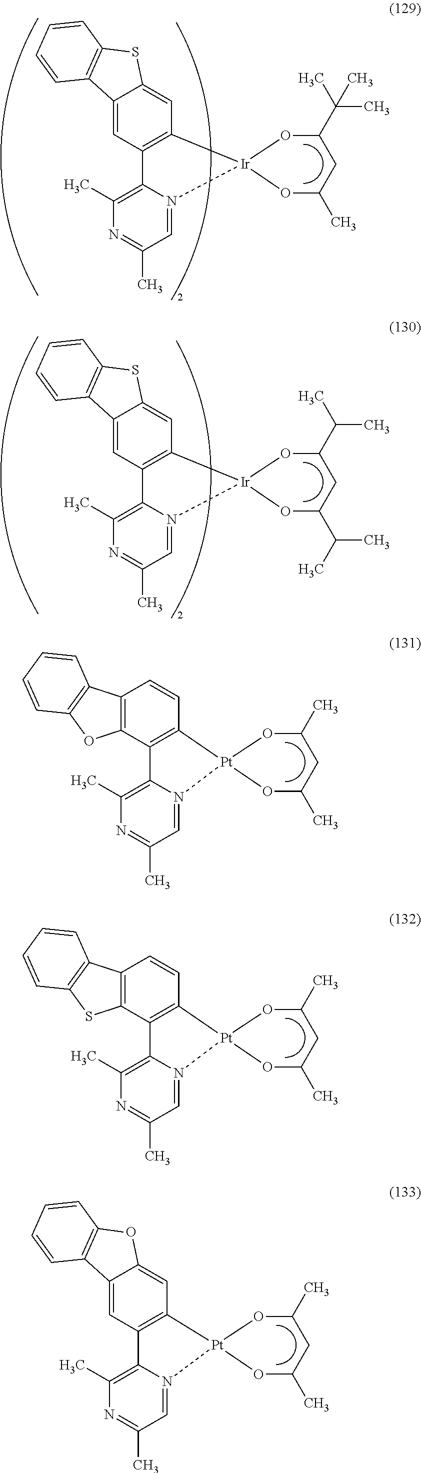

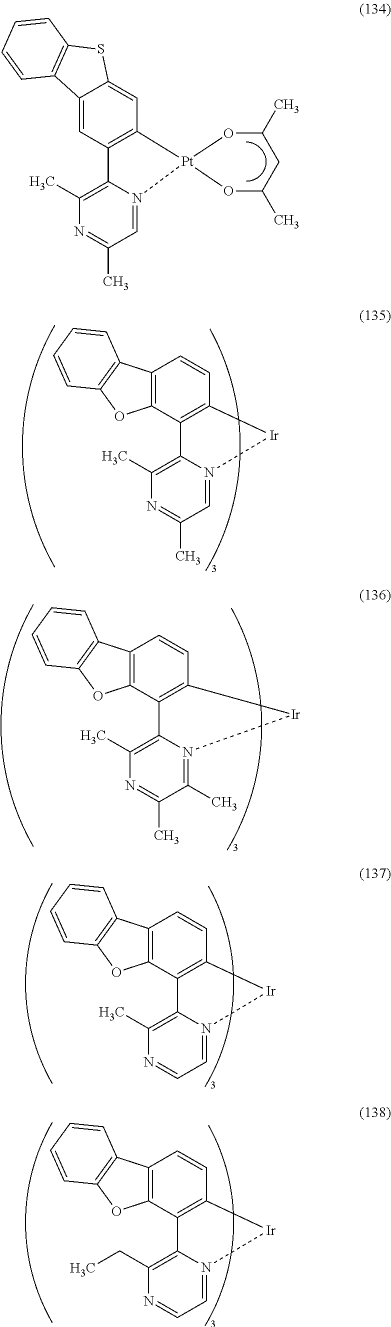

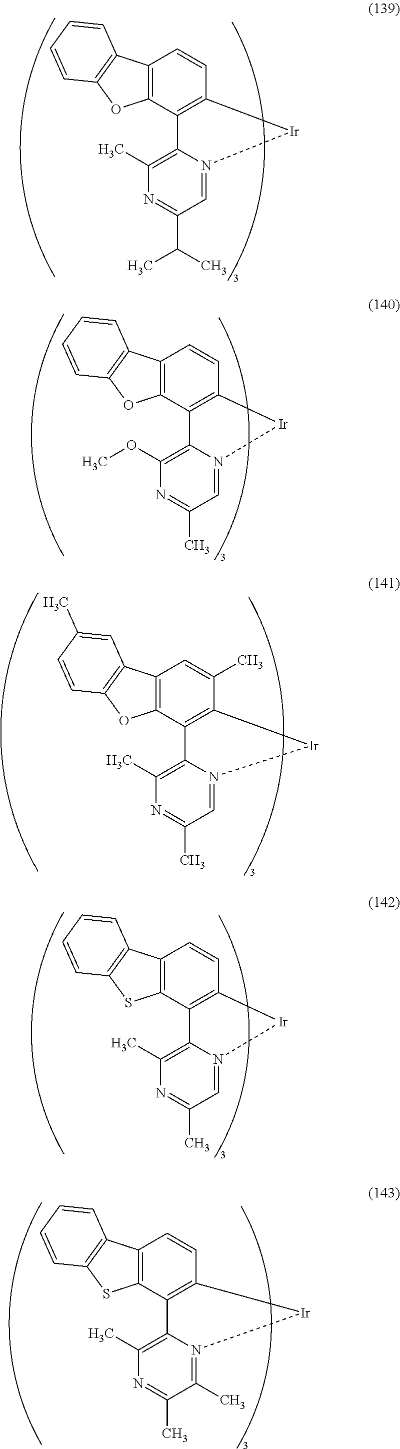

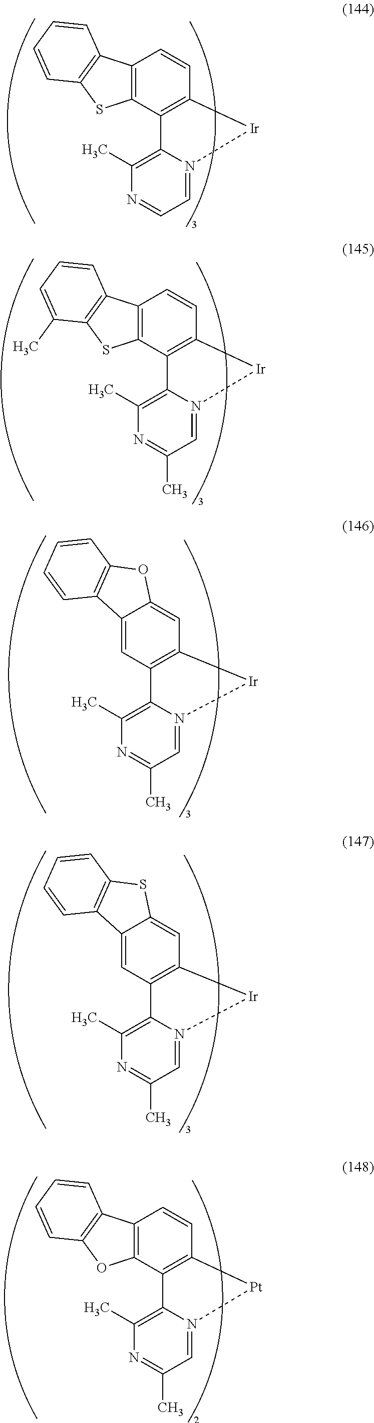

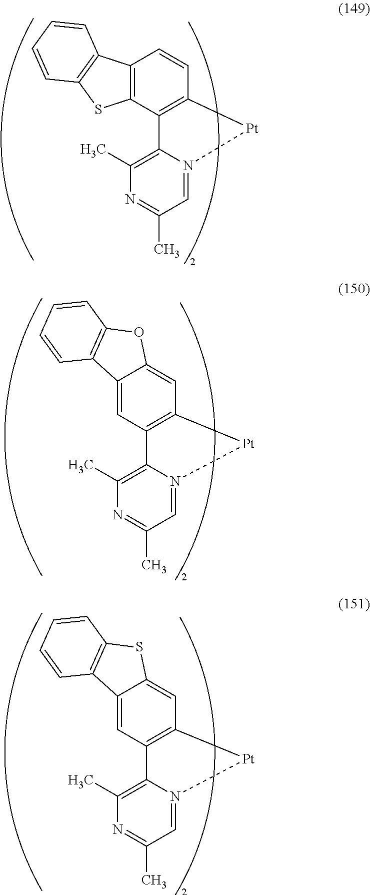

Depending on the type of the ligand, there can be stereoisomers of the organometallic complexes represented by the above structural formulae (100) to (151), and all these isomers are included in the category of the organometallic complexes which are embodiments of the present invention.

Further, the above-described organometallic complexes which are embodiments of the present invention can each be used as a sensitizer owing to the capability of intersystem crossing. Furthermore, since the organometallic complexes are capable of emitting phosphorescence, they can each be used as a light-emitting material or a light-emitting substance for a light-emitting element.

Among those represented by the above structural formulae (100) to (151), methods of synthesizing the organometallic complexes represented by the structural formulae (100), (124), and (135) are described in Example 1, Example 2, and Example 3, respectively. Further, for these three organometallic complexes, the respective Examples also contain results of nuclear magnetic resonance (¹H-NMR) spectroscopy and measurement results of an ultraviolet-visible absorption spectrum (hereinafter, simply referred to as an “absorption spectrum”) and an emission spectrum.

As described in Examples 1 and 2, the absolute quantum yield of the structural formula (100) is 78% and that of the structural formula (124) is 78%. Thus, it can be said that the organometallic complexes described in this embodiment have a high emission quantum yield.

Further, the organometallic complexes represented by the structural formulae (100), (124), and (135) synthesized in Examples 1 to 3 are each a rigid structure having a dibenzofuran skeleton which is a ring structure. Therefore, it can be said that the organometallic complexes described in this embodiment have high heat resistance.

Moreover, as in the methods described in Examples 1 to 3, the organometallic complexes represented by the structural formulae (100), (124), and (135) can be easily produced by using a material that is commercially available or can be synthesized. Therefore, it can be said that the time and cost for the synthesis of the organometallic complexes described in this embodiment can be saved.

### Embodiment 2

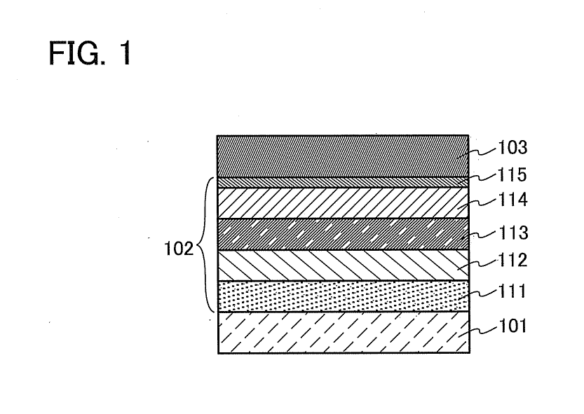

In Embodiment 2, as one embodiment of the present invention, a light-emitting element in which an organometallic complex is used for a light-emitting layer will be described with reference to FIG. 1.

FIG. 1 illustrates a light-emitting element in which an EL layer 102 including a light-emitting layer 113 is interposed between a first electrode 101 and a second electrode 103. The light-emitting layer 113 contains any of the organometallic complexes which are embodiments of the present invention and described in Embodiment 1.

By application of a voltage to such a light-emitting element, holes injected from the first electrode 101 side and electrons injected from the second electrode 103 side recombine in the light-emitting layer 113 to raise the organometallic complex to an excited state. Then, light is emitted when the organometallic complex in the excited state returns to the ground state. Thus, the organometallic complex of one embodiment of the present invention functions as a light-emitting substance in the light-emitting element. Note that in the light-emitting element described in this embodiment, the first electrode 101 functions as an anode and the second electrode 103 functions as a cathode.

When the first electrode 101 functions as an anode, any of metals, alloys, or electrically conductive compounds, mixtures or stacked layers thereof, and the like which has a high work function (specifically, a work function of 4.0 eV or more) is preferably used for the first electrode 101. Specific examples are indium tin oxide (ITO), indium tin oxide containing silicon or silicon oxide, indium zinc oxide (IZO), indium oxide containing tungsten oxide and zinc oxide, and the like. Other than these, gold (Au), platinum (Pt), nickel (Ni), tungsten (W), chromium (Cr), molybdenum (Mo), iron (Fe), cobalt (Co), copper (Cu), palladium (Pd), titanium (Ti), or the like can be used.

Alternatively, an electrically conductive high molecule (an electrically conductive polymer) can be used for the first electrode 101. Specifically, PEDOT (polyethylenedioxythiophene) and the like can be given.

When a layer included in the EL layer 102 which is formed in contact with the first electrode 101 is formed using a later described composite material foamed by combining an organic compound and an electron acceptor (an acceptor), as a substance used for the first electrode 101, any of a variety of metals, alloys, and electrically-conductive compounds, a mixture thereof; and the like can be used regardless of the work function; for example, aluminum (Al), silver (Ag), an alloy containing aluminum (e.g., Al—Si), or the like can also be used.

Note that the first electrode 101 can be formed by, for example, a sputtering method, an evaporation method (including a vacuum evaporation method), or the like. Alternatively, a coating method, a printing method, an inkjet method, or the like can be used.

The EL layer 102 fowled over the first electrode 101 has at least the light-emitting layer 113 and is formed to include any of the organometallic complexes which are embodiments of the present invention. For part of the EL layer 102, a known substance can be used, and either a low molecular compound or a high molecular compound can be used. Note that substances forming the EL layer 102 may consist of organic compounds or may include an inorganic compound as a part.

Further, as illustrated in FIG. 1, the EL layer 102 may include a hole-injection layer 111 containing a substance having a high hole-injection property, a hole-transport layer 112 containing a substance having a high hole-transport property, an electron-transport layer 114 containing a substance having a high electron-transport property, an electron-injection layer 115 containing a substance having a high electron-injection property, and the like in appropriate combination in addition to the light-emitting layer 113.

The hole-injection layer 111 is a layer containing a substance having a high hole-injection property. Examples of the substance having a high hole-injection property which can be used are metal oxides, such as molybdenum oxide, titanium oxide, vanadium oxide, rhenium oxide, ruthenium oxide, chromium oxide, zirconium oxide, hafnium oxide, tantalum oxide, silver oxide, tungsten oxide, and manganese oxide. Alternatively, phthalocyanine-based compounds, such as phthalocyanine (abbreviation: H2Pc) and copper(II) phthalocyanine (abbreviation: CuPc), can be used.

Further, examples of the substance that can be used are aromatic amine compounds which are low molecular organic compounds, such as 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis[N-(4-diphenylaminophenyl)-N-phenylamino]biphenyl (abbreviation: DPAB), 4,4′-bis(N-{4-[N-(3-methylphenyl)-N-phenylamino]phenyl}-N-phenylamino)biphenyl (abbreviation: DNTPD), 1,3,5-tris[N-(4-diphenylaminophenyl)-N-phenylamino]benzene (abbreviation: DPA3B), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), and 3-[N-(1-naphthyl)-N-(9-phenylcarbazol-3-yl)amino]-9-phenylcarbazole (abbreviation: PCzPCN1).

Still other examples of the substance that can be used are high molecular compounds (e.g., oligomers, dendrimers, and polymers), such as poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide] (abbreviation: PTPDMA), and poly[N,N′-bis(4-butylphenyl)-N,N′-bis(phenyl)benzidine] (abbreviation: Poly-TPD), and high molecular compounds to which acid is added, such as poly(3,4-ethylenedioxythiophene)/poly(styrenesulfonic acid) (PEDOT/PSS), and polyaniline/poly(styrenesulfonic acid) (PAni/PSS).

For the hole-injection layer 111, the composite material formed by combining an organic compound and an electron acceptor (also referred to as an acceptor, a generic name for a compound in the state where an electron is easily received, among compounds serving for electron transfer reaction) may be used. Such a composite material is excellent in injection and transport of holes because the action of the electron acceptor enables holes to be generated in the hole-injection layer 111. In this case, the organic compound is preferably a material excellent in transport of the generated holes (a substance having a high hole-transport property).

As the organic compound used for the composite material, any of a variety of compounds, such as aromatic amine compounds, carbazole derivatives, aromatic hydrocarbons, and high molecular compounds (e.g., oligomers, dendrimers, and polymers) can be used. Note that the organic compound used for the composite material is preferably an organic compound having a high hole-transport property. Specifically, a substance having a hole mobility of 10⁻⁶ cm²/Vs or more is preferably used. Further, other than these substances, any substance that has a property of transporting more holes than electrons may be used. Organic compounds that can be used for the composite material will be specifically described below.

Examples of the organic compound that can be used for the composite material are aromatic amine compounds, such as TDATA, MTDATA, DPAB, DNTPD, DPA3B, PCzPCA1, PCzPCA2, PCzPCN1, 4,4′-bis[N-(1-naphthyl)-N-phenylamino]biphenyl (abbreviation: NPB or α-NPD), N,N′-bis(3-methylphenyl)-N,N′-diphenyl-[1,1′-biphenyl]-4,4′-diamine (abbreviation: TPD), and 4-phenyl-4′-(9-phenylfluoren-9-yl)triphenylamine (abbreviation: BPAFLP), and carbazole derivatives, such as 4,4′-di(N-carbazolyl)biphenyl (abbreviation: CBP), 1,3,5-tris[4-(N-carbazolyl)phenyl]benzene (abbreviation: TCPB), 9-[4-(N-carbazolyl)phenyl]-10-phenylanthracene (abbreviation: CzPA), 9-phenyl-3-[4-(10-phenyl-9-anthryl)phenyl]-9H-carbazole (abbreviation: PCzPA), and 1,4-bis[4-(N-carbazolyl)phenyl-2,3,5,6-tetraphenylbenzene.

Other examples of the organic compound that can be used are aromatic hydrocarbon compounds, such as 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 9,10-bis[2-(1-naphthyl)phenyl]-2-tert-butylanthracene, 9,10-bis[2-(1-naphthyl)phenyl]anthracene, and 2,3,6,7-tetramethyl-9,10-di(1-naphthyl)anthracene.

Other examples of the organic compound that can be used are aromatic hydrocarbon compounds, such as 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, 2,5,8,11-tetra(tert-butyl)perylene, pentacene, coronene, 4,4′-bis(2,2-diphenylvinyl)biphenyl (abbreviation: DPVBi), and 9,10-bis[4-(2,2-diphenylvinyl)phenyl]anthracene (abbreviation: DPVPA).

Further, examples of the electron acceptor are organic compounds, such as 7,7,8,8-tetracyano-2,3,5,6-tetrafluoroquinodimethane (abbreviation: F₄-TCNQ) and chloranil, transition metal oxides, and oxides of metals that belong to Groups 4 to 8 in the periodic table. Specific preferred examples include vanadium oxide, niobium oxide, tantalum oxide, chromium oxide, molybdenum oxide, tungsten oxide, manganese oxide, and rhenium oxide because their electron-acceptor properties are high. Among these, molybdenum oxide is especially preferable since it is stable in the air and its hygroscopic property is low and is easily treated.

The composite material may be formed using the above-described electron acceptor and the above-described high molecular compound, such as PVK, PVTPA, PTPDMA, or Poly-TPD, and used for the hole-injection layer 111.

The hole-transport layer 112 is a layer that contains a substance having a high hole-transport property. As the substance having a high hole-transport property, the following aromatic amine compounds can be given: NPB, TPD, BPAFLP, 4,4′-bis[N-(9,9-dimethylfluoren-2-yl)-N-phenylamino]biphenyl (abbreviation: DFLDPBi), 4,4′-bis[N-(spiro-9,9′-bifluoren-2-yl)-N-phenylamino]biphenyl (abbreviation: BSPB), and the like. The substances mentioned here are mainly substances that have a hole mobility of 10⁻⁶ cm²/Vs or more. Note that other than the above substances, any substance that has a property of transporting more holes than electrons may be used. Further, the layer containing a substance having a high hole-transport property is not limited to a single layer, and may be a stack of two or more layers containing any of the above substances.

For the hole-transport layer 112, a carbazole derivative, such as CBP, CzPA, or PCzPA, or an anthracene derivative, such as t-BuDNA, DNA, or DPAnth, may be used.

For the hole-transport layer 112, a high molecular compound, such as PVK, PVTPA, PTPDMA, or Poly-TPD, can be used.

The light-emitting layer 113 is a layer containing any of the organometallic complexes which are embodiments of the present invention, and preferably a layer in which the organometallic complex which is one embodiment of the present invention is dispersed as a guest material in a substance as a host material which has higher triplet excitation energy than the organometallic complex which is one embodiment of the present invention; thus, quenching of light emission from the organometallic complex caused depending on the concentration can be prevented. Note that the triplet excitation energy indicates an energy gap between a ground state and a triplet excited state.

The substance (i.e. host material) used for dispersing any of the above-described organometallic complexes is preferably, but not limited to, any of compounds having an arylamine skeleton, such as 2,3-bis(4-diphenylaminophenyl)quinoxaline (abbreviation: TPAQn) and NPB, carbazole derivatives such as CBP and 4,4′,4″-tris(N-carbazolyetriphenylamine (abbreviation: TCTA), and metal complexes such as bis[2-(2-hydroxyphenyl)pyridinato]zinc (abbreviation: Znpp₂), bis[2-(2-hydroxyphenyl)benzoxazolato]zinc (abbreviation: Zn(BOX)₂), bis(2-methyl-8-quinolinolato)(4-phenylphenolato)aluminum (abbreviation: BAlq), and tris(8-quinolinolato)aluminum (abbreviation: Alq₃). Alternatively, a high molecular compound such as PVK can be used.

The electron-transport layer 114 is a layer containing a substance having a high electron-transport property. For the electron-transport layer 114, metal complexes such as Alg₃, tris(4-methyl-8-quinolinolato)aluminum (abbreviation: Almq₃), bis(10-hydroxybenzo[h]-quinolinato)beryllium (abbreviation: BeBq₂), BAlq, Zn(BOX)₂, and bis[2-(2-hydroxyphenyl)benzothiazolato]zinc (abbreviation: Zn(BTZ)₂) can be given.

Other examples of the substance that can be used are heteroaromatic compounds, such as 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 3-(4-tert-butylphenyl)-4-phenyl-5-(4-biphenylyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), bathophenanthroline (abbreviation: BPhen), bathocuproine (abbreviation: BCP), and 4,4′-bis(5-methylbenzoxazol-2-yl)stilbene (abbreviation: BzOs).

A high molecular compound, such as poly(2,5-pyridinediyl) (abbreviation: PPy), poly[(9,9-dihexylfluorene-2,7-diyl)-co-(pyridine-3,5-diyl)] (abbreviation: PF-Py), or poly[(9,9-dioctylfluorene-2,7-diyl)-co-(2,2′-bipyridine-6,6′-diyl)] (abbreviation: PF-BPy) can also be used.

The substances described above are mainly substances having an electron mobility of 10⁻⁶ cm²/Vs or more. Note that other than the above substances, any substance that has a property of transporting more electrons than holes may be used for the electron-transport layer.

Further, the electron-transport layer 114 is not limited to a single layer, and may be a stack of two or more layers containing any of the above substances.

The electron-injection layer 115 is a layer that contains a substance having a high electron-injection property. Examples of the substance that can be used for the electron-injection layer 115 are alkali metals, alkaline-earth metals, and compounds thereof, such as lithium (Li), cesium (Cs), calcium (Ca), lithium fluoride (LiF), cesium fluoride (CsF), calcium fluoride (CaF₂), and lithium oxide (LiOx), rare earth-metal compounds, such as erbium fluoride (ErF₃), and the above-mentioned substances for forming the electron-transport layer 114.

Alternatively, the composite material formed by combining an organic compound and an electron donor (also referred to as a donor, a generic name for a compound in the state which easily releases an electron, among compounds serving for electron transfer reaction) may be used for the electron-injection layer 115. Such a composite material is excellent in injection and transport of electrons because the action of the electron donor enables electrons to be generated in the organic compound. In this case, the organic compound is preferably a material excellent in transport of the generated electrons; specifically, the above-described substances for forming the electron-transport layer 114 (e.g., a metal complex or a heteroaromatic compound) can be used, for example. The electron donor can be a substance exhibiting an electron-donating property for the organic compound. Specific examples of the electron donor are alkali metals, alkaline-earth metals, and rare earth-metals, such as lithium, cesium, magnesium, calcium, erbium, and ytterbium. Alkali metal oxides and alkaline-earth metal oxides are preferable, examples of which are lithium oxide, calcium oxide, barium oxide, and the like, and a Lewis base such as magnesium oxide or an organic compound such as tetrathiafulvalene (abbreviation: TTF) can be used.

Note that the hole-injection layer 111, the hole-transport layer 112, the light-emitting layer 113, the electron-transport layer 114, and the electron-injection layer 115 which are described above can each be formed by a method, such as an evaporation method (including a vacuum evaporation method), a coating method, a printing method, or an inkjet method.

When the second electrode 103 functions as a cathode, any of metals, alloys, electrically conductive compounds, mixtures thereof, and the like which has a low work function (specifically, a work function of 3.8 eV or less) is preferably used for the second electrode 103. Specific examples of the substance that can be used are elements that belong to Groups 1 and 2 in the periodic table, that is, alkali metals such as lithium (Li) and cesium (Cs), alkaline earth-metals such as magnesium (Mg), calcium (Ca), and strontium (Sr), alloys thereof (e.g., Mg—Ag and Al—Li), rare earth-metals such as europium (Eu) and ytterbium (Yb), alloys thereof, aluminum, silver, and the like.

Alternatively, an electrically conductive high molecule (an electrically conductive polymer) can be used for the second electrode 103. Specifically, PEDOT (polyethylenedioxythiophene) and the like can be given.

When a layer included in the EL layer 102 which is formed in contact with the second electrode 103 is formed using the composite material formed by combining the organic compound and the electron donor (donor), which are described above, a variety of electrically conductive materials such as Al, Ag, ITO, and indium tin oxide containing silicon or silicon oxide can be used regardless of the work function.

Note that when the second electrode 103 is formed, a vacuum evaporation method, a sputtering method, or the like can be used. Alternatively, a coating method, a printing method, an inkjet method, or the like can be used.

In the above-described light-emitting element, a current flows due to a potential difference generated between the first electrode 101 and the second electrode 103 and holes and electrons recombine in the EL layer 102, so that light is emitted. Then, this light emission is extracted outside through one or both of the first electrode 101 and the second electrode 103. Therefore, one or both of the first electrode 101 and the second electrode 103 are electrodes having a property of transmitting visible light (specifically, preferably a visible light transmittance greater than or equal to 50%, more preferably greater than or equal to 80%).

Note that by use of the light-emitting element described in this embodiment, a passive matrix light-emitting device or an active matrix light-emitting device in which driving of the light-emitting element is controlled by a thin film transistor (TFT) can be fabricated.

In fabrication of an active matrix light-emitting device, there is no particular limitation on the structure of the TFT; for example, a staggered TFT or an inverted staggered TFT can be used as appropriate. In addition, a driver circuit formed in a TFT substrate may be formed with an n-type TFT and a p-type TFT, or with either an n-type TFT or a p-type TFT. Further, there is no particular limitation on the crystallinity of a semiconductor film used for the TFT; for example, an amorphous semiconductor film, a crystalline semiconductor film, an oxide semiconductor film, an organic semiconductor film, or the like can be used.

Note that a fabrication method and element characteristics of an example of a light-emitting element fabricated using the structure according to this embodiment are described in Example 4.

As described in Example 4, the light-emitting elements 1 and 2 show external quantum efficiencies of 22% and 23% respectively at a luminance of 1000 cd/m². These values of the external quantum efficiencies both exceed the limit value of the external quantum efficiency of fluorescent compounds. Therefore, it can be said that the organometallic complexes described in this embodiment are capable of emitting phosphorescence.

The above values of the external quantum efficiencies also indicate that the light-emitting elements described in this embodiment have high emission efficiency.

Further, according to the diagram of the relationship between voltage and luminance of the light-emitting elements which is shown in FIG. 18 for Example 4, the light-emitting elements show a luminance of approximately 1000 cd/m² at a voltage of about 3.5 V. Therefore, it can be said that the light-emitting elements described in this embodiment are capable of low voltage driving.

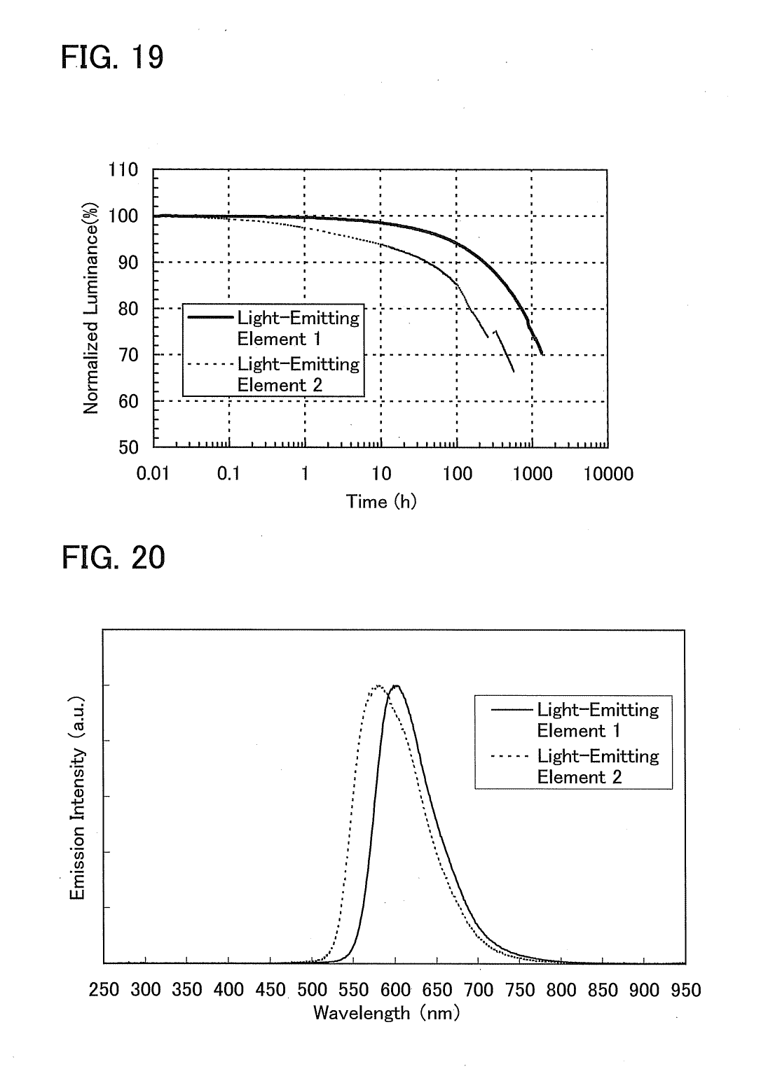

Furthermore, the diagram of the relationship between driving time and normalized luminance of the light-emitting elements, which is shown in FIG. 19 for Example 4, demonstrates that an emission intensity reduction of the light-emitting elements described in this embodiment is small relative to the driving time.

Note that a structure described in this embodiment can be combined with any of the structures described in Embodiment 1 as appropriate. Accordingly, a high-performance light-emitting element, which has high emission efficiency and is capable of low voltage driving and an emission intensity reduction of which is small relative to the driving time, can be fabricated.

### Embodiment 3

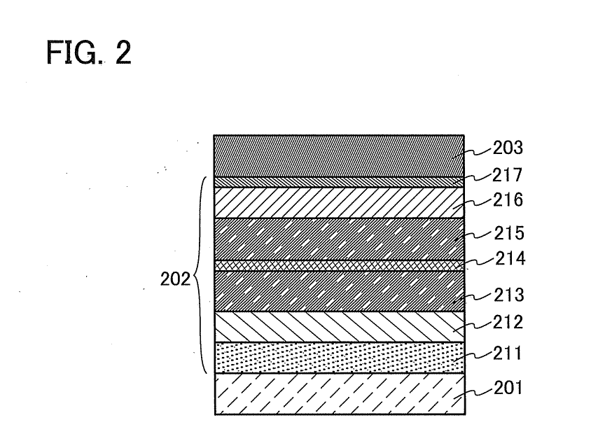

The light-emitting element which is one embodiment of the present invention may have a plurality of light-emitting layers. The plurality of light-emitting layers is provided and light is emitted from each light-emitting layer, so that light emission in which a plurality of light emissions is mixed be obtained. Thus, for example, emission of white light can be obtained. In Embodiment 3, a mode of a light-emitting element having a plurality of light-emitting layers will be described with reference to FIG. 2.

In FIG. 2, an EL layer 202 is provided between a first electrode 201 and a second electrode 203, and a first light-emitting layer 213 and a second light-emitting layer 215 are provided in the EL layer 202. A mixture of light emission from the first light-emitting layer 213 and light emission from the second light-emitting layer 215 can be obtained. Note that there is preferably a separation layer 214 between the first light-emitting layer 213 and the second light-emitting layer 215. In the light-emitting element described in this embodiment, the first electrode 201 functions as an anode and the second electrode 203 functions as a cathode.

When a voltage is applied so that the potential of the first electrode 201 is higher than that of the second electrode 203, a current flows between the first electrode 201 and the second electrode 203, and holes and electrons recombine in at least one of the first light-emitting layer 213, the second light-emitting layer 215, and the separation layer 214. Generated excitation energy is distributed to both the first light-emitting layer 213 and the second light-emitting layer 215 to raise each of a first light-emitting substance contained in the first light-emitting layer 213 and a second light-emitting substance contained in the second light-emitting layer 215 to an excited state. The first and second light-emitting substances each in the excited state emit light while returning to the ground state.

The first light-emitting layer 213 contains the first light-emitting substance, typical examples of which are fluorescent compounds such as perylene, 2,5,8,11-tetra(tert-butyl)perylene (abbreviation: TBP), DPVBi, 4,4′-bis[2-(N-ethylcarbazol-3-yl)vinyl]biphenyl (abbreviation: BCzVBi), BAlq, and bis(2-methyl-8-quinolinolato)gallium chloride (abbreviation: Gamq₂Cl), and phosphorescent compounds such as bis{2-[3,5-bis(trifluoromethyl)phenyl]pyridinato-N,C²′}iridium(III)picolinate (abbreviation: Ir(CF₃ ppy)₂(pic)), bis[2-(4,6-difluorophenyl)pyridinato-N,C²′]iridium(III)acetylacetonate (abbreviation: FIr(acac)), bis[2-(4,6-difluorophenyl)pyridinato-N, C²′]iridium(III)picolinate (abbreviation: FIrpic), and bis[2-(4,6-difuluorophenyl) pyridinato-N,C²′]iridium(III)tetra(1-pyrazolyl)borate (abbreviation: FIr6), to emit light having an emission spectrum with a peak at 450 nm to 510 nm (i.e. blue light to blue green light).

In addition, when the first light-emitting substance is a fluorescent compound, the first light-emitting layer 213 preferably has a structure in which the first light-emitting substance is dispersed as a guest material in a substance as a first host material which has higher singlet excitation energy than the first light-emitting substance. Alternatively, when the first light-emitting substance is a phosphorescent compound, the first light-emitting layer 213 preferably has a structure in which the first light-emitting substance is dispersed as a guest material in a substance as the first host material which has higher triplet excitation energy than the first light-emitting substance. As the first host material, DNA, t-BuDNA, or the like can be used other than NPB, CBP, TCTA, and the like described above. Note that the singlet excitation energy is an energy difference between a ground state and a singlet excited state. In addition, the triplet excitation energy is an energy difference between a ground state and a triplet excited state.

The second light-emitting layer 215 includes any of the organometallic complexes which are embodiments of the present invention and emits yellow light. The second light-emitting layer 215 can have the same structure as the light-emitting layer 113 described in Embodiment 2.

Specifically, the separation layer 214 can be formed using TPAQn, NPB, CBP, TCTA, Znpp₂, ZnBOX or the like described above. Such provision of the separation layer 214 can prevent a defect in which only one of the first light-emitting layer 213 and the second light-emitting layer 215 has excessively high emission intensity. Note that although not necessarily needed, the separation layer 214 can be provided as appropriate to adjust the ratio in emission intensity of the first light-emitting layer 213 to the second light-emitting layer 215.

Although any of the organometallic complexes which are embodiments of the present invention and another light-emitting substance are used for the second light-emitting layer 215 and the first light-emitting layer 213, respectively, in Embodiment 3, any of the organometallic complexes which are embodiments of the present invention and another light-emitting substance may be used for the first light-emitting layer 213 and the second light-emitting layer 215, respectively.

Further, although the light-emitting element in which two light-emitting layers are provided as illustrated in FIG. 2 is described in Embodiment 3, the number of the light-emitting layers is not limited to two and may be three, for example, so that light emissions from the light-emitting layers can be mixed. Thus, emission of white light, for example, can be obtained.

Note that the first electrode 201 can have the same structure as the first electrode 101 described in Embodiment 2. Similarly, the second electrode 203 can have the same structure as the second electrode 103 described in Embodiment 2.

In Embodiment 3, the hole-injection layer 211, the hole-transport layer 212, the electron-transport layer 216, and the electron-injection layer 217 are provided, as illustrated in FIG. 2; as for structures of these layers, the structures of the respective layers described in Embodiment 2 can be applied. However, these layers are not necessarily needed and may be provided as appropriate according to element characteristics.

According to Embodiment 3, light emission in which a plurality of light emissions is mixed can be obtained as described above. Thus, the emission colors of the first light-emitting unit and the second light-emitting unit are made complementary, so that the light-emitting element which emits white light as the whole element can be obtained, for example. Note that the teen “complementary” means color relationship in which an achromatic color is obtained when colors are mixed. That is, a mixture of light emissions with complementary colors gives white light emission.

For example, white light emission can be obtained when any of the organometallic complexes capable of emitting orange phosphorescence, which are embodiments of the present invention in this specification, is used for the first light-emitting layer and a material capable of emitting blue light is used for the second light-emitting layer.

Note that the structure described in Embodiment 3 can be combined with any of the structures described in Embodiments 1 and 2 as appropriate. Accordingly, a high-performance light-emitting element, which has features such as light emission with a variety of colors, high emission efficiency, low voltage driving, and a small emission intensity reduction relative to the driving time, can be fabricated.

### Embodiment 4

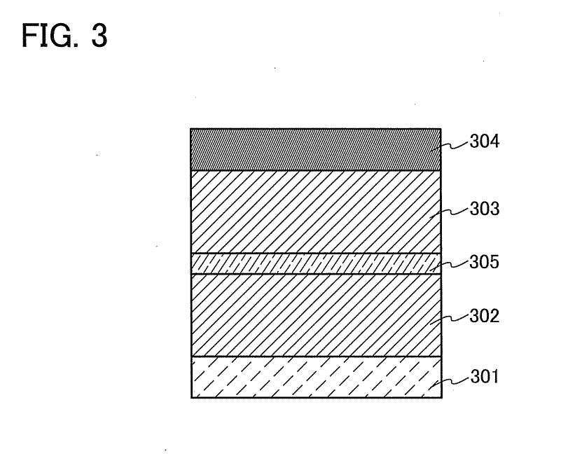

In Embodiment 4, as one embodiment of the present invention, a structure of a light-emitting element which includes a plurality of EL layers (hereinafter, referred to as a stacked-type element) will be described with reference to FIG. 3. This light-emitting element is a stacked-type light-emitting element having a plurality of EL layers (a first EL layer 302 and a second EL layer 303) between a first electrode 301 and a second electrode 304. Note that the number of the EL layers is two in this embodiment but may be three or more.

In this embodiment, the first electrode 301 functions as an anode, and the second electrode 304 functions as a cathode. Note that the first electrode 301 and the second electrode 304 can each have the same structures as in Embodiment 2. Further, all or any of the plurality of EL layers (the first EL layer 302 and the second EL layer 303) may have the same structure as the EL layer described in Embodiment 2. In other words, the structures of the first EL layer 302 and the second EL layer 303 may be the same as or different from each other.

Further, a charge generation layer 305 is provided between the plurality of EL layers (the first EL layer 302 and the second EL layer 303). The charge generation layer 305 has a function of injecting electrons into one of the EL layers and injecting holes into the other of the EL layers when a voltage is applied to the first electrode 301 and the second electrode 304. In this embodiment, the case where a voltage is applied so that the potential of the first electrode 301 is higher than that of the second electrode 304 is described; in this case, the charge generation layer 305 injects electrons into the first EL layer 302 and injects holes into the second EL layer 303.

Note that the charge generation layer 305 preferably has a property of transmitting visible light (specifically, preferably a visible light transmittance greater than or equal to 50%, more preferably greater than or equal to 80%) in terms of light extraction efficiency. Further, the charge generation layer 305 functions even if it has lower electrical conductivity than the first electrode 301 or the second electrode 304.

For the charge generation layer 305, a structure containing an organic compound having a high hole-transport property and an electron acceptor (an acceptor) should be used, or a structure containing an organic compound having a high electron-transport property and an electron donor (a donor) may be used. A structure in which both the structures are stacked may be used.

In the case of the structure in which the electron acceptor is added to the organic compound having a high hole-transport property, examples of the substance that can be used as the organic compound having a high hole-transport property are aromatic amine compounds such as NPB, TPD, TDATA, MTDATA, and 4,4′-bis[N-(spiro-9,9′-bifluoren-2-yl)-N-phenylamino]biphenyl (abbreviation: BSPB), and the like. The substances mentioned here are mainly substances that have a hole mobility of 10⁻⁶ cm²/Vs or more. Note that other than the above substances, any substance that has a property of transporting more holes than electrons may be used.

In addition, examples of the electron acceptor are 7,7,8,8-tetracyano-2,3,5,6-tetrafluoroquinodimethane (abbreviation: F₄-TCNQ), chloranil, oxides of transition metals, and oxides of metals that belong to Groups 4 to 8 in the periodic table, and the like. Specific preferred examples include vanadium oxide, niobium oxide, tantalum oxide, chromium oxide, molybdenum oxide, tungsten oxide, manganese oxide, and rhenium oxide because of their high electron-acceptor properties. Among these, especially molybdenum oxide is preferable since it is stable in the air and its hygroscopic property is low and is easily treated.

Further, in the case of the structure in which the electron donor is added to the organic compound having a high electron-transport property, examples of the organic compound having a high electron-transport property which can be used are metal complexes having a quinoline skeleton or a benzoquinoline skeleton such as Alq, Almq₃, BeBq₂, and BAlq, metal complexes having an oxazole-based ligand or a thiazole-based ligand, such as Zn(BOX)₂ and Zn(BTZ)₂, and the like. Examples other than the metal complexes are PBD, OXD-7, TAZ, BPhen, BCP, and the like. The substances described here are mainly substances having an electron mobility of 10⁻⁶ cm²/Vs or more. Note that other than the above substances, any organic compound that has a property of transporting more electrons than holes may be used.

Examples of the electron donor that can be used are alkali metals, alkaline-earth metals, rare-earth metals, metals that belong to Group 13 in the periodic table and oxides or carbonates thereof, and preferably specifically lithium (Li), cesium (Cs), magnesium (Mg), calcium (Ca), ytterbium (Yb), indium (In), lithium oxide, cesium carbonate, and the like. An organic compound such as tetrathianaphthacene may be used as the electron donor.

By forming the charge generation layer 305 with any of the above materials, it is possible to suppress an increase in drive voltage caused when the EL layers are stacked.

Although the light-emitting element having two EL layers is described in this embodiment, a light-emitting element in which three or more EL layers are stacked can also be used. When a plurality of EL layers with a charge generation layer interposed therebetween are arranged between a pair of electrodes, as in the light-emitting element of this embodiment, light emission in a high luminance region can be obtained. Thus, current density can be kept low, and an element having a long lifetime can be realized.

Since a voltage drop due to the resistance of an electrode material can be reduced by using this embodiment as described above, uniform light emission in a large area can be obtained. Moreover, owing to the capability of low-voltage driving, a light-emitting device with low power consumption can be realized.

Furthermore, by making the emission colors of the EL layers different, a desired emission color can be obtained. For example, white light emission can be obtained by a mixture of lights from the first and second EL layers whose emission colors are made complementary colors, as in Embodiment 2.

Further, the same can be applied to a light-emitting element having three EL layers as well. For example, the light-emitting element as a whole can emit white light when the emission color of the first EL layer is red, the emission color of the second EL layer is green, and the emission color of the third EL layer is blue.

Note that the structure described in this embodiment can be combined with any of the structures described in Embodiments 1 to 3 as appropriate. Accordingly, a high-performance light-emitting element, which can realize light emission with a variety of colors, has high emission efficiency and low power consumption, and is capable of low voltage driving and uniform light emission and an emission intensity reduction of which is small relative to the driving time, can be fabricated.

### Embodiment 5

In Embodiment 5, as one embodiment of the present invention, one mode of a light-emitting element in which an organometallic complex is used as a sensitizer will be described with reference to FIG. 1.

FIG. 1 illustrates the light-emitting element in which the EL layer 102 including the light-emitting layer 113 is interposed between the first electrode 101 and the second electrode 103. The light-emitting layer 113 includes any of the organometallic complexes which are embodiments of the present invention and a fluorescent compound that can emit light having, a longer wavelength than light emitted from this organometallic complex.

In such a light-emitting element, holes injected from the first electrode 101 and electrons injected from the second electrode 103 side recombine in the light-emitting layer 113 to raise the fluorescent compound to an excited state. When the fluorescent compound in the excited state returns to the ground state, light is emitted. At this time, the organometallic complex which is one embodiment of the present invention acts as a sensitizer for the fluorescent compound, and increases the number of fluorescent compound molecules in a singlet excited state. With use of the organometallic complex of the present invention as a sensitizer in this manner, a light-emitting element having high emission efficiency can be obtained. Note that in the light-emitting element of this embodiment, the first electrode 101 functions as an anode and the second electrode 103 function as a cathode.

The light-emitting layer 113 includes the organometallic complex which is one embodiment of the present invention and the fluorescent compound that can emit light having a longer wavelength than light emitted from this organometallic complex. Preferably, the organometallic complex and the fluorescent compound are dispersed as guests in a substance used as a host material which has higher singlet excitation energy than that of the fluorescent substance as well as higher triplet excitation energy than that of the organometallic complex.

Note that there is no particular limitation on the substance (i.e. host material) used to disperse the organometallic complex and the fluorescent compound, and the substances given as examples of the host material in Embodiment 2, or the like can be used.

Although there is also no particular limitation on the fluorescent compound, preferable examples thereof are compounds which can emit red light to infrared light such as 4-dicyanomethylene-2-isopropyl-6-[2-(1,1,7,7-tetramethyljulolidin-9-yl)ethenyl]-4H-pyran (abbreviation: DCJTI), magnesium phthalocyanine, magnesium porphyrin, phthalocyanine and the like.

Note that the first electrode 101 described in Embodiment 5 can have the same structure as the first electrode described in Embodiment 2 and the second electrode 103 in this embodiment can have the same structure as the second electrode described in Embodiment 2.

Further, the hole-injection layer 111, the hole-transport layer 112, the electron-transport layer 114, and the electron-injection layer 115 are provided as illustrated in FIG. 1 in Embodiment 5, and as for structures of these layers, the structures of the respective layers described in Embodiment 2 can be applied. However, these layers are not necessarily needed, and can be provided as appropriate depending on element characteristics.

As described above, according to Embodiment 5, any of the organometallic complexes which are embodiments of the present invention can each be used as a sensitizer so that light emission with high efficiency can be obtained.

Note that the structure described in Embodiment 5 can be combined with any of the structures described in Embodiments 1 to 4 as appropriate.

### Embodiment 6

In Embodiment 6, as one embodiment of the present invention, a passive matrix light-emitting device and an active matrix light-emitting device each of which is a light-emitting device fabricated using a light-emitting element will be described.

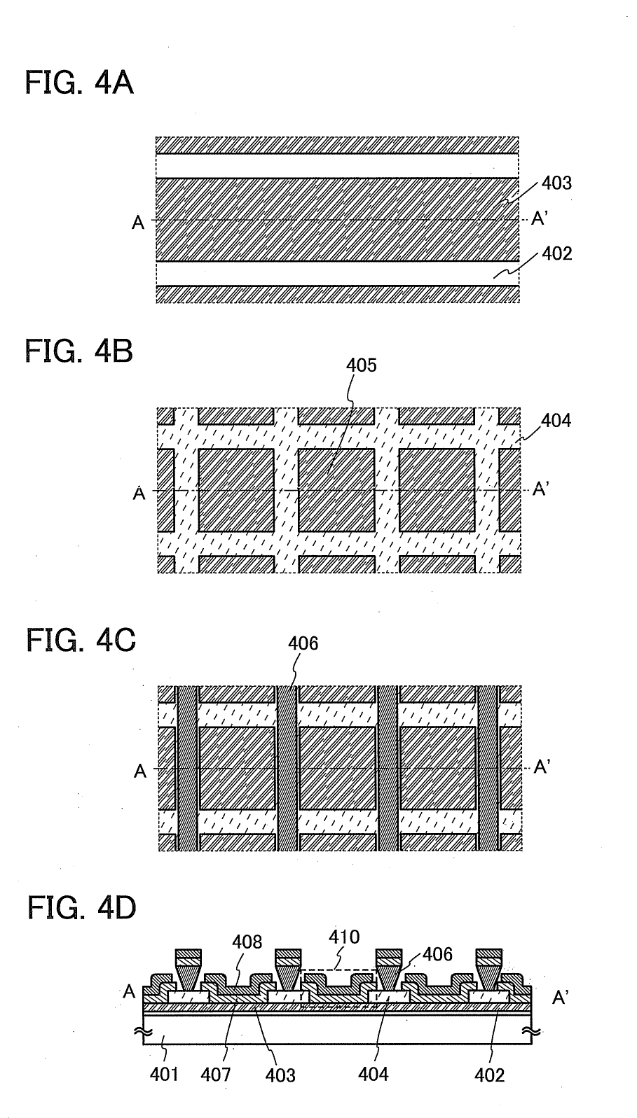

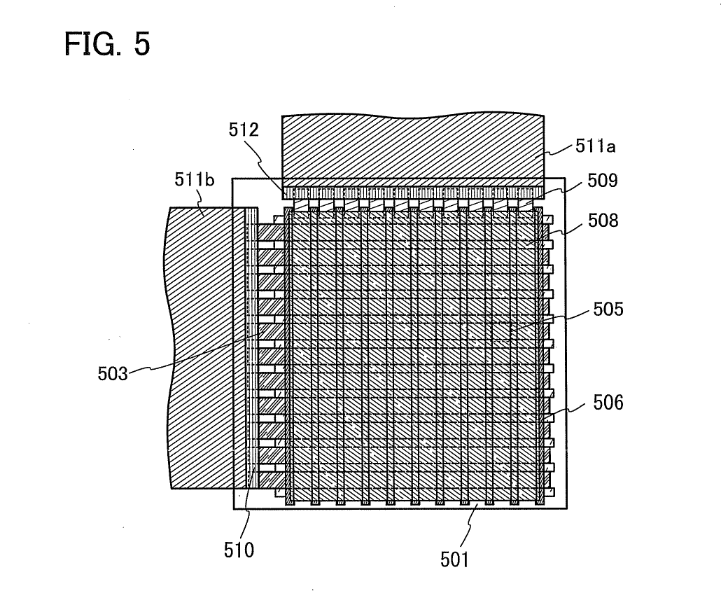

Examples of the passive matrix light-emitting device are illustrated in FIGS. 4A to 4D and FIG. 5.

In the passive matrix (also called simple matrix) light-emitting device, a plurality of anodes arranged in stripes (in stripe form) is provided to intersect at right angles with a plurality of cathodes arranged in stripes. At intersections of the anodes and the cathodes, a light-emitting layer is interposed. Thus, light is emitted from a pixel at the intersection of an anode which is selected (to which a voltage is applied) and a cathode which is selected.

FIGS. 4A to 4C are top views of a pixel portion before sealing, and FIG. 4D is a cross-sectional view taken along a dashed line A-A′ in FIG. 4C.

First, over a substrate 401, an insulating layer 402 is formed as a base insulating layer. Note that the base insulating layer 402 is not necessarily formed if not needed. Over the insulating layer 402, a plurality of first electrodes 403 is arranged in stripes at regular intervals (see FIG. 4A).

Next, a first partition 404 having openings each corresponding to a pixel is provided over the first electrodes 403. Note that the first partition 404 having the openings is formed of an insulating material (a photosensitive or nonphotosensitive organic material (e.g., polyimide, acrylic, polyamide, polyimide amide, resist, or benzocyclobutene) or an SOG film (e.g., a SiOₓ film containing an alkyl group)). Note that openings corresponding to the pixels serve as light-emitting regions 405 (see FIG. 4B).

Next, over the first partition 404 having the openings, a plurality of second partitions 406 which are reversely tapered and parallel to each other is provided to intersect with the first electrodes 403 (see FIG. 4C). The second partitions 406 which are reversely tapered are formed by a photolithography method.

After the second partitions 406 which are reversely tapered are formed as illustrated in FIG. 4C, an EL layer 407 and a second electrode 408 are sequentially formed as illustrated in FIG. 4D. Note that the sum of the heights of the first partition 404 having the openings and the second partition 406 which is reversely tapered is set to exceed the sum of the thicknesses of the EL layer 407 and the second electrode 408. Consequently, as illustrated in FIG. 4D, a plurality of divided regions each including the EL layer 407 and the second electrode 408 is formed. Note that the plurality of divided regions 410 is electrically isolated from one another.

The second electrodes 408 are electrodes that extend in the direction in which they intersect with the first electrodes 403 and that are arranged in stripes to be parallel to one another. Although a part of a material for forming the EL layer 407 and a part of a conductive layer for forming the second electrode 408 are formed even over the second partition 406 which is reversely tapered, these parts are electrically isolated from the divided regions 410.

Note that there is no limitation on the first electrode 403 and the second electrode 408 in this embodiment as far as one of them is an anode and the other is a cathode. Further, the stack structure of the EL layer 407 can be adjusted as appropriate depending on the polarities of the electrodes.

Further, if necessary, a sealing material such as a sealing can or a glass substrate may be attached to the substrate 401 to perform sealing with an adhesive such as a sealant so that a light-emitting element is placed in the sealed space. This can prevents deterioration of the light-emitting element. Note that the sealed space may be filled with a filler or a dry inert gas. Further, a desiccant or the like is put between the substrate and the sealing material to prevent deterioration of the light-emitting element due to moisture or the like, and accordingly, the desiccant removes a minute amount of moisture to perform sufficient desiccation. Note that the desiccant can be a substance that absorbs moisture by chemical adsorption, such as an oxide of an alkaline-earth metal typified by calcium oxide or barium oxide. As a desiccant other than the above, a substance that adsorbs moisture by physical adsorption, such as zeolite or silica gel, may be used.

FIG. 5 is a top view of the passive matrix light-emitting device using a structure illustrated in FIG. 4D, on which an FPC and the like are mounted.

In FIG. 5, scan lines and data lines intersect at right angles in the pixel portion (corresponding to the light-emitting region in FIG. 4B) for displaying images.

Here, the first electrode 403 in FIGS. 4A to 4D corresponds to a scan line 503 in FIG. 5, the second electrode 408 in FIGS. 4A to 4D corresponds to a data line 508 in FIG. 5, and the second partition 406 which is reversely tapered corresponds to a second partition 506. The EL layer 407 in FIGS. 4A to 4D is interposed between the data lines 508 and the scan lines 503, and an intersection indicated as a region 505 corresponds to one pixel.

Note that the data lines 508 are electrically connected at their ends to connection wirings 509, and the connection wirings 509 are connected to an FPC 511a via an input terminal 512. In addition, the scan lines 503 are connected to an FPC 511b via an input terminal 510.

If necessary, an optical film such a polarizing plate, a circularly polarizing plate (including an elliptically polarizing plate), a retardation plate (a quarter-wave plate or a half-wave plate) or a color filter, or a micro lens array may be provided as appropriate on the emission side. Note that the polarizing plate or the circularly polarizing plate may be provided with an anti-reflection film. For example, projections and depressions are provided on a surface of the emission side to diffuse reflected light caused by light entering the emission side from the outside of the light-emitting device so that glare can be reduced (also referred to as an anti-glare treatment). Further, devising the form of the projections and depressions provided on a surface of the emission side (e.g., regular arrangement of hemicycle lenses) can enhance the efficiency of light extraction from the light-emitting layer to the outside (so-called light extraction efficiency).

Note that, although FIG. 5 illustrates an example in which a driver circuit is not provided over the substrate 501, an IC chip including a driver circuit may be mounted on the substrate 501.

When the IC chip is mounted, in the peripheral (outside) region of the pixel portion, ICs, in which a driver circuit for transmitting a signal to the pixel portion is formed, are mounted on the data line side and/or the scan line side by a COG method. As the mounting technique other than the COG method, a TCP or a wire bonding method may be used. The TCP is obtained by mounting an IC on a TAB tape in such a way that the TAB tape is connected to a wiring over an element formation substrate and the IC is mounted. The ICs on the data line side and the scan line side may be formed using a silicon substrate, or may be obtained by formation of a driver circuit with a TFT over a glass substrate, a quartz substrate, or a plastic substrate.

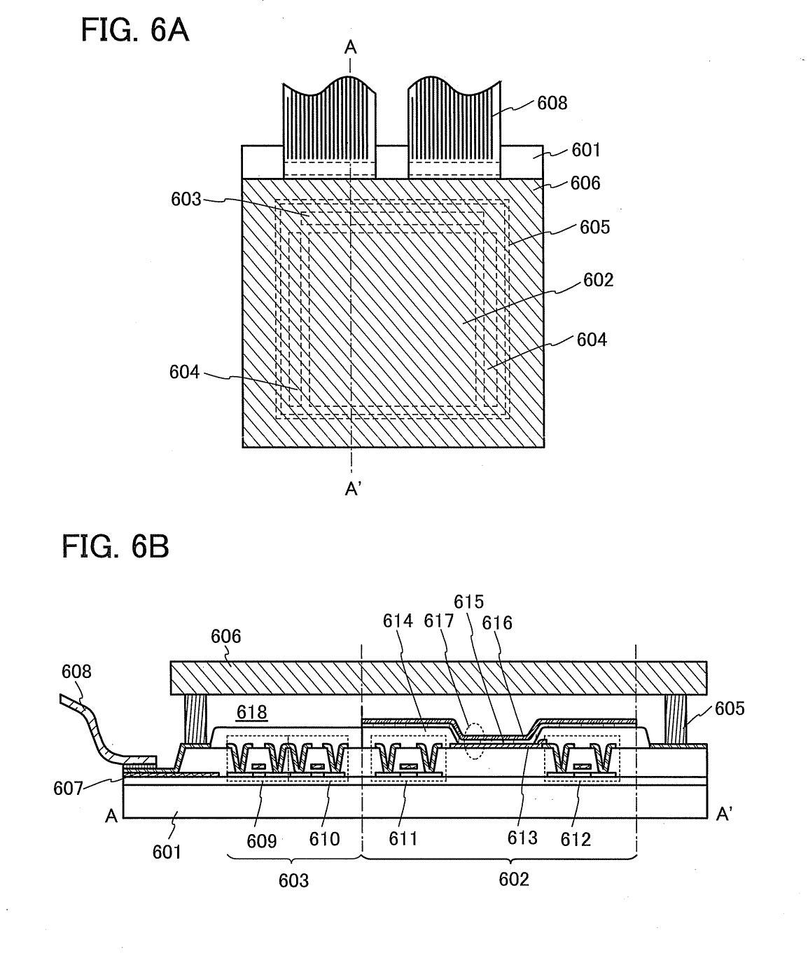

Next, an example of the active matrix light-emitting device will be described with reference to FIGS. 6A and 6B. Note that FIG. 6A is a top view illustrating the light-emitting device and FIG. 6B is a cross-sectional view taken along an alternate long and short dashed line A-A′ in FIG. 6A. The active matrix light-emitting device according to this embodiment includes a pixel portion 602 provided over an element substrate 601, a driver circuit portion (source side driver circuit) 603, and a driver circuit portion (gate side driver circuit) 604. The pixel portion 602, the driver circuit portion (source side driver circuit) 603, and the driver circuit portion (gate side driver circuit) 604 are sealed between the element substrate 601 and the sealing substrate 606 by the sealing material 605.

Note that FIG. 6B, which is a cross-sectional view taken along the alternate long and short dashed line A-A′, illustrates only part of the cross section of the pixel portion 602 and part of the driver circuit portion (source side driver circuit) 603, because the whole of the cross sections are difficult to illustrate.

In addition, over the element substrate 601, a lead wiring 607 for connecting an external input terminal, through which a signal (e.g., a video signal, a clock signal, a start signal, or a reset signal) or a potential from the outside is transmitted to the driver circuit portion (source side driver circuit) 603 and the driver circuit portion (gate side driver circuit) 604, is provided. Here, an example in which an FPC (flexible printed circuit) 608 is provided as the external input terminal is described. Although only the FPC is illustrated here, a printed wiring board (PWB) may be attached to the FPC. The light-emitting device in the present specification includes, in its category, not only the light-emitting device itself but also the light-emitting device provided with the FPC or the PWB.

Next, a cross-sectional structure of the light-emitting device will be described with reference to FIG. 6B. The driver circuit portion and the pixel portion are formed over the element substrate 601; the driver circuit portion (source side driver circuit) 603 and the pixel portion 602 are illustrated here.

The driver circuit portion (source side driver circuit) 603 is an example where a CMOS circuit in which an n-channel TFT 609 and a p-channel TFT 610 are combined is formed. Note that the driver circuit portion may be formed with any of a variety of circuits such as a CMOS circuit, a PMOS circuit, or an NMOS circuit. Although a driver integrated type in which the driver circuit is formed over the substrate is illustrated in this embodiment, the driver circuit may not necessarily be formed over the substrate, and the driver circuit can be formed outside, not over the substrate.

The pixel portion 602 includes a plurality of pixels including a switching TFT 611, a current control TFT 612, and an anode 613 electrically connected to a wiring (a source electrode or a drain electrode) of the current control TFT 612. Note that to cover an end portion of the anode 613, an insulator 614 is formed, for which a positive type photosensitive acrylic resin film is used here.

The insulator 614 is preferably formed so as to have a curved surface with curvature at an upper end portion or a lower end portion thereof in order to obtain favorable coverage by a film which is to be stacked over the anode 613 and the insulator 614. For example, in the case where a positive photosensitive acrylic resin is used as a material of the insulator 614, the upper end portion of the insulator 614 preferably has a curved surface with a curvature radius (0.2 μm to 3 μm). Note that, as the insulator 614, either a negative photosensitive material that becomes insoluble in an etchant by light or a positive photosensitive material that becomes soluble in an etchant by light can be used, or an inorganic compound such as silicon oxide or silicon oxynitride can be used in addition to an organic compound.

An EL layer 615 and a cathode 616 are stacked over the anode 613. Note that when an ITO film is used as the anode 613, and a stacked film of a titanium nitride film and a film containing aluminum as its main component or a stacked film of a titanium nitride film, a film containing aluminum as its main component, and a titanium nitride film is used as the wiring of the current controlling TFT 612 which is connected to the anode 613, resistance as a wiring is low and favorable ohmic contact with the ITO film can be obtained. Note that, although not illustrated here, the cathode 616 is electrically connected to the FPC (flexible printed circuit) 608 which is an external input terminal.

It is preferable that in the EL layer 615, at least a light-emitting layer be provided, and in addition to the light-emitting layer, a hole-injection layer, a hole-transport layer, an electron-transport layer, and an electron-injection layer be provided as appropriate. A light-emitting element 617 has a stacked structure of the anode 613, the EL layer 615, and the cathode 616.

Although the cross-sectional view in FIG. 6B illustrates only one light-emitting element 617, a plurality of light-emitting elements is preferably arranged in matrix in the pixel portion 602. Light-emitting elements which emit three-color (R, G, and B) light are selectively formed in the pixel portion 602, so that a light-emitting device capable of full color display can be formed. Alternatively, a light-emitting device capable of full color display may be obtained in such a way that a light-emitting element that emits single-color light is formed in the pixel portion 602 and combined with a color filter.

Further, the sealing substrate 606 is attached to the element substrate 601 with the sealing material 605, so that the light-emitting element 617 is provided in a space 618 surrounded by the element substrate 601, the sealing substrate 606, and the sealing material 605. The space 618 may be filled with an inert gas (such as nitrogen or argon), or the sealing material 605.

Note that an epoxy based resin is preferably used for the sealing material 605. It is desirable that such a material do not transmit moisture or oxygen as much as possible. As a material for the sealing substrate 606, a plastic substrate formed of FRP (fiberglass-reinforced plastics), PVF (polyvinyl fluoride), polyester, acrylic, or the like can be used besides a glass substrate or a quartz substrate.

By using this embodiment, the passive matrix light-emitting device and active matrix light-emitting device each including the light-emitting element according to the present invention can be fabricated as described above.

Note that the structure described in this embodiment can be combined with any of the structures described in Embodiments 1 to 5 as appropriate. Accordingly, a passive matrix light-emitting device and an active matrix light-emitting device each having low power consumption and high reliability, for example, can be fabricated.

### Embodiment 7

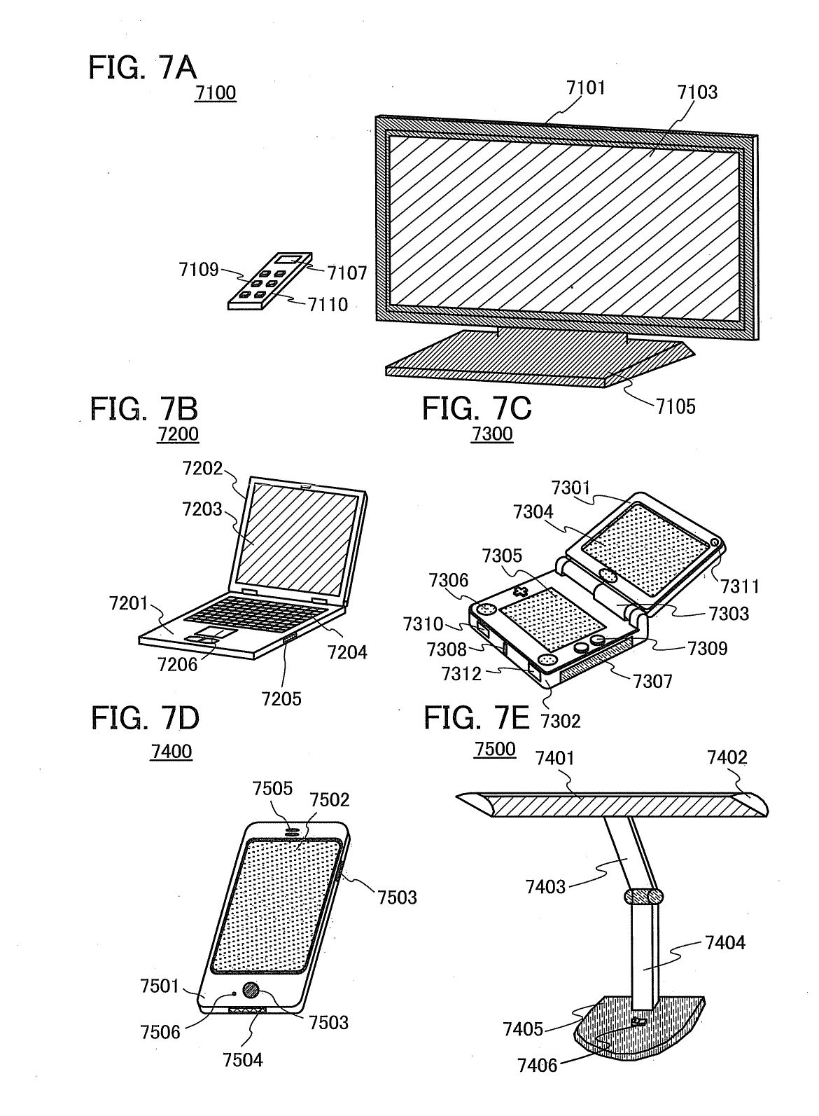

In Embodiment 7, with reference to FIGS. 7A to 7E, FIG. 8, and FIGS. 9A and 9B, description is given of examples of a variety of electronic devices and lighting devices that are completed by using the light-emitting device according to one embodiment of the present invention.

Examples of the electronic devices to which the light-emitting device is applied are television devices (also referred to as TV or television receivers), monitors for computers and the like, cameras such as digital cameras and digital video cameras, digital photo frames, cellular phones (also referred to as portable telephone devices), portable game machines, portable information terminals, audio playback devices, large game machines such as pin-ball machines, and the like. Specific examples of these electronic devices and a lighting device are illustrated in FIGS. 7A to 7E.

FIG. 7A illustrates an example of a television device. In the television device 7100, a display portion 7103 is incorporated into a housing 7101. The display portion 7103 is capable of displaying images, and the light-emitting device can be used for the display portion 7103. In addition, here, the housing 7101 is supported by a stand 7105.

The television device 7100 can be operated by an operation switch of the housing 7101 or a separate remote controller 7110. With operation keys 7109 of the remote controller 7110, channels and volume can be controlled and images displayed on the display portion 7103 can be controlled. Furthermore, the remote controller 7110 may be provided with a display portion 7107 for displaying data output from the remote controller 7110.

Note that the television device 7100 is provided with a receiver, a modem, and the like. With the receiver, general television broadcasting can be received. Furthermore, when the television device 7100 is connected to a communication network by wired or wireless connection via the modem, one-way (from a transmitter to a receiver) or two-way (between a transmitter and a receiver, between receivers, or the like) data communication can be performed.

FIG. 7B illustrates a computer 7200 having a main body 7201, a housing 7202, a display portion 7203, a keyboard 7204, an external connecting port 7205, a pointing device 7206, and the like. This computer is manufactured by using the light-emitting device for the display portion 7203.

FIG. 7C illustrates a portable game machine 7300 having two housings, a housing 7301 and a housing 7302, which are connected with a joint portion 7303 so that the portable game machine can be opened or folded. A display portion 7304 is incorporated into the housing 7301 and a display portion 7305 is incorporated into the housing 7302. In addition, the portable game machine illustrated in FIG. 7C includes a speaker portion 7306, a recording medium insertion portion 7307, an LED lamp 7308, an input means (an operation key 7309, a connection terminal 7310, a sensor 7311 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), or a microphone 7312), and the like. It is needless to say that the structure of the portable games machine is not limited to the above as far as the light-emitting device can be used for at least either the display portion 7304 or the display portion 7305, or both, and may include other accessories arbitrarily. The portable game machine illustrated in FIG. 7C has a function of reading out a program or data stored in a storage medium to display it on the display portion, and a function of sharing information with another portable game machine by wireless communication. The portable game machine illustrated in FIG. 7C can have a variety of functions without limitation to the above.

FIG. 7D illustrates an example of a cellular phone. The cellular phone 7400 is provided with operation buttons 7403, an external connection port 7404, a speaker 7405, a microphone 7406, and the like, in addition to a display portion 7402 incorporated into a housing 7401. Note that the cellular phone 7400 is manufactured using the light-emitting device for the display portion 7402.

When the display portion 7402 of the cellular phone 7400 illustrated in FIG. 7D is touched with a finger or the like, data can be input into the cellular phone 7400. Further, operations such as making a call and creating e-mail can be performed by touch on the display portion 7402 with a finger or the like.

There are mainly three screen modes of the display portion 7402. The first mode is a display mode mainly for displaying an image. The second mode is an input mode mainly for inputting information such as characters. The third mode is a display-and-input mode in which two modes of the display mode and the input mode are mixed.

For example, in the case of making a call or creating e-mail, a text input mode mainly for inputting text is selected for the display portion 7402 so that text displayed on a screen can be input. In this case, it is preferable to display a keyboard or number buttons on almost the entire screen of the display portion 7402.

When a detection device including a sensor for detecting inclination, such as a gyroscope or an acceleration sensor, is provided inside the cellular phone 7400, display on the screen of the display portion 7402 can be automatically changed by determining the orientation of the cellular phone 7400 (whether the cellular phone is placed horizontally or vertically for a landscape mode or a portrait mode).

The screen modes are switched by touch on the display portion 7402 or operation with the operation buttons 7403 of the housing 7401. Alternatively, the screen modes can be switched depending on kinds of images displayed on the display portion 7402. For example, when a signal for an image displayed on the display portion is data of moving images, the screen mode is switched to the display mode. When the signal is text data, the screen mode is switched to the input mode.

Moreover, in the input mode, if a signal detected by an optical sensor in the display portion 7402 is detected and the input by touch on the display portion 7402 is not performed during a certain period, the screen mode may be controlled so as to be switched from the input mode to the display mode.

The display portion 7402 can function as an image sensor. For example, an image of a palm print, a fingerprint, or the like is taken by touch on the display portion 7402 with the palm or the finger, so that personal authentication can be performed. Furthermore, by provision of a backlight or a sensing light source emitting a near-infrared light for the display portion, an image of a finger vein, a palm vein, or the like can also be taken.

FIG. 7E illustrates a desk lamp 7500 including a lighting portion 7501, a shade 7502, an adjustable arm 7503, a support 7504, a base 7505, and a power switch 7506. The desk lamp is manufactured using the light-emitting device for the lighting portion 7501. Note that the “lighting device” also encompasses ceiling lights, wall lights, and the like.

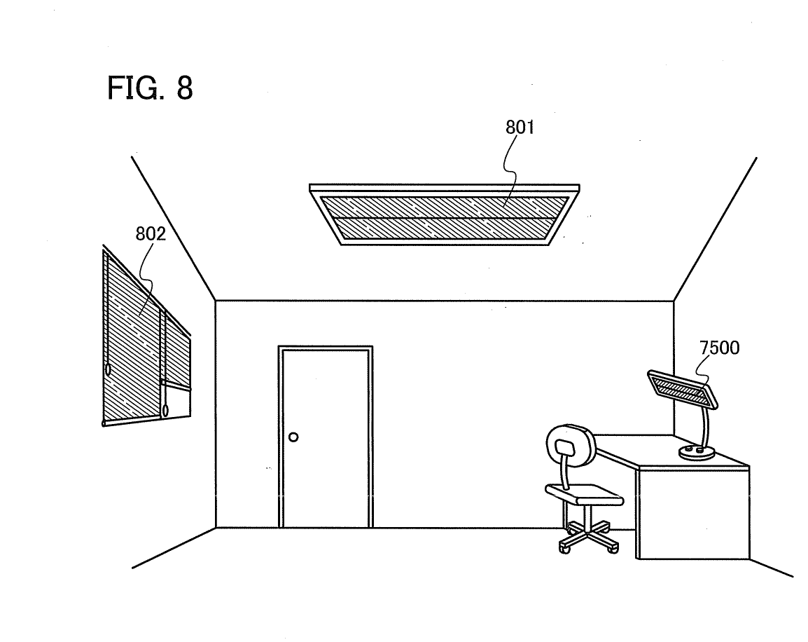

FIG. 8 illustrates an example in which the light-emitting device is used for an interior lighting device 801. Since the light-emitting device can have a larger area, it can be used as a lighting device having a large area. Furthermore, the light-emitting device can be used as a roll-type lighting device 802. As illustrated in FIG. 8, the desk lamp 7500 described with reference to FIG. 7E may be used together in a room provided with the interior lighting device 801.

By use of this embodiment, a variety of light-emitting devices, such as an electronic device and a lighting device, including the light-emitting element according to the present invention can be fabricated as described above.

Note that the structure described in this embodiment can be combined with any of the structures described in Embodiments 1 to 6 as appropriate. Accordingly, a variety of light-emitting devices, such as an electronic device and a lighting device, with high added value, e.g., low power consumption and high reliability can be fabricated.

### Embodiment 8

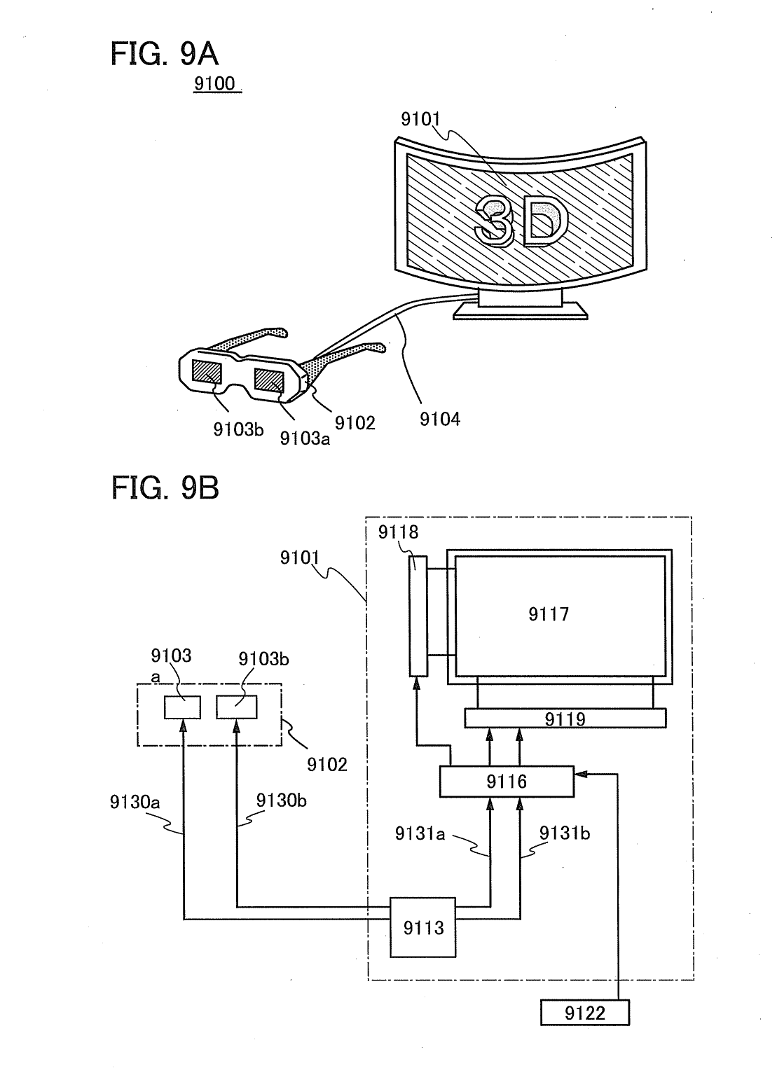

Referring to FIGS. 9A and 9B, this embodiment shows an example in which a display device that switches between an image for a left eye and an image for a right eye at high speed is used for visual recognition of a 3D image, which is a moving image or a still image, using dedicated glasses with which videos of the display device are synchronized.

FIG. 9A illustrates the appearance of a 3D image display device 9100, and a display portion 9101 and dedicated glasses 9102 are connected with a cable 9104. In the dedicated glasses 9102, shutters provided in a panel 9103a for a left eye and a panel 9103b for a right eye are alternately opened and closed; thus, an image displayed on the display portion 9101 can be seen as a 3D image by a user.

In addition, FIG. 9B is a block diagram illustrating a main structure of the display portion 9101 and the dedicated glasses 9102.

The display portion 9101 illustrated in FIG. 9B includes a display control circuit 9116, a display portion 9117, a timing generator 9113, a source line driver circuit 9118, an external operation unit 9122, and a gate line driver circuit 9119. A highly efficient light-emitting element using any of the organometallic complexes according to the present invention can be used for the display portion 9117. Note that an output signal changes in accordance with operation by the external operation unit 9122 such as a keyboard.

In the timing generator 9113, a start pulse signal and the like are formed, and a signal for synchronizing an image for a left eye and the shutter of the panel 9103a for a left eye, a signal for synchronizing an image for a right eye and the shutter of the panel 9103b for a right eye, and the like are formed.

A synchronization signal 9131a of the image for a left eye is input to the display control circuit 9116, so that the image for a left eye is displayed on the display portion 9117. At the same time, a synchronization signal 9130a for opening the shutter of the panel 9103a for a left eye is input to the panel 9103a for a left eye. In addition, a synchronization signal 9131b of the image for a right eye is input to the display control circuit 9116, so that the image for a right eye is displayed on the display portion 9117. At the same time, a synchronization signal 9130b for opening the shutter of the panel 9103b for a right eye is input to the panel 9103b for a right eye.

Further, since a field sequential method is employed, it is preferable that the timing generator 9113 input signals synchronized with the synchronization signals 9130a and 9130b to light-emitting elements as well.

According to this embodiment, a displayed image with higher luminance can be realized as described above, leading to suppression of the darkness of a screen which is one of the problems with 3D image display devices. Further, inclusion of the light-emitting element according to the present invention enables the response speed of each pixel to be greatly increased, leading to suppression of crosstalk generation which is one of the problems with 3D image display devices. Furthermore, the power consumption of 3D image display devices can also be reduced.

Note that the structure described in this embodiment can be combined with any of the structures described in Embodiments 1 to 7 as appropriate. Accordingly, a 3D image display device with low power consumption and high reliability, for example, can be fabricated.

### Example 1

### Synthesis Example 1

Example 1 gives a specific example of the synthesis of the organometallic complex represented by the structural formula (100) in Embodiment 1 which is one embodiment of the present invention, (acetylacetonato)bis[2-(dibenzofuran-4-yl)-3,5-dimethylpyrazinato]iridium(III) (abbreviation: [Ir(dm4 dbfpr)₂(acac)]). A structure of [Ir(dm4 dbfpr)₂(acac)] is illustrated below.

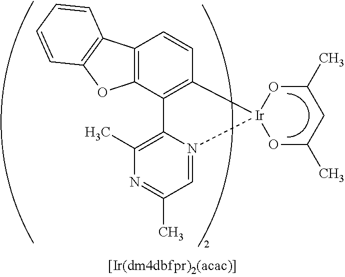

### Step 1: Synthesis of 3,5-Dimethyl-2-(dibenzofuran-4-yl)pyrazine (abbreviation: Hdm4 dbfpr)

First, into a recovery flask equipped with a reflux pipe were placed 1.51 g of 2-chloro-3,5-dimethylpyrazine, 2.25 g of 4-dibenzofuranylboronic acid, 1.12 g of sodium carbonate, 0.048 g of bis(triphenylphosphine)palladium(II) dichloride (abbreviation: Pd(PPh₃)₂Cl₂), 15 mL of water, and 15 mL of acetonitrile, and the air inside the flask was replaced with argon. Heating was performed by microwave irradiation (2.45 GHz, 100 W) of this reaction container for 10 minutes, so that reaction occurred. After that, water was added to this reaction solution, and extraction with dichloromethane was carried out. A solution of the obtained extract was washed with water and dried over magnesium sulfate. After the drying, the solution was filtered. After the solvent of this solution was distilled, the obtained residue was washed with methanol, so that the pyrazine derivative which was the object of the synthesis, Hdm4 dbfpr, was obtained (a pale orange powder in a yield of 65%). Note that a microwave synthesis system (Discover, produced by CEM Corporation) was used for the microwave irradiation. The synthesis scheme of Step 1 is illustrated in the following scheme (x-1).

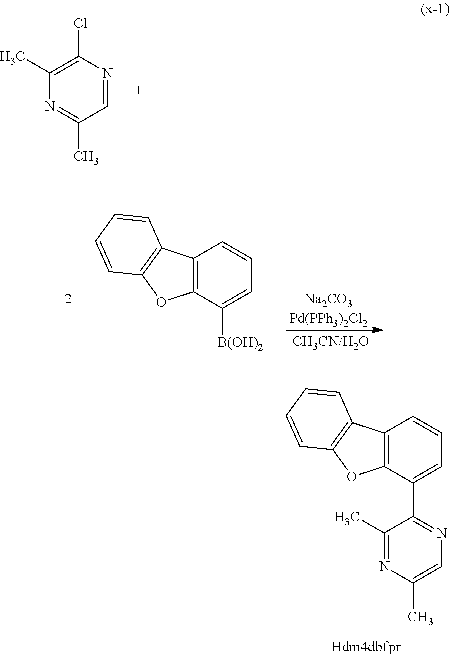

### Step 2: Synthesis of Di-μ-chloro-bis[bis{2-(dibenzofuran-4-yl)-3,5-dimethylpyrazinato}iridium(III)] (abbreviation: [Ir(dm4 dbfpr)₂Cl]₂)

Next, into a recovery flask equipped with a reflux pipe were placed 15 mL of 2-ethoxyethanol, 5 mL of water, 1.25 g of Hdm4 dbfpr obtained in Step 1 above, and 0.68 g of iridium chloride hydrate (IrCl₃.H₂O), and the air in the flask was replaced with argon. Microwave irradiation (2.45 GHz, 100 W) was performed for 30 minutes, so that reaction occurred. The powder precipitated from the reaction solution was subjected to filtration and washed with ethanol to give a binuclear complex, [Ir(dm4 dbfpr)₂Cl]₂ (a red powder in a yield of 54%). The synthesis scheme of Step 2 is illustrated in the following scheme (x-2).

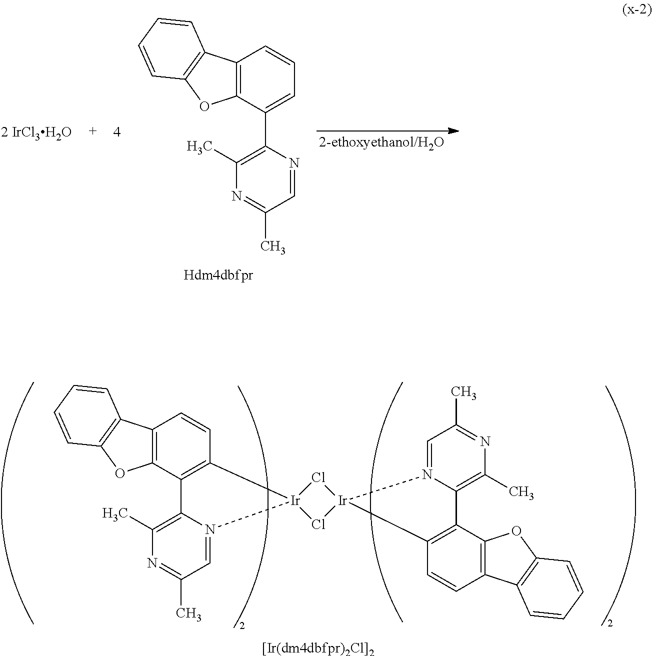

### Step 3: Synthesis of (Acetylacetonato)bis[2-(dibenzofuran-4-yl)-3,5-dimethylpyrazinato]iridium(III) (abbreviation: [Ir(dm4 dbfpr)₂(acac)])

Furthermore, into a recovery flask equipped with a reflux pipe were placed 10 mL of 2-ethoxyethanol, 0.39 g of the binuclear complex obtained in Step 2 above, [Ir(dm4 dbfpr)₂Cl]₂, 0.078 mL of acetylacetone, and 0.26 g of sodium carbonate, and the air in the flask was replaced with argon. After that, microwave irradiation (2.45 GHz, 100 W) was performed for 30 minutes, so that reaction occurred. Dichloromethane was added to the reaction solution, and the mixture was filtered. The obtained filtrate was concentrated, and the precipitated powder was subjected to filtration. This powder was washed with ethanol, water, ethanol again, and hexane in this order, and then was dissolved in dichloromethane. This solution was filtered through a mixture of silica gel and Celite (produced by Wako Pure Chemical Industries, Ltd., Catalog No. 531-16855) so that impurities were removed, and the solution was concentrated. The obtained residue was washed with ethanol and then hexane, so that one of the organometallic complexes according to the present invention, [Ir(dm4 dbfpr)₂(acac)], was obtained (a red powder in a yield of 36%). The synthesis scheme of Step 3 is illustrated in the following scheme (x-3).

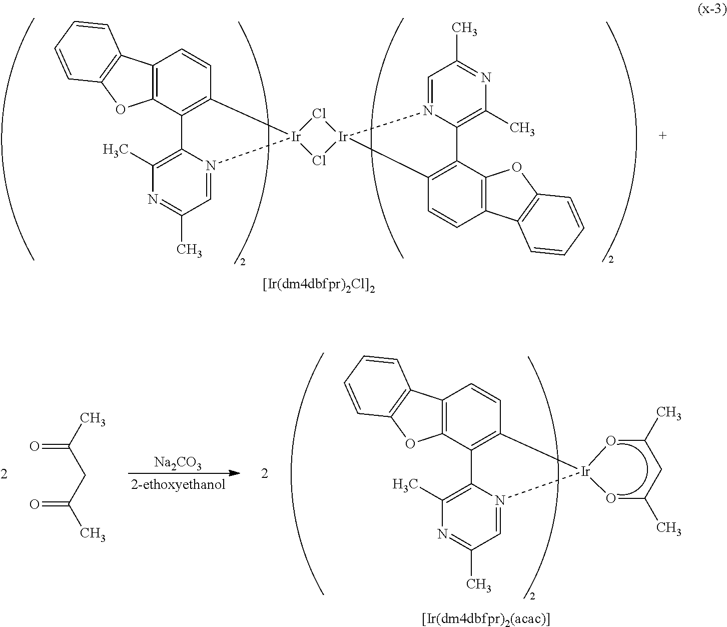

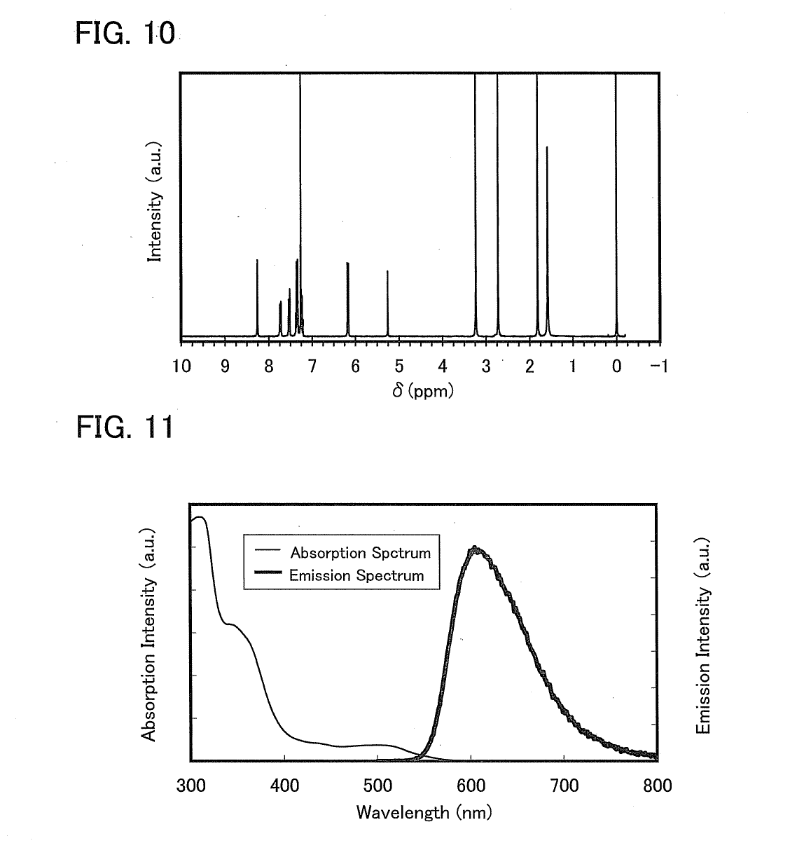

The results of the nuclear magnetic resonance (¹H-NMR) spectroscopy, by which the red powder obtained in Step 3 above was analyzed, are shown in FIG. 10 and below. These results revealed that the organometallic complex represented by the above-described structural formula (100) which is one embodiment of the present invention, [Ir(dm4 dbfpr)₂(acac)], was obtained in Synthesis Example 1.

¹H-NMR. δ (CDCl₃): 1.81 (s, 6H), 2.72 (s, 6H), 3.24 (s, 6H), 5.26 (s, 1H), 6.17 (d, 2H), 7.23 (m, 2H), 7.32-7.38 (m, 4H), 7.53 (d, 2H), 7.73 (d, 2H), 8.26 (s, 2H).

Next, an ultraviolet-visible absorption spectrum (hereinafter, simply referred to as an “absorption spectrum”) of a dichloromethane solution of [Ir(dm4 dbfpr)₂(acac)] and an emission spectrum thereof were measured. The measurement of the absorption spectrum was conducted at room temperature, for which an ultraviolet-visible light spectrophotometer (V550 type manufactured by Japan Spectroscopy Corporation) was used and the dichloromethane solution (0.071 mmol/L) was put in a quartz cell. In addition, the measurement of the emission spectrum was conducted at room temperature, for which a fluorescence spectrophotometer (FS920 manufactured by Hamamatsu Photonics Corporation) was used and the degassed dichloromethane solution (0.43 mmol/L) was put in a quartz cell. Measurement results of the obtained absorption and emission spectra are shown in FIG. 11, in which the horizontal axis represents wavelength and the vertical axis represents absorption intensity and emission intensity. In FIG. 11 where there are two solid lines, the thin line represents the absorption spectrum and the thick line represents the emission spectrum. Note that the absorption spectrum in FIG. 11 is the results obtained in such a way that the absorption spectrum measured by putting only dichloromethane in a quartz cell was subtracted from the absorption spectrum measured by putting the dichloromethane solution (0.071 mmol/L) in a quartz cell.

As shown in FIG. 11, the organometallic complex of one embodiment of the present invention, [Ir(dm4 dbfpr)₂(acac)], has an emission peak at 605 nm, and red-orange light emission was observed from the dichloromethane solution.

Next, the absolute quantum yield of [Ir(dm4 dbfpr)₂(acac)] was measured. After the concentration was adjusted with toluene as a solvent so as to be 1.0×10⁻⁵ mol/L, the measurement of the absolute quantum yield was carried out at room temperature for the wavelength region ranging from 200 nm to 900 nm with an absolute PL quantum yield measurement system (C9920-02, produced by Hamamatsu Photonics Corporation). As a result, the absolute quantum yield was 78%, which indicates high emission efficiency.

### Example 2

### Synthesis Example 2

Example 1 gives a specific example of the synthesis of the organometallic complex represented by the structural formula (124) in Embodiment 1 which is one embodiment of the present invention, bis[2-(dibenzofuran-2-yl)-3,5-dimethylpyrazinato] (dipivaloylmethanato)iridium(III) (abbreviation: [Ir(dm2 dbfpr)₂(dpm)]). A structure of [Ir(dm2 dbfpr)₂(dpm)] is illustrated below.

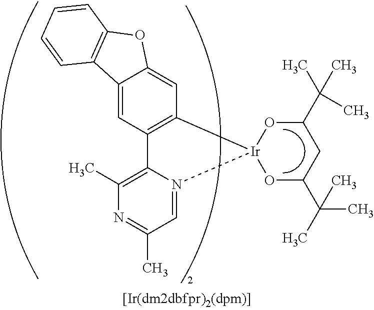

### Step 1: Synthesis of 2-Bromodibenzofuran

First, into a four-neck flask equipped with a dropping funnel and a temperature meter were placed 15 g of dibenzofuran and 90 mL of glacial acetic acid, and the inside was refluxed under a nitrogen atmosphere. After that, the flask was heated to 50° C., and 18.8 g of bromine was added dropwise with the dropping funnel for 15 minutes while the temperature of the reaction solution was kept at 60° C. or less. Then, a yellow solid was precipitated after stirring at room temperature for 24 hours. The solution after the reaction was filtered, and washed with 9 mL of acetic acid. Then, washing was performed with water until the yellow solid becomes colorless, and washing was further performed with methanol. The obtained solid was recrystallized from dichloromethane to give 2-bromodibenzofuran, which was the object of the synthesis (a white powder in a yield of 45%). The synthesis scheme of Step 1 is illustrated in the following scheme (y-1).

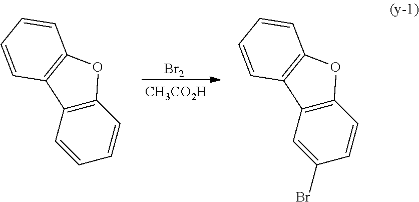

### Step 2: Synthesis of 2-Dibenzofuranyl boronic acid

Next, into a three-neck flask were placed 10.79 g of 2-bromodibenzofuran obtained in Step 1 above, 70 mL of dehydrated ether, and 70 mL of dehydrated toluene, and the air in the flask was replaced with nitrogen. After that, 55 mL of a hexane solution (1.58 mol/L) of n-butyllithium was added dropwise to this suspension at −78° C. After this reaction solution was stirred at −78° C. for 2 hours, 14.6 mL of trimethyl borate was added thereto, and the temperature of the reaction solution was raised to room temperature. Then, 33 mL of 10% hydrochloric acid was added to the reaction solution. This solution was extracted with ethyl acetate, and a solution of the extract was dried over magnesium sulfate. After being dried, the solution was filtered, and the filtrate was concentrated. The obtained residue was washed with hexane to give 2-dibenzofuranylboronic acid, which was the object of the synthesis (a white powder in a yield of 29%). The synthesis scheme of Step 2 is illustrated in the following scheme (y-2).

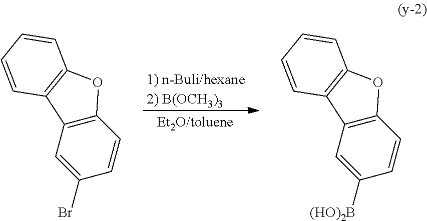

### Step 3: Synthesis of 3,5-Dimethyl-2-(dibenzofuran-2-yl)pyrazine (abbreviation: Hdm2 dbfpr)

Next, into a recovery flask equipped with a reflux pipe were placed 1.80 g of 2-chloro-3,5-dimethylpyrazine, 2.68 g of 2-dibenzofuranylboronic acid, 1.34 g of sodium carbonate, 0.0575 g of bis(triphenylphosphine)palladium(II) dichloride (abbreviation: Pd(PPh₃)₂Cl₂), 15 mL of water, and 15 mL of acetonitrile, and the air inside the flask was replaced with argon. Heating was performed by microwave irradiation (2.45 GHz, 100 W) of this reaction container for 10 minutes, so that reaction occurred. After that, water was added to this reaction solution, and extraction with dichloromethane was carried out. A solution of the obtained extract was washed with water and dried over magnesium sulfate. After the drying, the solution was filtered. After the solvent of this solution was distilled, the obtained residue was washed with methanol and then ethyl acetate, so that the pyrazine derivative which was the object of the synthesis, Hdm2 dbfpr, was obtained (a white powder in a yield of 94%). Note that a microwave synthesis system (Discover, produced by CEM Corporation) was used for the microwave irradiation. The synthesis scheme of Step 3 is illustrated in the following scheme (y-3).

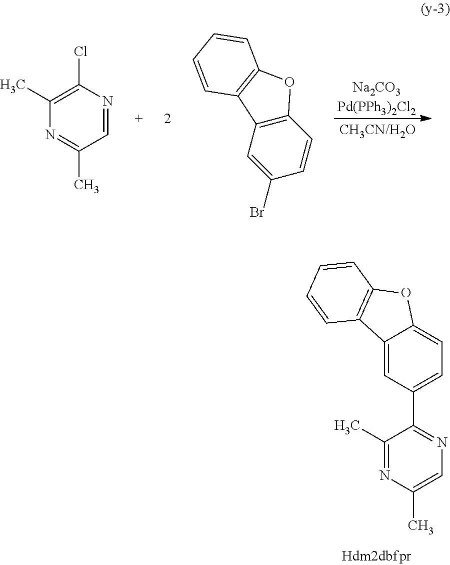

### Step 4: Synthesis of Di-μ-chloro-bis[bis{2-(dibenzofuran-2-yl)-3,5-dimethylpyrazinato}iridium(III)] (abbreviation: [Ir(dm2 dbfpr)₂C1]₂)

Next, into a recovery flask equipped with a reflux pipe were placed 15 mL of 2-ethoxyethanol, 5 mL of water, 1.24 g of Hdm2 dbfpr obtained in Step 3 above, and 0.54 g of iridium chloride hydrate (IrCl₃.H₂O), and the air in the flask was replaced with argon. After that, microwave irradiation (2.45 GHz, 100 W) was performed for 30 minutes, so that reaction occurred. The powder precipitated from the reaction solution was subjected to filtration and washed with ethanol to give a binuclear complex, [Ir(dm2 dbfpr)₂Cl]₂ (an ocher powder in a yield of 65%). The synthesis scheme of Step 4 is illustrated in the following scheme (y-4).

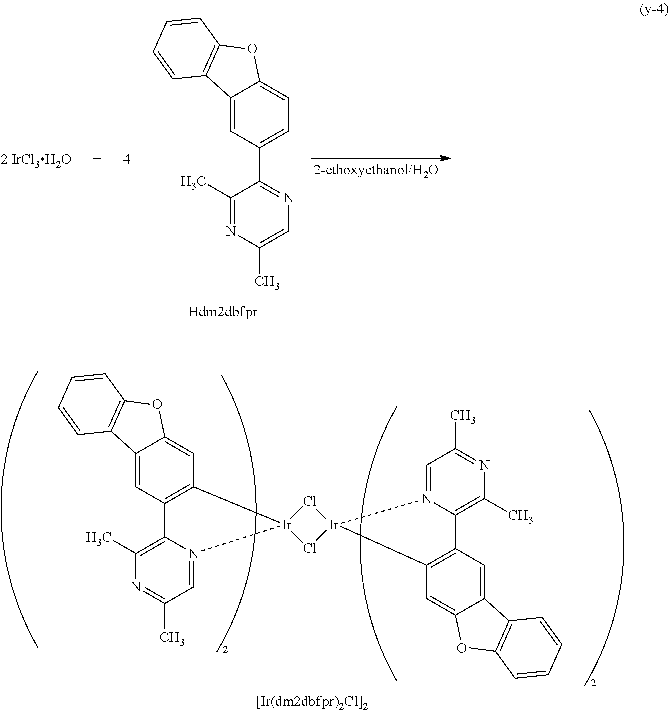

### Step 5: Synthesis of Bis[2-(dibenzofuran-2-yl)-3,5-dimethylpyrazinato](dipivaloylmethanato)iridium(III) (abbreviation: [Ir(dm2 dbfpr)₂(dpm)])

Furthermore, into a recovery flask equipped with a reflux pipe were placed 10 mL of 2-ethoxyethanol, 0.59 g of the binuclear complex obtained in Step 4 above, [Ir(dm2 dbfpr)₂Cl]₂, 0.21 mL of dipivaloylmethane, and 0.40 g of sodium carbonate, and the air in the flask was replaced with argon. After that, microwave irradiation (2.45 GHz, 100 W) was performed for 30 minutes, so that reaction occurred. Dichloromethane was added to the reaction solution, and the mixture was filtered. The obtained filtrate was concentrated, and the precipitated powder was dissolved in dichloromethane. This solution was filtered through a mixture of silica gel and Celite (produced by Wako Pure Chemical Industries, Ltd., Catalog No. 531-16855) so that impurities were removed, and the solution was concentrated. The obtained residue was washed with methanol and then hexane, so that one of the organometallic complexes according to the present invention, [Ir(dm2 dbfpr)₂(dpm)], was obtained (an orange powder in a yield of 16%). The synthesis scheme of Step 5 is illustrated in the following scheme (y-5).

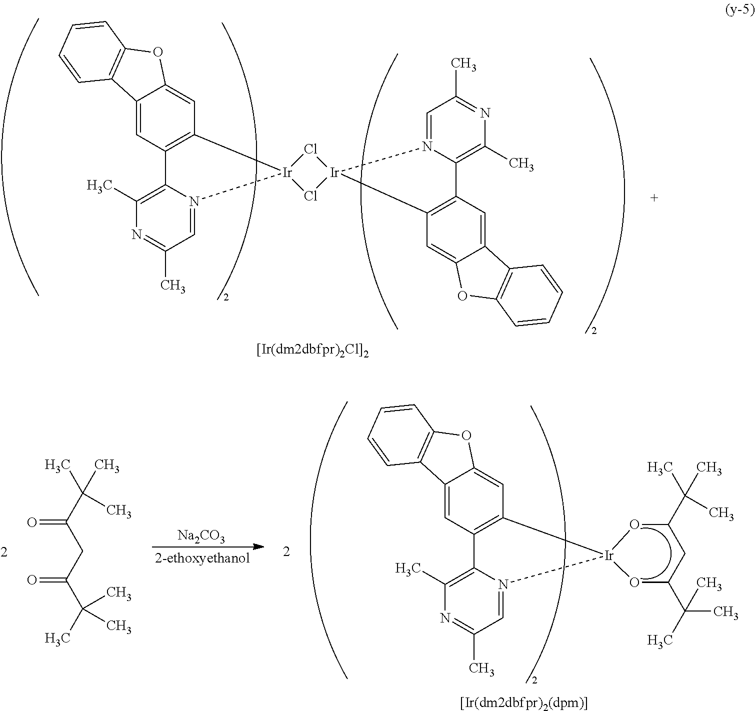

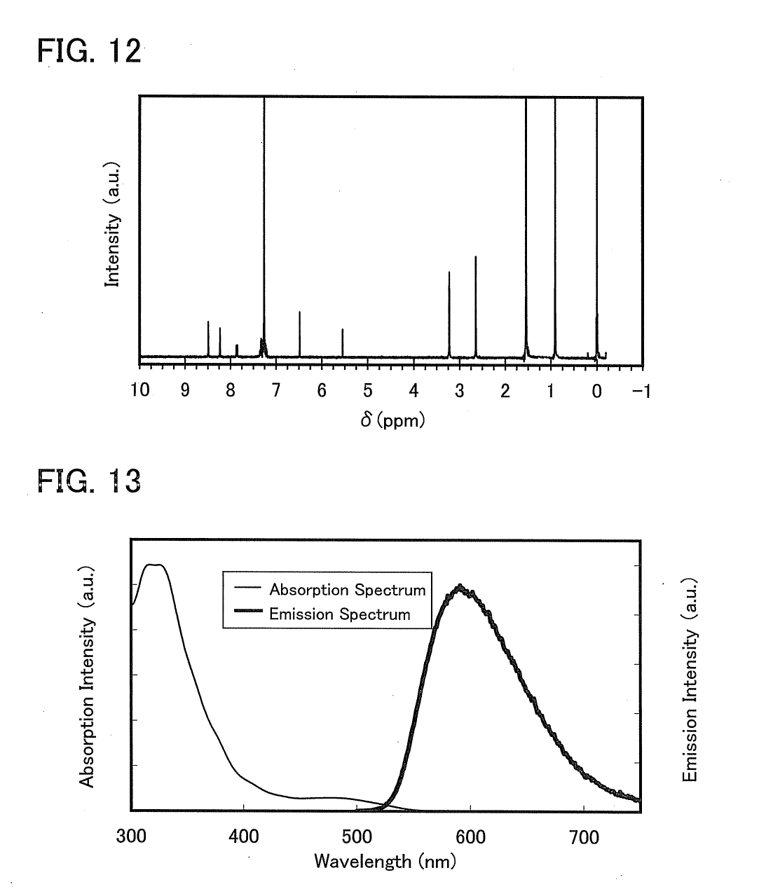

The results of the nuclear magnetic resonance (¹H-NMR) spectroscopy, by which the orange powder obtained in Step 5 above was analyzed, are shown in FIG. 12 and below. These results revealed that the organometallic complex represented by the above-described structural formula (124) which is one embodiment of the present invention, [Ir(dm2 dbfpr)₂(dpm)], was obtained in Synthesis Example 2.

¹H-NMR. δ (CDCl₃): 0.91 (s, 18H), 2.64 (s, 6H), 3.23 (s, 6H), 5.55 (s, 1H), 6.48 (s, 2H), 7.23 (m, 2H), 7.33 (m, 4H), 7.86 (d, 2H), 8.23 (s, 2H), 8.49 (s, 2H).

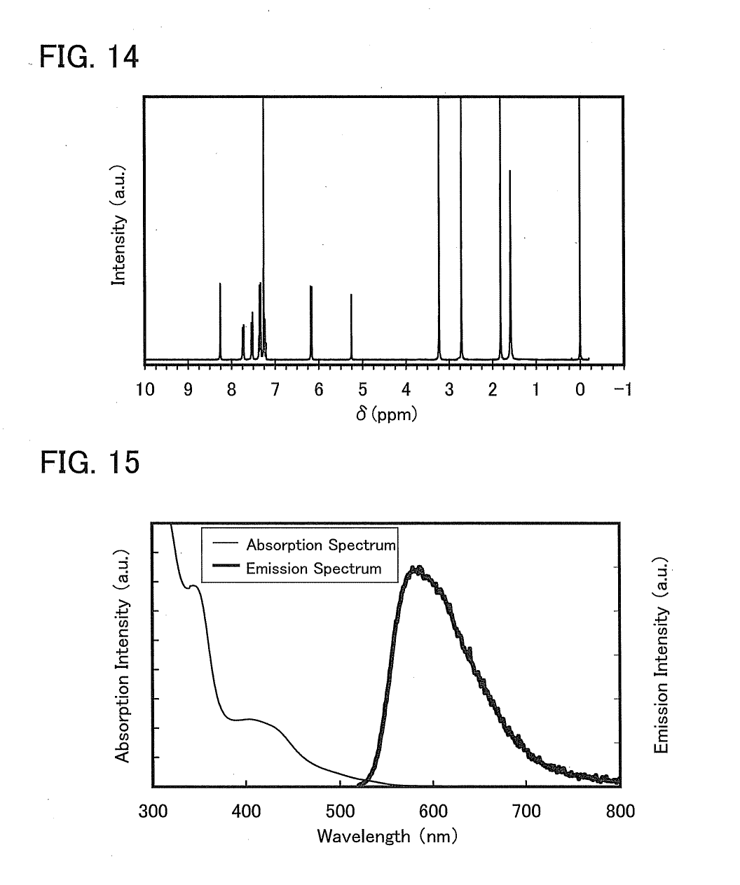

Next, an ultraviolet-visible absorption spectrum (hereinafter, simply referred to as an “absorption spectrum”) of a dichloromethane solution of [Ir(dm2 dbfpr)₂(dpm)] and an emission spectrum thereof were measured. The measurement of the absorption spectrum was conducted at room temperature, for which an ultraviolet-visible light spectrophotometer (V550 type manufactured by Japan Spectroscopy Corporation) was used and the dichloromethane solution (0.065 mmol/L) was put in a quartz cell. In addition, the measurement of the emission spectrum was conducted at room temperature, for which a fluorescence spectrophotometer (FS920 manufactured by Hamamatsu Photonics Corporation) was used and the degassed dichloromethane solution (0.39 mmol/L) was put in a quartz cell. Measurement results of the obtained absorption and emission spectra are shown in FIG. 13, in which the horizontal axis represents wavelength and the vertical axis represents absorption intensity and emission intensity. In FIG. 13 where there are two solid lines, the thin line represents the absorption spectrum and the thick line represents the emission spectrum. Note that the absorption spectrum in FIG. 13 is the results obtained in such a way that the absorption spectrum measured by putting only dichloromethane in a quartz cell was subtracted from the absorption spectrum measured by putting the dichloromethane solution (0.065 mmol/L) in a quartz cell.

As shown in FIG. 13, the organometallic complex of one embodiment of the present invention, [Ir(dm2 dbfpr)₂(dpm)], has an emission peak at 589 nm, and orange light emission was observed from the dichloromethane solution.

Next, the absolute quantum yield of [Ir(dm2 dbfpr)₂(dpm)] was measured. After the concentration was adjusted with toluene as a solvent so as to be 1.0×10⁻⁵ mol/L, the measurement of the absolute quantum yield was carried out at room temperature for the wavelength region ranging from 200 nm to 900 nm with an absolute PL quantum yield measurement system (C9920-02, produced by Hamamatsu Photonics Corporation). As a result, the absolute quantum yield was 78%, which indicates high emission efficiency.

### Example 3

### Synthesis Example 3

Example 3 gives a specific example of the synthesis of the organometallic complex represented by the structural formula (135) in Embodiment 1 which is one embodiment of the present invention, tris[2-(dibenzofuran-4-yl)-3,5-dimethylpyrazinato]iridium(III) (abbreviation: [Ir(dm4 dbfpr)₃]). A structure of [Ir(dm4 dbfpr)₃] is illustrated below.

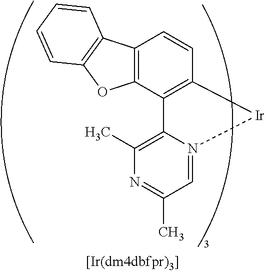

### Step 1: Synthesis of Tris[2-(dibenzofuran-4-yl)-3,5-dimethylpyrazinato]iridium(III) (abbreviation: [Ir(dm4 dbfpr)₃])

First, 0.35 g of the ligand prepared in Step 1 in Synthesis Example 1 above, Hdm4 dbfpr, and 0.14 g of tris(acetylacetonato)iridium(III) were placed into a reaction container provided with a three-way cock, and the air in the reaction container was replaced with argon. After that, the mixture was heated at 250° C. for 53 hours to be reacted. The reactant was dissolved in dichloromethane, and this solution was filtered. The solvent of the filtrate was distilled, and the obtained residue was purified by silica gel column chromatography with ethyl acetate as a developing solvent, so that the organometallic complex which is one embodiment of the present invention, [Ir(dm4 dbfpr)₃], was obtained (an orange powder in a yield of 18%). The synthesis scheme of Step 1 is illustrated below.

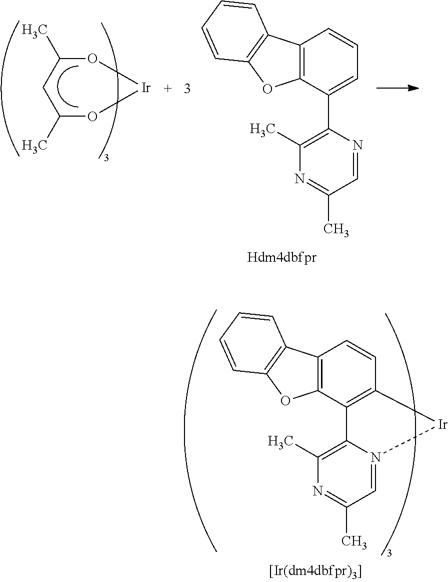

The results of the nuclear magnetic resonance (¹H-NMR) spectroscopy, by which the orange powder obtained by the above step was analyzed, are shown below. In addition, a ¹H-NMR chart is shown in FIG. 14. These results revealed that the organometallic complex represented by the above-described structural formula (135) which is one embodiment of the present invention, [Ir(dm4 dbfpr)₃], was obtained in Synthesis Example 3.

¹H-NMR. δ (CDCl₃): 2.41 (s, 9H), 3.03 (s, 9H), 6.74 (d, 3H), 7.16 (s, 3H), 7.30 (dd, 3H), 7.39 (dt, 3H), 7.44 (d, 3H), 7.55 (d, 3H), 7.82 (d, 3H).

Next, an ultraviolet-visible absorption spectrum (hereinafter, simply referred to as an “absorption spectrum”) of a dichloromethane solution of [Ir(dm4 dbfpr)₃] and an emission spectrum thereof were measured. The measurement of the absorption spectrum was conducted at room temperature, for which an ultraviolet-visible light spectrophotometer (V550 type manufactured by Japan Spectroscopy Corporation) was used and the dichloromethane solution (0.086 mmol/L) was put in a quartz cell. In addition, the measurement of the emission spectrum was conducted at room temperature, for which a fluorescence spectrophotometer (FS920 manufactured by Hamamatsu Photonics Corporation) was used and the degassed dichloromethane solution (0.52 mmol/L) was put in a quartz cell. Measurement results of the obtained absorption and emission spectra are shown in FIG. 15, in which the horizontal axis represents wavelength and the vertical axis represents absorption intensity and emission intensity. In FIG. 15 where there are two solid lines, the thin line represents the absorption spectrum and the thick line represents the emission spectrum. Note that the absorption spectrum in FIG. 15 is the results obtained in such a way that the absorption spectrum measured by putting only dichloromethane in a quartz cell was subtracted from the absorption spectrum measured by putting the dichloromethane solution (0.086 mmol/L) in a quartz cell.

As shown in FIG. 15, the organometallic complex of one embodiment of the present invention, [Ir(dm4 dbfpr)₃], has an emission peak at 578 nm, and orange light emission was observed from the dichloromethane solution.

### Example 4

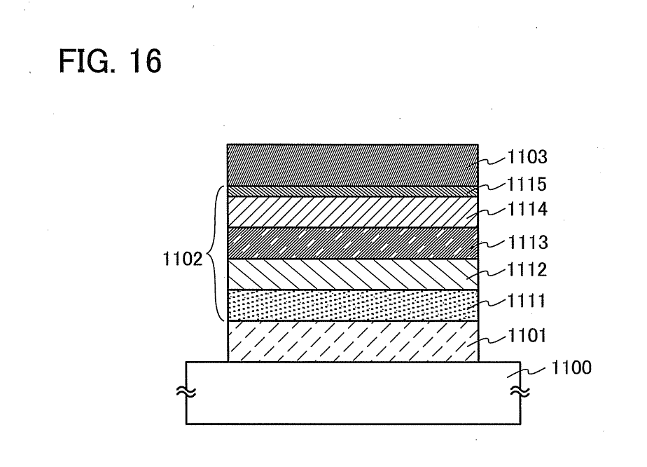

This example shows a light-emitting element (light-emitting element 1) in which the organometallic complex that is one embodiment of the present invention and was synthesized in Example 1, [Ir(dm4 dbfpr)₂(acac)] (structural formula (100)), is included as a light-emitting substance, and a light-emitting element (light-emitting element 2) in which the organometallic complex that is one embodiment of the present invention and was synthesized in Example 2, [Ir(dm2 dbfpr)₂(dpm)] (structural formula (124)), is included as a light-emitting substance. Note that structures of other organic compounds used in this example are represented by structural formulae (i) to (iv) below. Further, examples of the methods of synthesizing the substance represented by the structural formula (I) below, 4-phenyl-4′-(9-phenylfluoren-9-yl) triphenyl amine (abbreviation: BPAFLP) and the substance represented by the structural formula (ii) below, 2-[3-(dibenzothiophen-4-yl)phenyl]dibenzo[f,h]quinoxaline (abbreviation: 2mDBTPDBq-II) are described. In addition, element structures of the light-emitting elements will be described on the basis of FIG. 16.

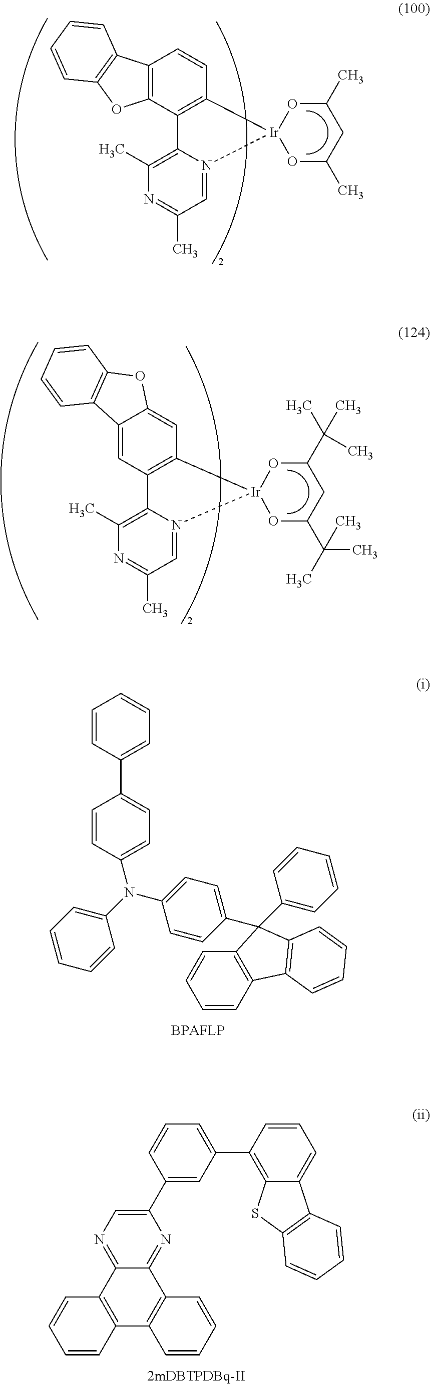

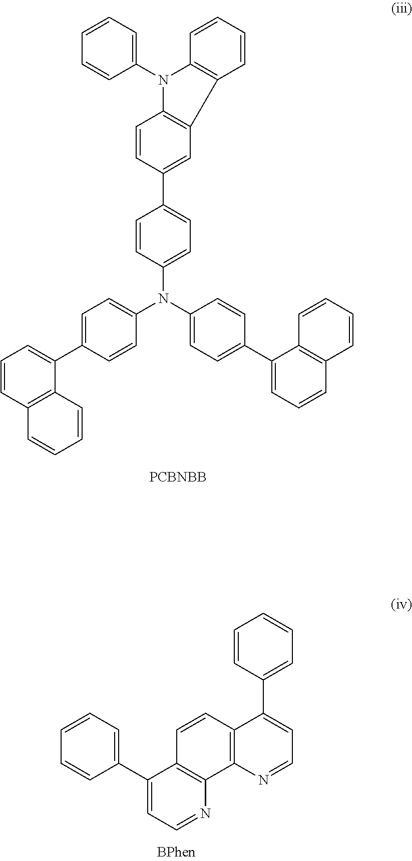

### (Fabrication of Light-Emitting Element 1 and Light-Emitting Element 2)

First, as a first electrode 1101, a 110 nm thick film of indium tin oxide containing silicon oxide (ITSO) is formed over a substrate 1100 made of glass. Note that a surface of the ITSO film is covered with an insulating film so that a 2 mm square portion of the surface is exposed. Here, the first electrode 1101 is an electrode that functions as an anode of each light-emitting element.

Next, in pretreatment for forming the light-emitting elements over the substrate 1100, the surface of the substrate was washed with ozone water, baking was performed at 200° C. for one hour, and UV ozone treatment was then performed for 370 seconds.

Then, the substrate was transferred into a vacuum evaporation apparatus where the pressure was reduced to about 10⁻⁴ Pa, vacuum baking at 170° C. for 30 minutes was performed in a heating chamber of the vacuum evaporation apparatus, and then the substrate 1100 was cooled down for about 30 minutes.

Next, the substrate 1100 was fixed to a holder provided in the vacuum evaporation apparatus so that the surface of the substrate on which the first electrode 1101 was formed faced downward. In this example, the case where a hole-injection layer 1111, a hole-transport layer 1112, a light-emitting layer 1113, an electron-transport layer 1114, and an electron-injection layer 1115 which are included in an EL layer 1102 are sequentially formed will be described.

After the pressure in the vacuum evaporation apparatus was reduced to 10⁻⁴ Pa, 4-phenyl-4′-(9-phenylfluoren-9-yl)triphenylamine (abbreviation: BPAFLP) represented by the above structural formula (i) and molybdenum oxide were co-evaporated so that the mass ratio of BPAFLP to molybdenum oxide was 4:2; thus, the hole-injection layer 1111 was formed. The thickness thereof was set to 40 nm. Note that co-evaporation is an evaporation method in which a plurality of different substances is concurrently vaporized from respective different evaporation sources.

Next, BPAFLP was evaporated to a thickness of 20 nm, so that the hole-transport layer 1112 was formed.

Next, for the light-emitting element 1, the light-emitting layer 1113 was formed by co-evaporation of 2-[3-(dibenzothiophen-4-yl)phenyl]dibenzo[f,h]quinoxaline (abbreviation: 2mDBTPDBq-II) represented by the above structural formula (ii), 4,4′-di(1-naphthyl)-4″-(9-phenyl-9H-carbazol-3-yl)triphenylamine (abbreviation: PCBNBB) represented by the above structural formula (iii), and (acetylacetonato)bis[2-(dibenzofuran-4-yl)-3,5-dimethylpyrazinato]iridium(III) (abbreviation: [Ir(dm4 dbfpr)₂(acac)]) represented by the above structural formula (100) on the hole-transport layer 1112 so that the mass ratio of 2mDBTPDBq-II to PCBNBB and [Ir(dm4 dbfpr)₂(acac)] were 0.8:0.2:0.05. For the light-emitting element 2, the light-emitting layer 1113 was formed by co-evaporation of 2mDBTPDBq-II, PCBNBB, and bis[2-(dibenzofuran-2-yl)-3,5-dimethylpyrazinato] (dipivaloylmethanato)iridium(III) (abbreviation: [Ir(dm2 dbfpr)₂(dpm)])) represented by the above structural formula (124) on the hole-transport layer 1112 so that the mass ratio of 2mDBTPDBq-II to PCBNBB and [Ir(dm2 dbfpr)₂(dpm)]) were 0.8:0.2:0.05. The thickness of the light-emitting layer in each of the light-emitting elements 1 and 2 was set to 40 nm.

Next, 2mDBTPDBq-II was evaporated to a thickness of 10 nm and then bathophenanthroline (abbreviation: BPhen) represented by the above structural formula (Iv) was evaporated to a thickness of 20 nm, so that the electron-transport layer 1114 was formed. Furthermore, lithium fluoride was evaporated to a thickness of 2 nm on the electron-transport layer 1114, so that the electron-injection layer 1115 was foimed.

Next, an aluminum film was formed to a thickness of 200 nm to form the second electrode 1103. Thus, the light-emitting elements (light-emitting elements 1 and 2) which are embodiments of the present invention were obtained. Note that the second electrode 1103 is an electrode that functions as a cathode. Note that in the above evaporation processes, evaporation was all performed by a resistance heating method.

Further, these light-emitting elements were sealed in a glove box under a nitrogen atmosphere to prevent from being exposed to the air.

### [Operation Characteristics of Light-Emitting Element 1 and Light-Emitting Element 2]

Operation characteristics of the fabricated light-emitting elements (light-emitting elements 1 and 2) were measured. Note that the measurements were carried out at room temperature (in an atmosphere kept at 25° C.).

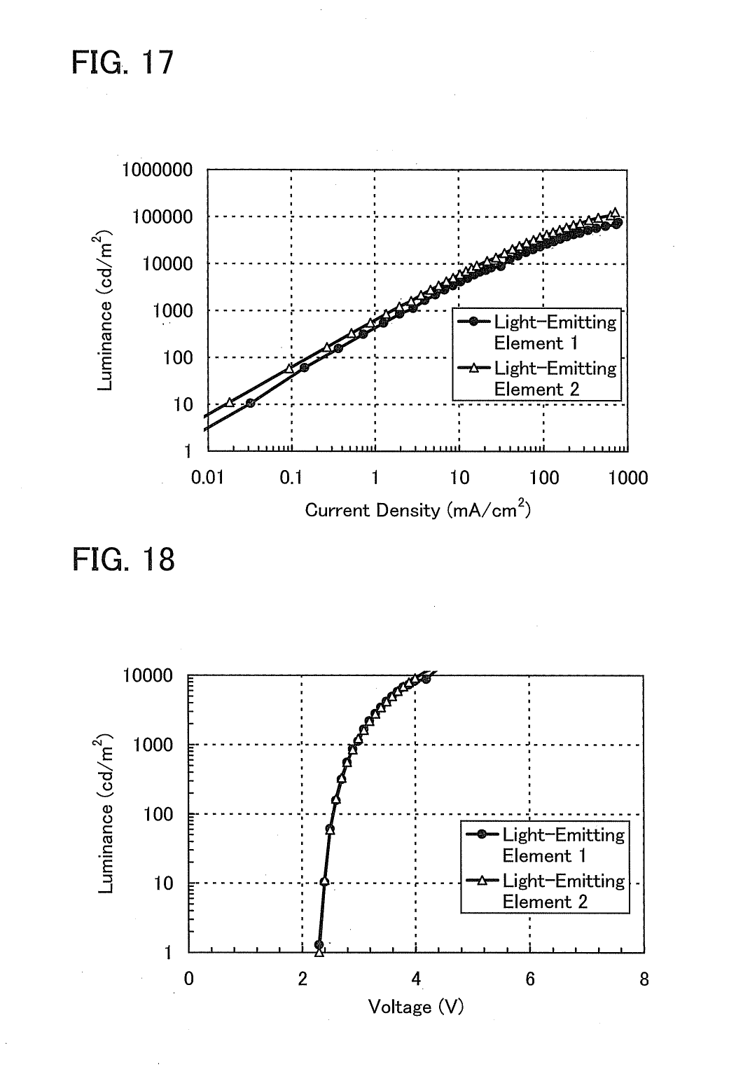

FIG. 17 shows luminance versus current density characteristics of the light-emitting elements. In FIG. 17, the vertical axis represents luminance (cd/m²) and the horizontal axis represents current density (mA/cm²). FIG. 18 shows luminance versus voltage characteristics of the light-emitting elements. In FIG. 18, the vertical axis represents luminance (cd/m²) and the horizontal axis represents voltage (V). It is found from FIG. 17 and FIG. 18 that the light-emitting elements 1 and 2 each have high emission efficiency. FIG. 19 shows luminance versus voltage characteristics of each light-emitting element. In FIG. 19, the vertical axis represents normalized luminance (%), and the horizontal axis represents driving time (h). Note that the normalized luminance is the luminance at each time expressed as percentage relative to the initial luminance of a light-emitting element, which is assumed as 100%. FIG. 19 reveals that a reduction in emission intensity of each of the light-emitting elements 1 and 2 is small relative to the driving time.

FIG. 20 shows emission spectra obtained when current was supplied to the light-emitting elements at a current density of 25 mA/cm². The emission spectrum of the light-emitting element 1 has a peak at 604 nm as shown in FIG. 20, which indicates derivation from light emission of one of the organometallic complexes which are embodiments of the present invention ([Ir(dm4 dbfpr)₂(acac)]). Further, the emission spectrum of the light-emitting element 2 has a peak at 579 nm, which indicates derivation from light emission of one of the organometallic complexes which are embodiments of the present invention ([Ir(dm2 dbfpr)₂(dpm)]).

Note that the light-emitting element 1 showed a voltage of 2.9 V and an external quantum efficiency of 22% at a luminance of 1000 cd/m². Further, the light-emitting element 2 showed a voltage of 2.9 V and an external quantum efficiency of 23% at a luminance of 1000 cd/m².

### Reference Example 1

A method of synthesizing 4-phenyl-4′-(9-phenylfluoren-9-yl)triphenylamine (abbreviation: BPAFLP) used in the above example will be specifically described. A structure of BPAFLP is illustrated below.

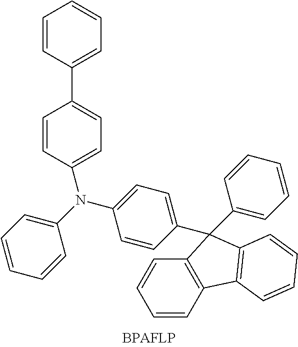

### Step 1: Method of Synthesizing 9-(4-Bromophenyl)-9-phenylfluorene

In a 100 mL three-neck flask, 1.2 g (50 mmol) of magnesium was heated and stirred for 30 minutes under reduced pressure to be activated. This was cooled to room temperature, and the flask was made to contain a nitrogen atmosphere. Then, several drops of dibromoethane were added, so that foam formation and heat generation were confirmed. To this, 12 g (50 mmol) of 2-bromobiphenyl dissolved in 10 mL of diethyl ether was slowly added dropwise, and then the mixture was heated and stirred under reflux for 2.5 hours, so that a Grignard reagent was prepared.

Into a 500 mL three-neck flask were placed 10 g (40 mmol) of 4-bromobenzophenone and 100 mL of diethyl ether. To this mixture, the Grignard reagent which was synthesized in advance was slowly added dropwise, and then the mixture was heated and stirred under reflux for 9 hours.

After reaction, this mixture solution was filtered to give a residue. The obtained residue was dissolved in 150 mL of ethyl acetate, a 1N-hydrochloric acid solution was added thereto until the mixed solution became acid, and the mixture was stirred for 2 hours. The organic layer portion of this liquid was washed with water, and magnesium sulfate was added to remove moisture. This suspension was filtered, and the obtained filtrate was concentrated to give an oily substance.

Into a 500 mL recovery flask were placed this oily substance, 50 mL of glacial acetic acid, and 1.0 mL of hydrochloric acid. The mixture was stirred and heated at 130° C. for 1.5 hours under a nitrogen atmosphere to be reacted.

After the reaction, this reaction mixture solution was filtered to give a residue. The obtained residue was washed with water, an aqueous solution of sodium hydroxide, water, and methanol in this order. Then, the mixture was dried, so that the substance which was the object of the synthesis was obtained as 11 g of a white powder in 69% yield. A reaction scheme of the above synthesis method is illustrated in the following scheme (x).

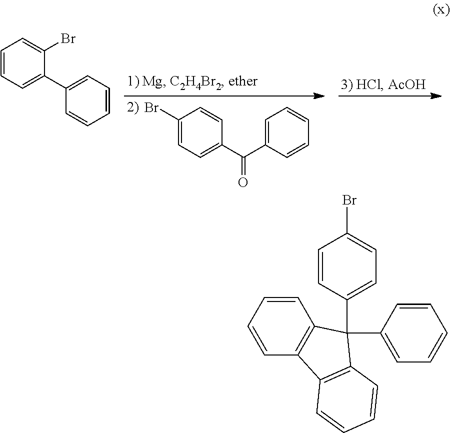

### Step 2: Method of Synthesizing 4-Phenyl-4′-(9-phenylfluoren-9-yl)triphenylamine (abbreviation: BPAFLP)

Into a 100 mL three-neck flask were placed 3.2 g (8.0 mmol) of 9-(4-bromophenyl)-9-phenylfluorene, 2.0 g (8.0 mmol) of 4-phenyl-diphenylamine, 1.0 g (10 mmol) of sodium tert-butoxide, and 23 mg (0.04 mmol) of bis(dibenzylideneacetone)palladium(0), and the air in the flask was replaced with nitrogen. Then, 20 mL of dehydrated xylene was added to this mixture. After the mixture was degassed by being stirred under reduced pressure, 0.2 mL (0.1 mmol) of tri(tert-butyl)phosphine (a 10 wt % hexane solution) was added to the mixture. This mixture was stirred and heated at 110° C. for 2 hours under a nitrogen atmosphere to be reacted.

After the reaction, 200 mL of toluene was added to this reaction mixture, and this suspension was filtered through Florisil (produced by Wako Pure Chemical Industries, Ltd., Catalog No. 540-00135) and Celite (produced by Wako Pure Chemical Industries, Ltd., Catalog No. 531-16855). The obtained filtrate was concentrated, and the resulting substance was purified by silica gel column chromatography (a developing solvent, toluene:hexane=1:4). The obtained fraction was concentrated, and acetone and methanol were added to the mixture. The mixture was irradiated with ultrasonic waves and then recrystallized, so that the substance which was the object of the synthesis was obtained as 4.1 g of a white powder in 92% yield. A reaction scheme of the above synthesis method is illustrated in the following scheme (x′).

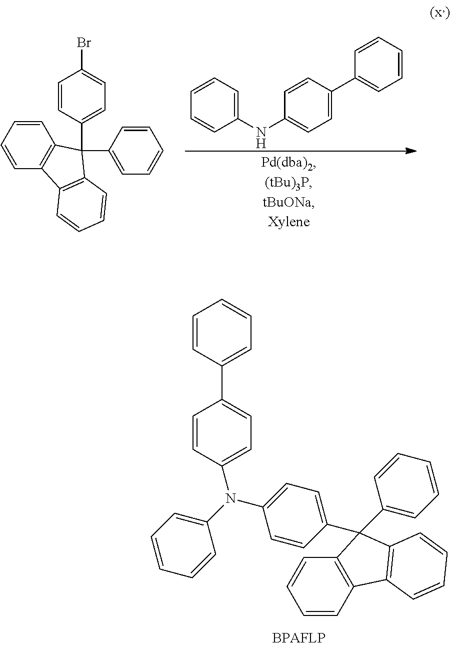

The Rf values of the substance that was the object of the synthesis, 9-(4-bromophenyl)-9-phenylfluorene, and 4-phenyl-diphenylamine were respectively 0.41, 0.51, and 0.27, which were found by silica gel thin layer chromatography (TLC) (a developing solvent, ethyl acetate:hexane=1:10).

The compound obtained in Step 2 above was identified as 4-phenyl-4′-(9-phenylfluoren-9-yl)triphenylamine (abbreviation: BPAFLP), which was the object of the synthesis, by nuclear magnetic resonance (NMR) spectroscopy. ¹H-NMR data of the obtained substance are as follows.

¹H-NMR (CDCl₃, 300 MHz): δ (ppm)=6.63-7.02 (m, 3H), 7.06-7.11 (m, 6H), 7.19-7.45 (m, 18H), 7.53-7.55 (m, 2H), 7.75 (d, J=6.9, 2H).

### Reference Example 2

A method of synthesizing 2-[3-(dibenzothiophen-4-yl)phenyl]dibenzo[f,h]quinoxaline (abbreviation: 2mDBTPDBq-II) used in the above example will be specifically described. A structure of 2mDBTPDBq-II is illustrated below.

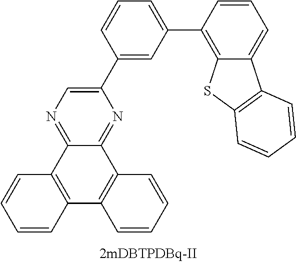

### Synthesis of 2-[3-(Dibenzothiophen-4-yl)phenyl]dibenzo[f,h]quinoxaline (abbreviation: 2mDBTPDBq-II)

A synthesis scheme of 2-[3-(dibenzothiophen-4-yl)phenyl]dibenzo[f,h]quinoxaline (abbreviation: 2mDBTPDBq-II) is illustrated in the following scheme (y).

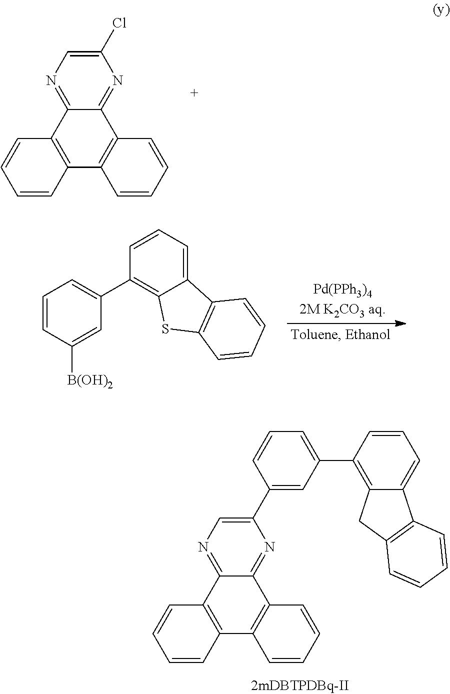

In a 2 L three-neck flask were placed 5.3 g (20 mmol) of 2-chlorodibenzo[f,h]quinoxaline, 6.1 g (20 mmol) of 3-(dibenzothiophen-4-yl)phenylboronic acid, 460 mg (0.4 mmol) of tetrakis(triphenylphosphine)palladium(0), 300 mL of toluene, 20 mL of ethanol, and 20 mL of a 2M aqueous solution of potassium carbonate. This mixture was degassed by stirring under reduced pressure, and the air in the flask was replaced with nitrogen. This mixture was stirred under a nitrogen stream at 100° C. for 7.5 hours. After cooled to room temperature, the obtained mixture was filtered to give a white residue. The obtained residue was washed well with water and ethanol in this order, and then dried. The obtained solid was dissolved in about 600 mL of hot toluene, and the mixture was suction filtered through Celite (produced by Wako Pure Chemical Industries, Ltd., Catalog No. 531-16855) and Florisil (produced by Wako Pure Chemical Industries, Ltd., Catalog No. 540-00135), so that a colorless transparent filtrate was obtained. The obtained filtrate was concentrated and purified by silica gel column chromatography using about 700 mL of silica gel. The chromatography was carried out using toluene at a temperature of about 40° C. as a developing solvent. Acetone and ethanol were added to the solid obtained here and subjected to irradiation with ultrasonic waves. Then, the generated suspended solid was filtered and the obtained solid was dried, so that the object of the synthesis was obtained as 7.85 g of a white powder in a yield of 80%.

The above object of the synthesis was relatively soluble in hot toluene, but is a material that is easy to precipitate when cooled. Further, the substance was poorly soluble in other organic solvents such as acetone and ethanol. Hence, the utilization of these different degrees of solubility leads to a high-yield synthesis with a simple method as above. Specifically, after the reaction finished, the mixture was returned to room temperature and the precipitated solid was collected by filtration, so that most impurities were able to be easily removed. Further, by hot column chromatography with hot toluene as a developing solvent, even the object of the synthesis which is easy to precipitate was able to be readily purified.

By a train sublimation method, 4.0 g of the obtained white powder was purified in such a way that the white powder was heated at 300° C. under a pressure of 5.0 Pa with a flow rate of argon gas of 5 nit/min. After purification by sublimation, the object of the synthesis was obtained in a yield of 88% as 3.5 g of white powder in solid form and in fiber form, which was attached to a portion at about 230° C. to 240° C. in a reaction tube of a sublimation apparatus.

Nuclear magnetic resonance (NMR) spectroscopy identified this compound as 2-[3-(dibenzothiophen-4-yl)phenyl]dibenzo[f,h]quinoxaline (abbreviation: 2mDBTPDBq-II), which was the object of the synthesis. ¹H-NMR data of the obtained substance are shown below.

¹H-NMR (CDCl₃, 300 MHz): δ (ppm)=7.45-7.52 (m, 2H), 7.59-7.65 (m, 2H), 7.71-7.91 (m, 7H), 8.20-8.25 (m, 2H), 8.41 (d, J=7.8 Hz, 1H), 8.65 (d, J=7.5 Hz, 2H), 8.77-8.78 (m, 1H), 9.23 (dd, J=7.2 Hz, 1.5 Hz, 1H), 9.42 (dd, J=7.8 Hz, 1.5 Hz, 1H), 9.48 (s, 1H).

This application is based on Japanese Patent Application serial No. 2010-244599 filed with the Japan Patent Office on Oct. 29, 2010, the entire contents of which are hereby incorporated by reference.

What is claimed is:

1. An organometallic complex including a structure represented by a general formula (G1), 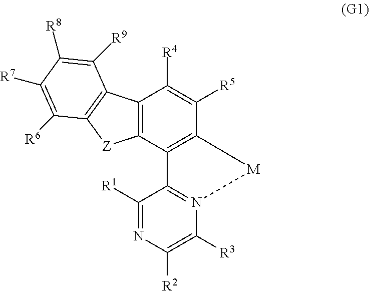
wherein R¹ represents an alkyl group having 1 to 4 carbon atoms or an alkoxy group having 1 to 4 carbon atoms,
wherein R² and R³ separately represent hydrogen or an alkyl group having 1 to 4 carbon atoms,
wherein R⁴, R⁵, R⁶, R⁷, R⁸, and R⁹ separately represent hydrogen or an alkyl group having 1 to 4 carbon atoms,
wherein Z represents oxygen or sulfur, and
wherein M is a central metal and represents either a Group 9 element or a Group 10 element.

2. The organometallic complex according to claim 1, wherein M represents iridium or platinum.

3. The organometallic complex according to claim 1, wherein each of R¹ and R² represents a methyl group.

4. The organometallic complex according to claim 1, wherein each of R⁴ to R⁹ represents hydrogen.

5. An organometallic complex including a structure represented by a general formula (G2), 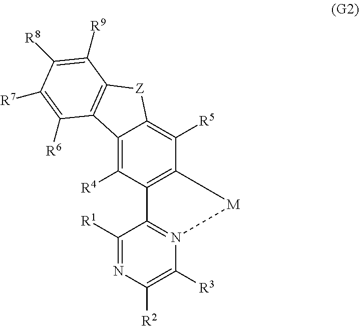
wherein R¹ represents an alkyl group having 1 to 4 carbon atoms or an alkoxy group having 1 to 4 carbon atoms,
wherein R² and R³ separately represent hydrogen or an alkyl group having 1 to 4 carbon atoms,
wherein R⁴, R⁵, R⁶, R⁷, R⁸, and R⁹ separately represent hydrogen or an alkyl group having 1 to 4 carbon atoms,
wherein Z represents oxygen or sulfur, and
wherein M is a central metal and represents either a Group 9 element or a Group 10 element.

6. The organometallic complex according to claim 5, wherein M represents iridium or platinum.

7. The organometallic complex according to claim 5, wherein each of R¹ and R² represents a methyl group.

8. The organometallic complex according to claim 5, wherein each of R⁴ to R⁹ represents hydrogen.

9. An organometallic complex including a structure represented by a general formula (G3), 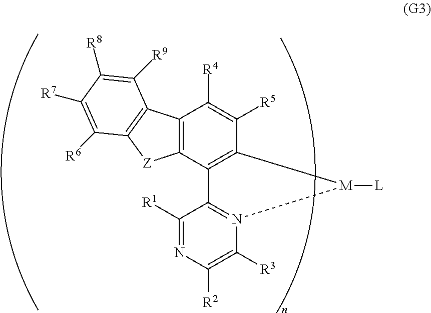
wherein R¹ represents an alkyl group having 1 to 4 carbon atoms or an alkoxy group having 1 to 4 carbon atoms,
wherein R² and R³ separately represent hydrogen or an alkyl group having 1 to 4 carbon atoms,
wherein R⁴, R⁵, R⁶, R⁷, R⁸, and R⁹ separately represent hydrogen or an alkyl group having 1 to 4 carbon atoms,
wherein M is a central metal and represents either a Group 9 element or a Group 10 element,
wherein L represents a monoanionic ligand,
wherein Z represents oxygen or sulfur, and
wherein n is 2 when the central metal M is a Group 9 element, or n is 1 when the central metal M is a Group 10 element.

10. The organometallic complex according to claim 9, wherein M represents iridium or platinum.

11. The organometallic complex according to claim 9, wherein each of R¹ and R² represents a methyl group.

12. The organometallic complex according to claim 9, wherein each of R⁴ to R⁹ represents hydrogen.

13. The organometallic complex according to claim 9, wherein the monoanionic ligand is any one of a monoanionic bidentate chelate ligand having a β-diketone structure, a monoanionic bidentate chelate ligand having a carboxyl group, a monoanionic bidentate chelate ligand having a phenolic hydroxyl group, and a monoanionic bidentate chelate ligand in which two ligand elements are both nitrogen.

14. The organometallic complex according to claim 9,
wherein the monoanionic ligand is a ligand represented by any one of structural formulae (L1) to (L6), 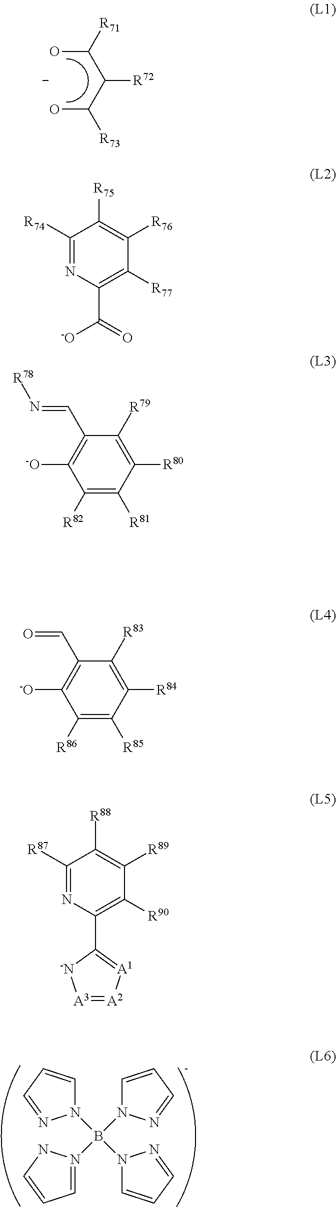
wherein R⁷¹ to R⁹⁰ separately represent any one of hydrogen, an alkyl group having 1 to 4 carbon atoms, a halogen group, a haloalkyl group, an alkoxy group having 1 to 4 carbon atoms, and an alkylthio group having 1 to 4 carbon atoms,
wherein A¹, A², and A³ separately represent nitrogen N or carbon C—R, and
wherein R represents hydrogen, an alkyl group having 1 to 4 carbon atoms, a halogen group, a haloalkyl group having 1 to 4 carbon atoms, or a phenyl group.

15. A light-emitting element comprising a pair of electrodes and the organometallic complex according to claim 9 between the pair of electrodes.

16. A light-emitting device comprising the light-emitting element according to claim 15.

17. The light-emitting device according to claim 16, wherein the light-emitting device is one selected from the group consisting of a television device, a monitor, a camera, a digital photo frame, a cellular phone, a portable game machine, a portable information terminal, an audio playback device, and a large game machine.

18. A lighting device comprising the light-emitting element according to claim 15.

19. An organometallic complex including a structure represented by a general formula (G5), 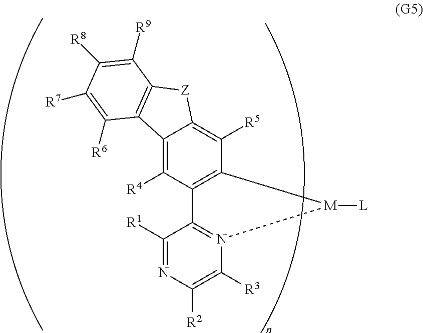
wherein R¹ represents an alkyl group having 1 to 4 carbon atoms or an alkoxy group having 1 to 4 carbon atoms,
wherein R² and R³ separately represent hydrogen or an alkyl group having 1 to 4 carbon atoms,
wherein R⁴, R⁵, R⁶, R⁷, R⁸, and R⁹ separately represent hydrogen or an alkyl group having 1 to 4 carbon atoms,
wherein M is a central metal and represents either a Group 9 element or a Group 10 element,
wherein L represents a monoanionic ligand,
wherein Z represents oxygen or sulfur, and
wherein n is 2 when the central metal M is a Group 9 element, or n is 1 when the central metal M is a Group 10 element.

20. The organometallic complex according to claim 19, wherein M represents iridium or platinum.

21. The organometallic complex according to claim 19, wherein each of R¹ and R² represents a methyl group.

22. The organometallic complex according to claim 19, wherein each of R⁴ to R⁹ represents hydrogen.

23. The organometallic complex according to claim 19, wherein the monoanionic ligand is any one of a monoanionic bidentate chelate ligand having a β-diketone structure, a monoanionic bidentate chelate ligand having a carboxyl group, a monoanionic bidentate chelate ligand having a phenolic hydroxyl group, and a monoanionic bidentate chelate ligand in which two ligand elements are both nitrogen.

24. The organometallic complex according to claim 19,
wherein the monoanionic ligand is a ligand represented by any one of structural formulae (L1) to (L6), 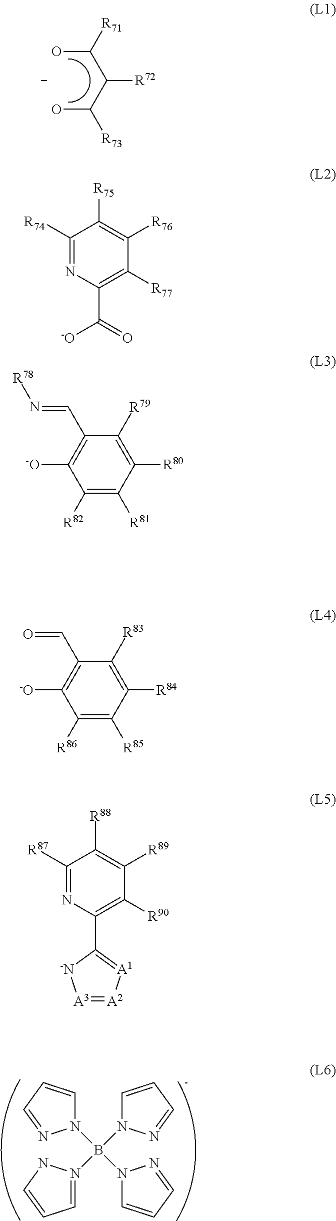
wherein R⁷¹ to R⁹⁰ separately represent any one of hydrogen, an alkyl group having 1 to 4 carbon atoms, a halogen group, a haloalkyl group, an alkoxy group having 1 to 4 carbon atoms, and an alkylthio group having 1 to 4 carbon atoms,
wherein A¹, A², and A³ separately represent nitrogen N or carbon C—R, and
wherein R represents hydrogen, an alkyl group having 1 to 4 carbon atoms, a halogen group, a haloalkyl group having 1 to 4 carbon atoms, or a phenyl group.

25. A light-emitting element comprising a pair of electrodes and the organometallic complex according to claim 19 between the pair of electrodes.

26. A light-emitting device comprising the light-emitting element according to claim 25.

27. The light-emitting device according to claim 26, wherein the light-emitting device is one selected from the group consisting of a television device, a monitor, a camera, a digital photo frame, a cellular phone, a portable game machine, a portable information terminal, an audio playback device, and a large game machine.

28. A lighting device comprising the light-emitting element according to claim 25.

29. An organometallic complex including a structure represented by a general formula (G7), 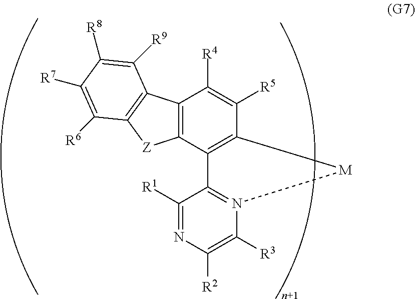
wherein R¹ represents an alkyl group having 1 to 4 carbon atoms or an alkoxy group having 1 to 4 carbon atoms,
wherein R² and R³ separately represent hydrogen or an alkyl group having 1 to 4 carbon atoms.
wherein R⁴, R⁵, R⁶, R⁷, R⁸, and R⁹ separately represent hydrogen or an alkyl group having 1 to 4 carbon atoms,
wherein M is a central metal and represents either a Group 9 element or a Group 10 element,
wherein Z represents oxygen or sulfur, and
wherein n is 2 when the central metal M is a Group 9 element, or n is 1 when the central metal M is a Group 10 element.

30. The organometallic complex according to claim 29, wherein M represents iridium or platinum.

31. The organometallic complex according to claim 29, wherein each of R¹ and R² represents a methyl group.

32. The organometallic complex according to claim 29, wherein each of R⁴ to R⁹ represents hydrogen.

33. A light-emitting element comprising a pair of electrodes and the organometallic complex according to claim 29 between the pair of electrodes.

34. A light-emitting device comprising the light-emitting element according to claim 33.

35. The light-emitting device according to claim 34, wherein the light-emitting device is one selected from the group consisting of a television device, a monitor, a camera, a digital photo frame, a cellular phone, a portable game machine, a portable information terminal, an audio playback device, and a large game machine.

36. A lighting device comprising the light-emitting element according to claim 33.

37. An organometallic complex including a structure represented by a general formula (G9), 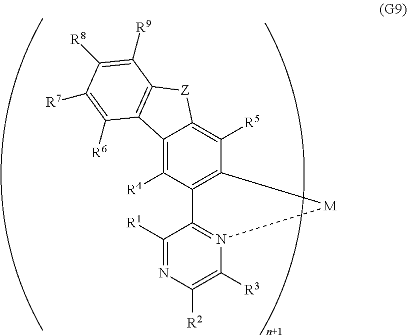
wherein R¹ represents an alkyl group having 1 to 4 carbon atoms or an alkoxy group having 1 to 4 carbon atoms,
wherein R² and R³ separately represent hydrogen or an alkyl group having 1 to 4 carbon atoms,
wherein R⁴, R⁵, R⁶, R⁷, R⁸, and R⁹ separately represent hydrogen or an alkyl group having 1 to 4 carbon atoms,
wherein Z represents oxygen or sulfur,
wherein M is a central metal and represents either a Group 9 element or a Group 10 element, and
wherein n is 2 when the central metal M is a Group 9 element, or n is 1 when the central metal M is a Group 10 element.

38. The organometallic complex according to claim 37, wherein M represents iridium or platinum.

39. The organometallic complex according to claim 37, wherein each of R¹ and R² represents a methyl group.

40. The organometallic complex according to claim 37, wherein each of R⁴ to R⁹ represents hydrogen.

41. A light-emitting element comprising a pair of electrodes and the organometallic complex according to claim 37 between the pair of electrodes.

42. A light-emitting device comprising the light-emitting element according to claim 41.

43. The light-emitting device according to claim 42, wherein the light-emitting device is one selected from the group consisting of a television device, a monitor, a camera, a digital photo frame, a cellular phone, a portable game machine, a portable information terminal, an audio playback device, and a large game machine.

44. A lighting device comprising the light-emitting element according to claim 41.
